(19) United States
(12) Patent Application Publication
(10) Pub. No.: US 2026/0155186 A1
(43) Pub. Date: Jun. 4, 2026

(54) MEMORY DEVICES INCLUDING MEMORY BLOCK PERFORMING SUB-BLOCK OPERATION

(71) Applicant: Samsung Electronics Co., Ltd., Suwon-si (KR)

(72) Inventors: Sungmin Joe, Suwon-si (KR); Donghyuk Chae, Suwon-si (KR); Sanggi Hong, Suwon-si (KR); Seunghyun Moon, Suwon-si (KR); Jihun Jang, Suwon-si (KR)

(21) Appl. No.: 19/371,512

(22) Filed: Oct. 28, 2025

(30) Foreign Application Priority Data
Dec. 4, 2024 (KR) 10-2024-0178888

(51) Int. Cl. G11C 16/16; G11C 16/04; G11C 16/30; G11C 16/32

(52) U.S. Cl. CPC G11C 16/16; G11C 16/0483; G11C 16/30; G11C 16/32

(57) ABSTRACT

A memory device including a memory block performing a sub-block operation is provided. The memory device includes a chip stack structure, which includes a peripheral circuit structure and a cell array structure. The cell array structure includes a first cell chip and a second cell chip on the first cell chip. The first cell chip includes a plurality of first sub-blocks, and the second cell chip includes a plurality of second sub-blocks. Each of the memory blocks is constituted of a first sub-block and a second sub-block corresponding thereto. The first word lines are respectively connected to the second word lines. In an erase operation of a selected first sub-block of a selected memory block among the memory blocks, the first string select lines sequentially float with a delay at a level of a ground voltage starting from a first string select line far from the first bit lines.

### CROSS-REFERENCE TO RELATED APPLICATION

This application is based on and claims priority under 35 U.S.C § 119 to Korean Patent Application No. 10-2024-0178888, filed on Dec. 4, 2024, in the Korean Intellectual Property Office, the disclosure of which is incorporated by reference herein in its entirety.

### BACKGROUND

With information and communication devices recently becoming multifunctional, memory devices are required to have a high capacity and a high integration density. As the size of memory cells is reduced for high integration density, the complexity of operating circuits and/or wiring structures, which are included in memory devices for the operations and electrical connection thereof, has increased. Therefore, a memory device for increasing an integration density and improving electrical characteristics is desired. To increase the storage capacity and integration density of a memory device, there has been research into non-volatile memory devices, e.g., three-dimensional (3D) NAND flash memory, in which memory cells are stacked in three dimensions.

The performance and quality of 3D NAND flash memory may change over time. Memory systems may expect reliability, availability, and serviceability (RAS) with respect to 3D NAND flash memory. Accordingly, some 3D NAND flash memory may include a spare memory block in a memory cell array. The need for a spare memory block may cause a chip size to increase.

### SUMMARY

In general, the present disclosure is directed toward memory devices capable of reducing a chip size by implementing a sub-block operation of a single memory block.

According to some implementations, the present disclosure is directed to a memory device that includes a chip stack structure, wherein the chip stack structure includes a peripheral circuit structure including a plurality of first bonding metal pads and a cell array structure on the peripheral circuit structure and overlapping the peripheral circuit structure in a vertical direction, the cell array structure including a plurality of memory blocks, a plurality of second bonding metal pads, and a plurality of third bonding metal pads. The cell array structure further includes a first cell chip and a second cell chip on the first cell chip. The first cell chip includes the plurality of second bonding metal pads and a first memory cell array region including a plurality of first sub-blocks, wherein each of the plurality of first sub-blocks includes a plurality of first word lines, a plurality of first string select lines, a plurality of first ground select lines, a plurality of first bit lines, and a first common source line, and some of the plurality of second bonding metal pads in a lower portion of the first cell chip are in contact with the plurality of first bonding metal pads. The second cell chip includes the plurality of third bonding metal pads and a second memory cell array region including a plurality of second sub-blocks, wherein each of the plurality of second sub-blocks includes a plurality of second word lines, a plurality of second string select lines, a plurality of second ground select lines, a plurality of second bit lines, and a second common source line, and the plurality of third bonding metal pads are in contact with the other second bonding metal pads in an upper portion of the first cell chip. Each of the plurality of memory blocks is constituted of a first sub-block corresponding thereto among the plurality of first sub-blocks and a second sub-block corresponding thereto among the plurality of second sub-blocks. The plurality of first word lines are respectively connected to the plurality of second word lines. In an erase operation of a selected first sub-block of a selected memory block among the plurality of memory blocks, the plurality of first string select lines sequentially float with a delay at a level of a ground voltage starting from a first string select line far from the plurality of first bit lines.

According to some implementations, the present disclosure is directed to a precharge operation of a program operation of a selected first sub-block of a selected memory block among the plurality of memory blocks, a channel of an unselected second sub-block is initialized in two directions of the plurality of second bit lines and the second common source line by applying a turn-on voltage to the plurality of second string select lines and the plurality of second ground select lines, and the turn-on voltage is at a level that turns on a transistor connected to each of the plurality of second string select lines and the plurality of second ground select lines.

In some implementations, a first bit line voltage may be applied to the plurality of first bit lines and the plurality of second bit lines, a first common source line voltage may be applied to the first common source line and the second common source line, and the first bit line voltage and the first common source line voltage may be at a level of a power supply voltage.

In some implementations, a pass voltage may be applied to the plurality of first word lines and the plurality of second word lines, and the pass voltage may be at a level that turns on a memory cell transistor connected to each of the plurality of first word lines and the plurality of second word lines.

In some implementations, a selected word line among the plurality of first word lines and the plurality of second word lines may be recovered from a level of the pass voltage to a level of the ground voltage at a first time point, and unselected word lines among the plurality of first word lines and the plurality of second word lines may be recovered from the level of the pass voltage to the level of the ground voltage at a second time point after the first time point.

In some implementations, the unselected word lines may be sequentially recovered to the level of the ground voltage starting from an unselected word line close to the selected word line.

In some implementations, each of a plurality of cell strings of each of the first sub-block and the second sub-block may include a plurality of stacks, a plurality of dummy word lines may be arranged near a boundary between the plurality of stacks, the pass voltage may be applied to the plurality of dummy word lines, and the plurality of dummy word lines may be recovered from the level of the pass voltage to the level of the ground voltage between the first time point and the second time point.

In some implementations, a first bit line voltage may be applied to the plurality of first bit lines, a second bit line voltage higher than the first bit line voltage may be applied to the plurality of second bit lines, a first common source line voltage may be applied to the first common source line, a second common source line voltage higher than the first common source line voltage may be applied to the second common source line, a level of the first bit line voltage may be equal to a level of the first common source line voltage, and a level of the second bit line voltage may be equal to a level of the second common source line voltage.

According to some implementations, the present disclosure is directed to a precharge operation of a program operation of a selected first sub-block of a selected memory block among the plurality of memory blocks, a first string select line that is close to the plurality of second bit lines among the plurality of second string select lines floats with a delay at a level of a ground voltage.

In some implementations, in the precharge operation, a first ground select line that is close to the second common source line among the plurality of ground select lines may float with a delay at the level of the ground voltage.

In some implementations, in the precharge operation, the ground voltage may be applied to the plurality of first word lines and the plurality of second word lines, a precharge voltage lower than an erase voltage may be applied to the plurality of first bit lines, the plurality of second bit lines, the first common source line, and the second common source line, and a power supply voltage may be applied to the plurality of first string select lines and the plurality of first ground select lines.

In some implementations, the precharge operation may be performed in the program operation of pages of the selected first sub-block.

In some implementations, the precharge operation may be performed in the program operation of each page of the selected first sub-block.

In some implementations, the precharge operation may be performed when an unselected second sub-block of the selected memory block may be in a programmed state.

In some implementations, whether the unselected second sub-block is in the programmed state may be determined in a program verify operation of the program operation.

In some implementations, whether the unselected second sub-block is in the programmed state may be determined in an erase verify operation of an erase operation of the second sub-block.

According to some implementations, the present disclosure is directed to a program verify operation of a selected first sub-block of a selected memory block among the plurality of memory blocks, in which a turn-off voltage is applied to the plurality of second string select lines and the plurality of second ground select lines of an unselected second sub-block, and the turn-off voltage is at a level that turns off a transistor connected to each of the plurality of second string select lines and the plurality of second ground select lines.

In some implementations, in the program verify operation, a verify voltage may be applied to a selected word line among the plurality of first word lines and the plurality of second word lines, one of a power supply voltage and a read voltage may be applied to unselected word lines among the plurality of first word lines and the plurality of second word lines, a first bit line voltage may be applied to a selected bit line among the plurality of first bit lines, a ground voltage may be applied to the plurality of second bit lines and an unselected bit line among the plurality of first bit lines, the read voltage may be applied to a selected string select line among the plurality of first string select lines, the read voltage may be applied to an unselected string select line among the plurality of first string select lines, the turn-off voltage may be applied to the unselected string select line among the plurality of first string select lines after a first time, the read voltage may be applied to a selected ground select line among the plurality of first ground select lines, the read voltage may be applied to an unselected ground select line among the plurality of first ground select lines, and the turn-off voltage may be applied to the unselected ground select line among the plurality of first string select lines after a first time.

In some implementations, when the unselected second sub-block is in an erased state, the power supply voltage may be applied to word lines below the selected word lines among the unselected word lines.

In some implementations, when the unselected second sub-block is in a programmed state, the read voltage may be applied to word lines below the selected word lines among the unselected word lines.

According to some implementations, the present disclosure is directed to a read operation of a selected first sub-block of a selected memory block among the plurality of memory blocks, in which a turn-off voltage may be applied to the plurality of second string select lines and the plurality of second ground select lines of an unselected second sub-block, and the turn-off voltage may be at a level that turns off a transistor connected to each of the plurality of second string select lines and the plurality of second ground select lines.

In some implementations, in the read operation, a first read voltage may be applied to a selected word line among the plurality of first word lines and the plurality of second word lines, a second read voltage may be applied to unselected word lines among the plurality of first word lines and the plurality of second word lines, a first bit line voltage may be applied to a selected bit line among the plurality of first bit lines, and a ground voltage may be applied to the plurality of second bit lines and an unselected bit line among the plurality of first bit lines.

In some implementations, the second read voltage may be applied to a selected string select line among the plurality of first string select lines, the second read voltage may be applied to an unselected string select line among the plurality of first string select lines, the turn-off voltage may be applied to the unselected string select line among the plurality of first string select lines after a first time, the second read voltage may be applied to a selected ground select line among the plurality of first ground select lines, the second read voltage may be applied to an unselected ground select line among the plurality of first ground select lines, and the turn-off voltage may be applied to the unselected ground select line among the plurality of first string select lines after a first time.

In some implementations, the second read voltage is applied to the plurality of second string select lines and the plurality of second ground select lines, and the turn-off voltage may be applied to the plurality of second string select lines and the plurality of second ground select lines after the first time.

### BRIEF DESCRIPTION OF THE DRAWINGS

Example implementations will be more clearly understood from the following detailed explanations, taken in conjunction with the accompanying drawings.

FIGS. 1 and 2 are diagrams illustrating an example of a memory device according to some implementations.

FIGS. 3A and 3B are diagrams illustrating an example of a memory block according to some implementations

FIGS. 4A and 4B are diagrams illustrating an example of a memory block according to some implementations.

FIGS. 5A and 5B are diagrams illustrating an example of a memory block according to some implementations.

FIGS. 6A and 6B are diagrams illustrating an example of a memory block according to some implementations.

FIGS. 7A-7B and 8 to 10 are diagrams illustrating an example of an erase operation of a memory device according to some implementations.

FIGS. 11 to 13 are diagrams illustrating an example of an erase operation of a memory device according to some implementations.

FIGS. 14 and 15 are diagrams illustrating an example of an erase operation of a memory device according to some implementations.

FIGS. 16A-16D and 17 to 20 are diagrams illustrating an example of a program operation of a memory device according to some implementations.

FIGS. 21 to 26 are diagrams illustrating examples of program methods according to some implementations.

FIGS. 27 and 28 are timing diagrams illustrating examples of program verify methods according to some implementations.

FIGS. 29 and 30 are diagrams illustrating examples of read methods of a memory device according to some implementations.

FIG. 31 is a cross-sectional view of an example of a memory device having a bonding vertical NAND (B-VNAND) structure according to some implementations.

FIG. 32 is a block diagram illustrating an example of applying a memory device to a solid-state drive (SSD) system according to some implementations.

FIG. 33 is a block diagram of a system illustrating an example of an electronic apparatus including a memory device according to some implementations.

### DETAILED DESCRIPTION

Hereinafter, example implementations will be explained in detail with reference to the accompanying drawings.

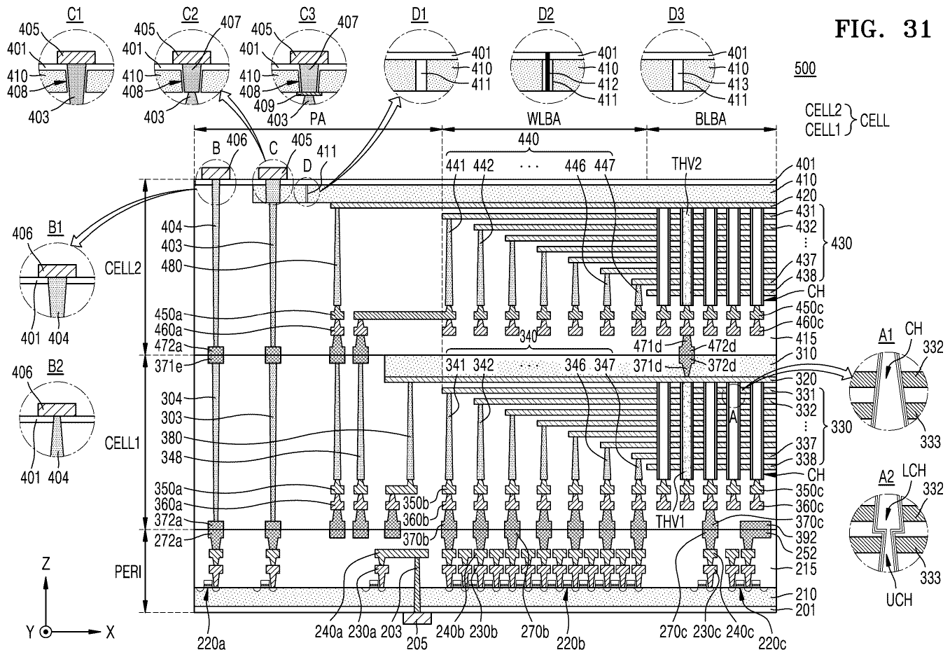

Memory devices described below may include memory blocks having a three-dimensional (3D) structure. Each memory block may include NAND flash memory cells. A memory device may have a chip-to-chip (C2C) structure. The C2C structure may refer to a structure formed by manufacturing at least one upper chip including a cell region and a lower chip including a peripheral circuit region and then connecting the upper chip to the lower chip in a bonding manner. The C2C structure may include two upper chips. However, this is just an example, and the number of upper chips is not limited thereto. When a memory device includes two upper chips, as shown in FIG. 31, a first upper chip including a first cell region CELL1, a second upper chip including a second cell region CELL2, and a lower chip including a peripheral circuit region PERI may be connected to one another in a bonding manner. Hereinafter, a memory device may include a plurality of memory blocks. A single memory block may be constituted of a plurality of sub blocks. A plurality of sub blocks may be connected to word lines or to word lines and bit lines. There are provided memory devices capable of reducing a chip size and power consumption and increasing the performance thereof through the erase, program, verify, and/or read operations of a plurality of sub blocks. For convenience of description, a memory device may interchangeably be used with a non-volatile memory device.

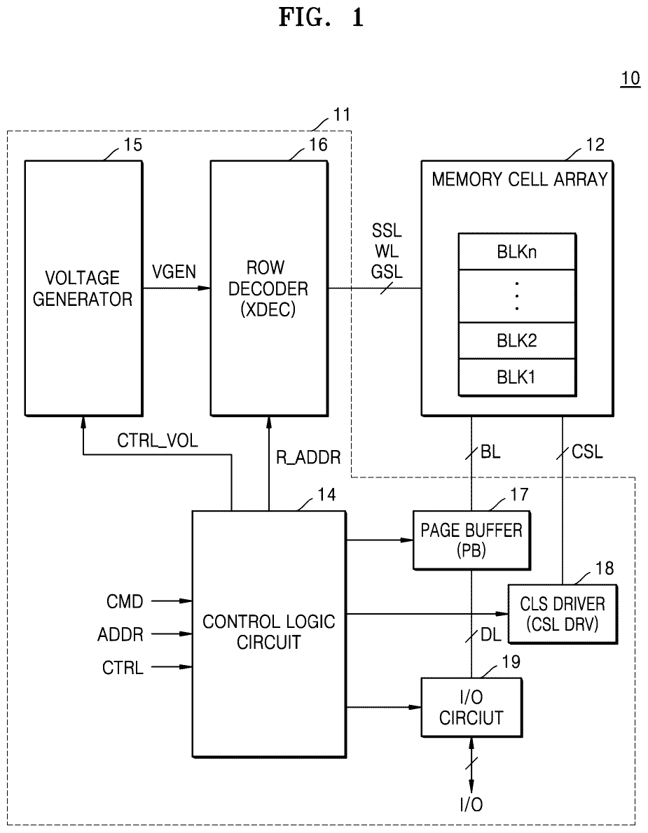

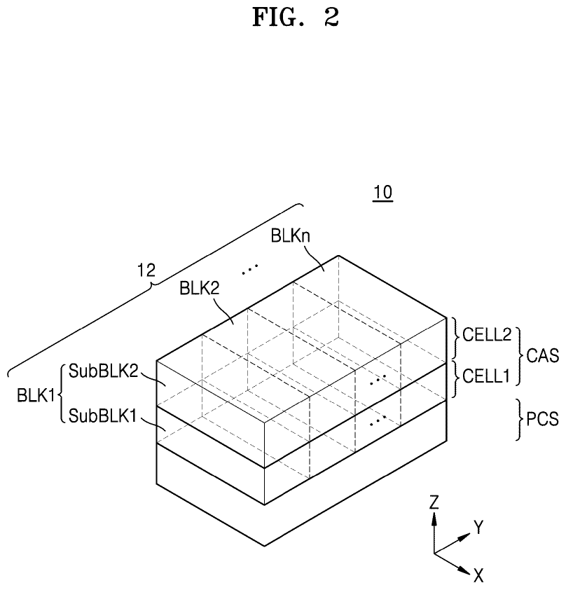

FIGS. 1 and 2 are diagrams illustrating an example of a memory device according to some implementations. FIG. 1 is a block diagram conceptually illustrating a memory device 10, and FIG. 2 schematically illustrates the structure of the memory device 10 of FIG. 1.

In FIG. 1, the memory device 10 may include a peripheral circuit 11 and a memory cell array 12. The peripheral circuit 11 may include a control logic circuit 14, a voltage generator 15, a row decoder (XDEC) 16, a page buffer (PB) 17, a common source line (CSL) driver (DRV) 18, and an input/output (I/O) circuit 19. In some implementations, the peripheral circuit 11 may further include an I/O interface connected to a memory controller that is an external device.

The memory cell array 12 may be connected to word lines WL, string select lines SSL, ground select lines GSL, common source lines CSL and bit lines BL. The memory cell array 12 may be connected to the row decoder 16 through the word lines WL, the string select lines SSL, and the ground select lines GSL, connected to the page buffer 17 through the bit lines BL, and connected to the CSL driver 18 through the common source lines CSL. The memory cell array 12 may include first to n-th memory blocks BLK1 to BLKn, where “n” is a natural number of at least 2. Each of the first to n-th memory blocks BLK1 to BLKn may include a plurality of NAND flash memory cells. The memory cell array 12 may include a 3D memory cell array including a plurality of cell strings.

The 3D memory cell array may be monolithically formed at at least one physical level of memory cell arrays, which have an active region on a silicon substrate and a circuit which is involved in the operation of memory cells and formed on or in the silicon substrate. The term “monolithic” means that layers of each level of an array are directly stacked on layers of an underlying level of the array. In some implementations, a 3D memory cell array includes cell strings which are arranged in a vertical direction so that at least one memory cell is placed on another memory cell. The memory cell may include a charge trap layer. Structures of a 3D memory array, in which the 3D memory array includes a plurality of levels and word lines and/or bit lines are shared by levels, are disclosed in U.S. patent application Publication Ser. No. 7,679,133, U.S. patent application Publication Ser. No. 8,553,466, U.S. patent application Publication Ser. No. 8,654,587, U.S. patent application Publication Ser. No. 8,559,235, and U.S. Patent Application Publication No. 2011/0233648, the disclosures of which are incorporated herein in their entirety by reference.

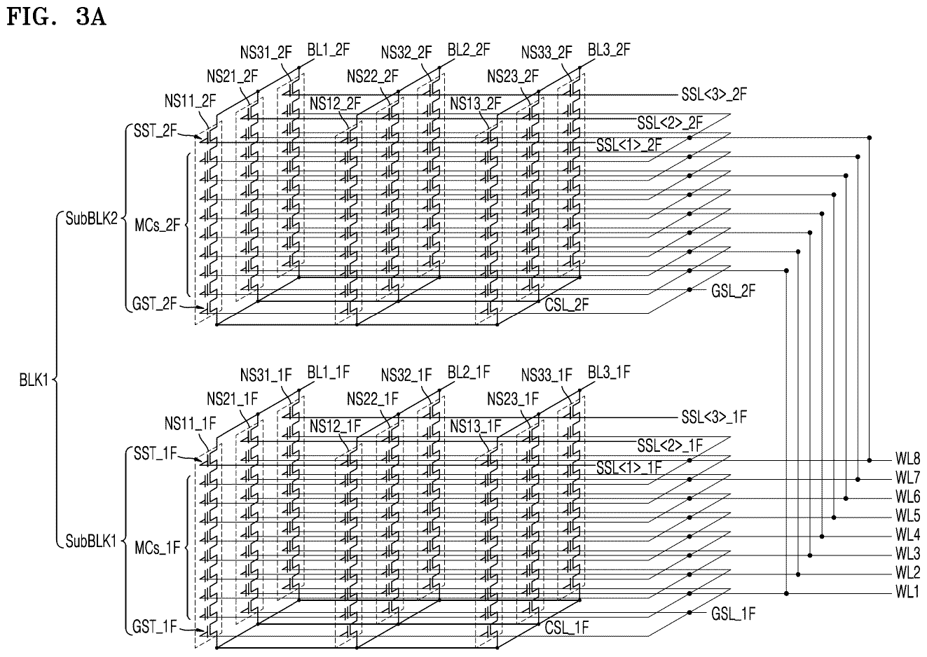

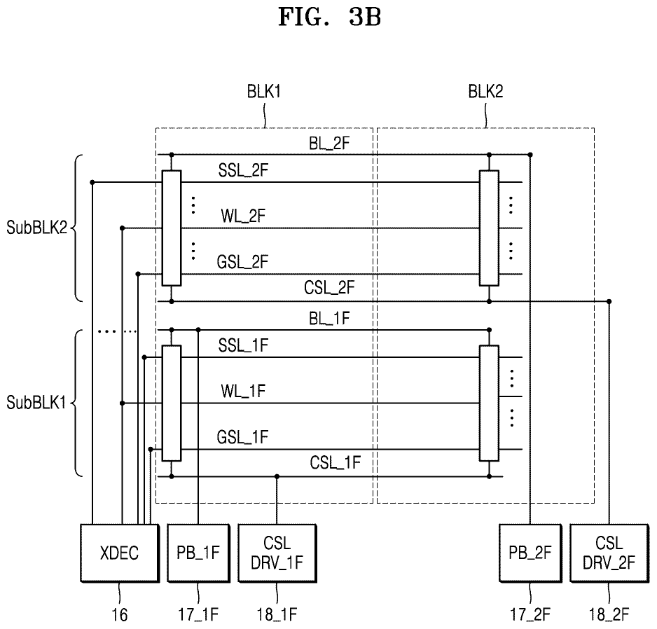

Each of the first to n-th memory blocks BLK1 to BLKn may include a plurality of memory cells (e.g., MCs_1F and MCs_2F in FIG. 3A) and a plurality of select transistors (e.g., SST_1F, GST_1F, SST_2F, and GST_2F in FIG. 3A). The memory cells may be connected to the word lines WL. The select transistors may be connected to the string select lines SSL or a ground select line GSL. The memory cells of each of the first to n-th memory blocks BLK1 to BLKn may include a single-level cell that stores 1-bit data or a multi-level cell that stores M-bit data, where M is 2 or an integer greater than 2.

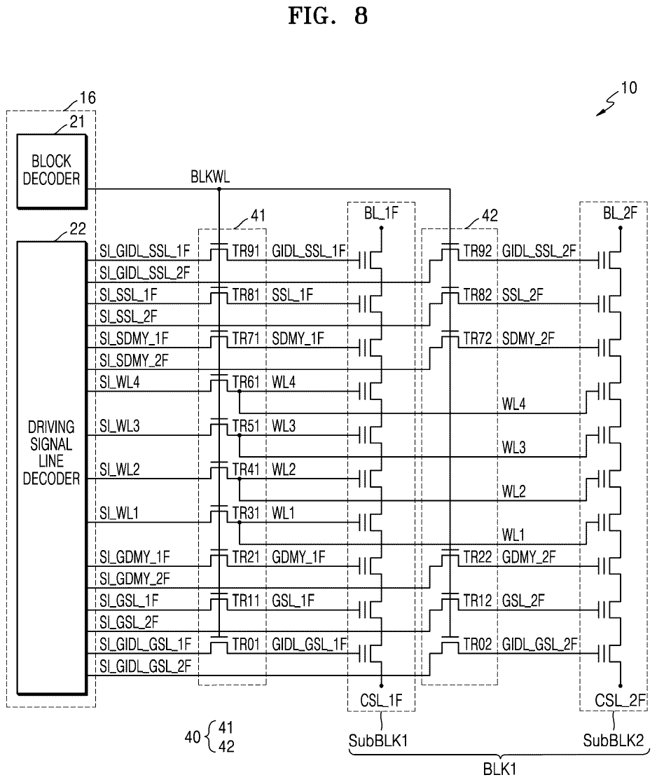

The row decoder 16 may select one of the first to n-th memory blocks BLK1 to BLKn of the memory cell array 12 and may drive the word lines WL, the string select lines SSL, and the ground select lines GSL of the first to n-th memory blocks BLK1 to BLKn according to operation modes (e.g., program, verify, read, and erase operations). According to some implementations, the row decoder 16 may drive dummy word lines (e.g., SDMY_1F, GDMY_1F, SDMY_2F, and GDMY_2F in FIG. 8) of the first to n-th memory blocks BLK1 to BLKn according to the operation modes.

The control logic circuit 14 may output various kinds of internal control signals for performing program, verify, read, and erase operations on the memory cell array 12, based on a command CMD, an address ADDR, and a control signal CTRL, which are transmitted from a memory controller. The control logic circuit 14 may provide a row address R_ADDR to the row decoder 16, a column address to the I/O circuit 19, and a voltage control signal CTRL_VOL to the voltage generator 15. The control logic circuit 14 may hereby generally control the operation modes of the memory device 10.

The page buffer 17 may operate as a write driver or a sense amplifier according the operation modes of the memory device 10. In an erase operation, the page buffer 17 may drive the bit lines BL of the first to n-th memory blocks BLK1 to BLKn under control by the control logic circuit 14. In a read operation, the page buffer 17 may sense a bit line BL of a selected memory cell under control by the control logic circuit 14. The sensed data may be stored in latches included in the page buffer 17. Under control by the control logic circuit 14, the page buffer 17 may dump the data stored in the latches to the I/O circuit 19 through a data line DL. The CSL driver 18 may drive the common source lines CSL of the first to n-th memory blocks BLK1 to BLKn according to the operation modes of the memory device 10.

The I/O circuit 19 may temporarily store the command CMD, the address ADDR, and data, which are provided from a memory controller through an I/O line I/O. The I/O circuit 19 may temporarily store read data of the memory device 10 and output the read data to the outside at a certain time through the I/O line I/O.

The voltage generator 15 may generate various kinds of voltages VGEN for performing the program, read, and erase operations of the memory cell array 12, based on the voltage control signal CTRL_VOL. Specifically, the voltage generator 15 may generate an erase voltage, a program voltage, a program verify voltage, a read voltage, a precharge voltage, etc.

In FIG. 2, the memory device 10 may include a cell array structure CAS and a peripheral circuit structure PCS, which overlap each other in a third direction (a Z direction). The cell array structure CAS may include the memory cell array 12 described with reference to FIG. 1. The peripheral circuit structure PCS may include the peripheral circuit 11 described with reference to FIG. 1. The cell array structure CAS may include the first to n-th memory blocks BLK1 to BLKn. Each of the first to n-th memory blocks BLK1 to BLKn may include memory cells arranged in three dimensions. For example, each of the first to n-th memory blocks BLK1 to BLKn may include structures extending in first to third directions (X, Y, and Z directions). Each of the first to n-th memory blocks BLK1 to BLKn may include a first sub-block SubBLK1 in a first cell region CELL1 and a second sub-block SubBLK2 in a second cell region CELL2.

FIGS. 3A and 3B are diagrams illustrating an example of a memory block according to some implementations. FIGS. 3A and 3B show the first memory block BLK1 as an example of one of the first to n-th memory blocks BLK1 to BLKn described with reference to FIG. 1. Hereinafter, implementations are described by explaining the first memory block BLK1 as an example. For convenience of description, the first memory block BLK1 may interchangeably be used with the memory block BLK1. The memory block BLK1 may refer to a 3D memory block that is formed on a substrate in a 3D structure. A plurality of memory cell strings included in the memory block BLK1 may be formed in a direction that is perpendicular to the substrate. For convenience of the description of FIGS. 3A and 3B, the first memory block BLK1 is mainly described. However, the second to n-th memory blocks BLK2 to BLKn is configured in the same manner as the first memory block BLK1.

In FIG. 3A, the memory block BLK1 may include a first sub-block SubBLK1 and a second sub-block SubBLK2. Word lines WL1 to WL8 of the first sub-block SubBLK1 may be respectively connected to word lines WL1 to WL8 of the second sub-block SubBLK2. The first sub-block SubBLK1 may include cell strings NS11_1F to NS33_1F, the word lines WL1 to WL8, bit lines BL1_1F to BL3_1F, a ground select line GSL_1F, string select lines SSL<1>_1F to SSL<3>_1F, and a common source line CSL_1F. Although it is illustrated in FIG. 3A that each of the cell strings NS11_1F to NS33_1F includes eight memory cells MCs_1F respectively connected to the eight word lines WL1 to WL8, this is just an example only intended for help with understanding and does not limit the inventive concept.

In the first sub-block SubBLK1, each cell string, e.g., the cell string NS11_1F, may include a string select transistor SST_1F, the memory cells MCs_1F, and a ground select transistor GST_1F, which are connected in series to one another. The string select transistor SST_1F may be connected to the string select line SSL<1>_1F corresponding thereto. The memory cells MCs_1F may be respectively connected to the word lines WL1 to WL8. The ground select transistor GST_1F may be connected to the ground select line GSL_1F. The string select transistor SST_1F may be connected to its corresponding one of the bit lines BL1_1F to BL3_1F, and the ground select transistor GST_1F may be connected to the common source line CSL_1F.

In the first sub-block SubBLK1, each of the word lines WL1 to WL8 may be connected in common to memory cell transistors in one layer. The memory cell transistors in one layer may receive the same word line voltage. A plurality of string select transistors SST_1F in one layer may be connected to the string select lines SSL<1>_1F to SSL<3>_1F. A plurality of ground select transistors GST_1F may be simultaneously controlled. In other words, the ground select transistors GST_1F of the first sub-block SubBLK1 may be controlled by the ground select line GSL_1F.

In some implementations, each cell string of the first sub-block SubBLK1 may include one or more dummy memory cells. Each cell string may include one or more dummy memory cells between the string select transistor SST_1F and the memory cells MCs_1F. Each cell string may include one or more dummy memory cells between the ground select transistor GST_1F and the memory cells MCs_1F. Each cell string may include one or more dummy memory cells among the memory cells MCs_1F. Dummy memory cells may have the same structure as the memory cells MCs_1F and may not be programmed (e.g., may be program-inhibited) or may be programmed differently than the memory cells MCs_1F. For example, when the memory cells MCs_1F are programmed to have two or more threshold voltage distributions, the dummy memory cells may be programmed to have one threshold voltage distribution or a smaller number of threshold voltage distributions than the memory cells MCs_1F.

In some implementations, the string select line SSL<1>_1F of the first sub-block SubBLK1 may be connected to the gate of string select transistor SST_1F, each of the word lines WL1 to WL8 may be connected to the gate of a memory cell transistor, each dummy word line may be connected to the gate of a dummy memory cell transistor, and the ground select line GSL_1F may be connected to the gate of the ground select transistor GST_1F. This may mean that the string select line SSL<1>_1F, the word lines WL1 to WL8, the dummy word lines, and the ground select line GSL_1F may each function as a gate line. Accordingly, the string select line SSL<1>_1F, the word lines WL1 to WL8, the dummy word lines, and the ground select line GSL_1F, which are connected to a cell string, may be referred to as gate lines.

In some implementations, the string select line SSL<1>_1F of the first sub-block SubBLK1 may include a plurality of string select lines (e.g., GIDL_SSL_1F and SSL_1F in FIG. 8), and the ground select line GSL_1F may also include a plurality of ground select lines (e.g., GIDL_GSL_1F and GSL_1F in FIG. 8).

Similar to the first sub-block SubBLK1, in the second sub-block SubBLK2, each cell string, e.g., the cell string NS11_2F, may include a string select transistor SST_2F, a plurality of memory cells MCs_2F, and a ground select transistor GST_2F, which are connected in series to one another. The string select transistor SST_2F may be connected to a string select line SSL<1>_2F corresponding thereto, the memory cells MCs_2F may be respectively connected to the word lines WL1 to WL8, and the ground select transistor GST_2F may be connected to a ground select line GSL_2F. The string select transistor SST_2F may be connected to its corresponding one of bit lines BL1_2F to BL3_2F, and the ground select transistor GST_2F may be connected to a common source line CSL_2F. Each cell string may include one or more dummy memory cells between the string select transistor SST_2F and the memory cells MCs_2F, between the ground select transistor GST_2F and the memory cells MCs_2F, and among the memory cells MCs_2F. The string select line SSL<1>_2F of the second sub-block SubBLK2 may include a plurality of string select lines (e.g., GIDL_SSL_2F and SSL_2F in FIG. 8), and the ground select line GSL_2F may also include a plurality of ground select lines (e.g., GIDL_GSL_2F and GSL_2F in FIG. 8). In some implementations, the second sub-block SubBLK2 may include cell strings NS11_2F to NS33_2F, and a plurality of string selection transistors SST_2F in one layer may be connected to string selection lines SSL<1>_2F to SSL<3>_2F.

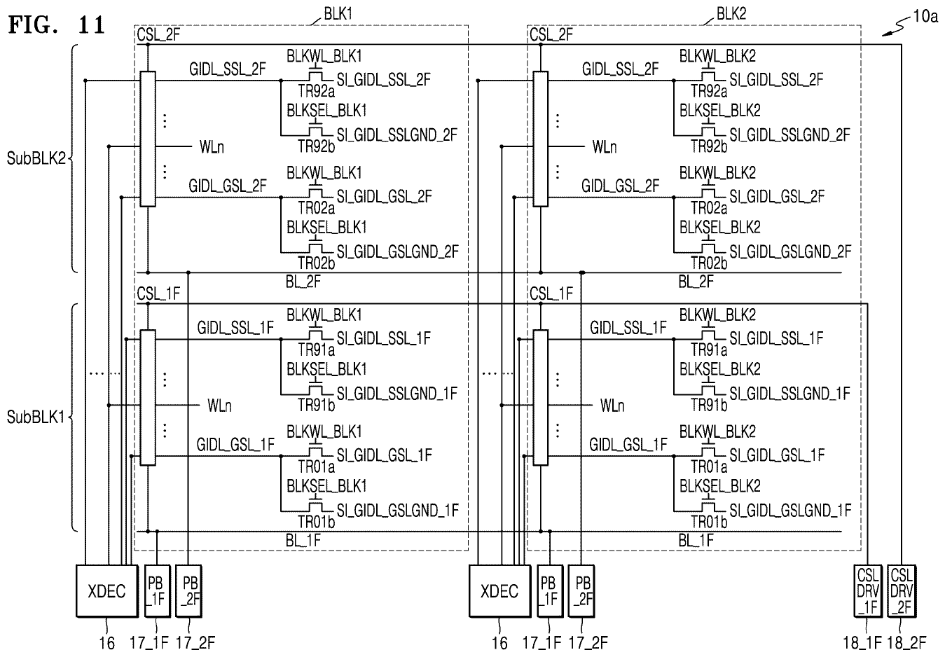

In FIG. 3B, each of the first memory block BLK1 and the second memory block BLK2 may include the first sub-block SubBLK1 and the second sub-block SubBLK2. Word lines WL_1F of the first sub-block SubBLK1 of each of the first and second memory blocks BLK1 and BLK2 may be respectively connected to word lines WL_2F of the second sub-block SubBLK2 of each of the first and second memory blocks BLK1 and BLK2, and the word lines WL_1F and the word lines WL_2F may be connected in common to the row decoder 16. In each of the first and second memory blocks BLK1 and BLK2, string select lines SSL_1F of the first sub-block SubBLK1 and string select lines SSL_2F of the second sub-block SubBLK2 may be connected to the row decoder 16. In each of the first and second memory blocks BLK1 and BLK2, the ground select lines GSL_1F of the first sub-block SubBLK1 and the ground select lines GSL_2F of the second sub-block SubBLK2 may be connected to the row decoder 16. The row decoder 16 may select one of the first and second memory blocks BLK1 and BLK2 in response to a block select signal (e.g., BLKWL_BLK1, BLKSEL_BLK1, BLKWL_BLK2, or BLKSEL_BLK2 in FIG. 11) and may drive the word lines WL_1F and WL_2F, the string select lines SSL_1F and SSL_2F, and the ground select lines GSL_1F and GSL_2F of the selected memory block.

In each of the first and second memory blocks BLK1 and BLK2, a bit line BL_1F of the first sub-block SubBLK1 may be connected to a first page buffer (PB_1F) 17_1F, and a bit line BL_2F of the second sub-block SubBLK2 may be connected to a second page buffer (PB_2F) 17_2F. The first page buffer 17_1F may select one of the first and second memory blocks BLK1 and BLK2 in response to a block select signal and may drive the bit lines BL_1F of the first sub-block SubBLK1 of the selected memory block. The second page buffer 17_2F may select one of the first and second memory blocks BLK1 and BLK2 in response to a block select signal and may drive the bit lines BL_2F of the second sub-block SubBLK2 of the selected memory block.

In each of the first and second memory blocks BLK1 and BLK2, the common source line CSL_1F of the first sub-block SubBLK1 may be connected to a first CSL driver (CSL DRV_1F) 18_1F, and the common source line CSL_2F of the second sub-block SubBLK2 may be connected to a second CSL driver (CSL DRV_2F) 18_2F. The first CSL driver 18_1F may select one of the first and second memory blocks BLK1 and BLK2 in response to a block select signal and may drive the common source line CSL_1F of the first sub-block SubBLK1 of the selected memory block. The second CSL driver 18_2F may select one of the first and second memory blocks BLK1 and BLK2 in response to a block select signal and may drive the common source line CSL_2F of the second sub-block SubBLK2 of the selected memory block.

In FIGS. 3A and 3B, the memory block BLK1 may be divided into the first sub-block SubBLK1 and the second sub-block SubBLK2, which operate separately from each other, thereby reducing the chip size of the memory device 10 having a high capacity. For example, the memory device 10 may be designed to have a user capacity of 1 TB. When the memory capacity of a single memory block (e.g., BLK1) is 100 MB, the memory device 10 may include ten memory blocks. When the single memory block (e.g., BLK1) of the memory device 10 includes the first sub-block SubBLK1 and the second sub-block SubBLK2 that have a memory capacity of 50 MB, the memory device 10 may include twenty sub-blocks (for example, first and/or second sub-blocks SubBLK1 and/or SubBLK2). The memory device 10 may provide one spare memory block to support reliability, availability, and serviceability (RAS) required by a memory controller. The memory device 10 may provide a single memory block (e.g., BLK1) as a spare memory block. In this case, the memory device 10 may provide a memory capacity of 1100 MB that is the sum of 1 GB (i.e., 1000 MB) user capacity and 100 MB spare memory block capacity. The memory device 10 may provide one of the first and second sub-blocks SubBLK1 and SubBLK2 as a spare memory block. In this case, the memory device 10 may provide a memory capacity of 1050 MB that is the sum of 1 GB (i.e., 1000 MB) user capacity and 50 MB spare memory block capacity. In other words, the memory device 10 may provide a memory capacity less than 1100 MB. As described above, the memory capacity of the memory device 10 may be reduced when a sub-block is provided as a spare memory block, and accordingly, the chip size of the memory device 10 may be reduced.

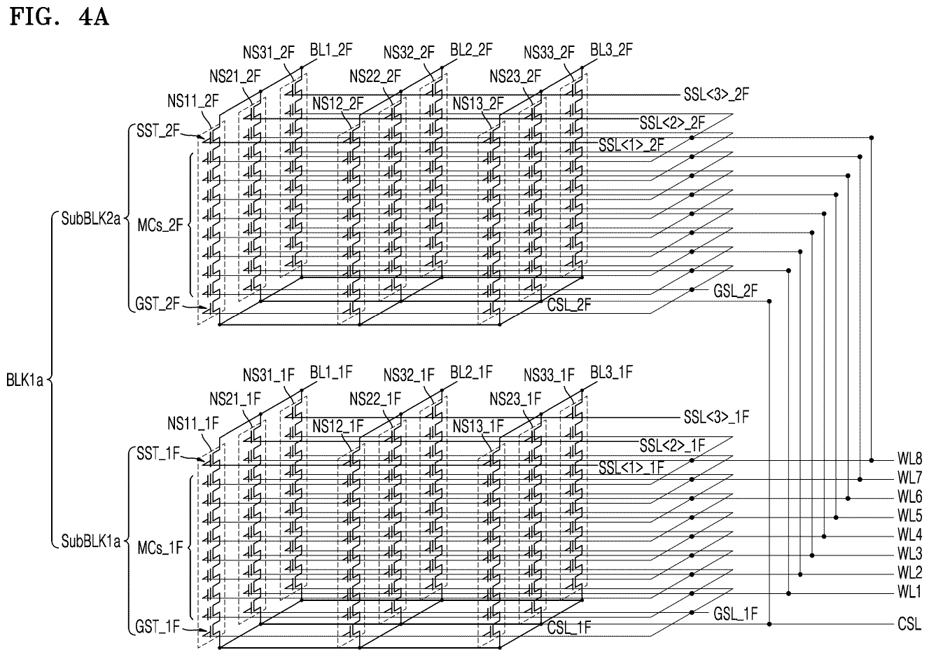

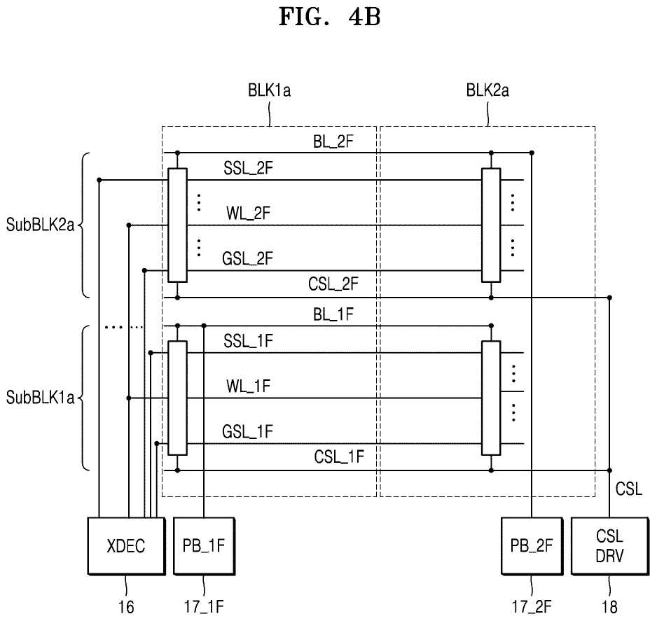

FIGS. 4A and 4B are diagrams illustrating an example of a memory block according to some implementations. Hereinafter, a suffix of like reference numerals (e.g., “a” in BLK1a, “b” in BLK1b, or “c” in BLK1c) in the drawings is used to distinguish from other components having the same or similar functions. Redundant descriptions of the memory block BLK1 of FIGS. 3A and 3B are omitted from the descriptions of a memory block BLK1a.

In FIG. 4A, the memory block BLK1a may include a first sub-block SubBLK1a and a second sub-block SubBLK2a. The memory block BLK1a is different from the memory block BLK1 of FIG. 3A in that the common source line CSL_1F of the first sub-block SubBLK1a and the common source line CSL_2F of the second sub-block SubBLK2a are connected to a single common source line CSL. In FIG. 4B, the CSL driver 18 connected to the common source line CSL may drive the common source line CSL_1F of the first sub-block SubBLK1a and the common source line CSL_2F of the second sub-block SubBLK2a according to the operation modes.

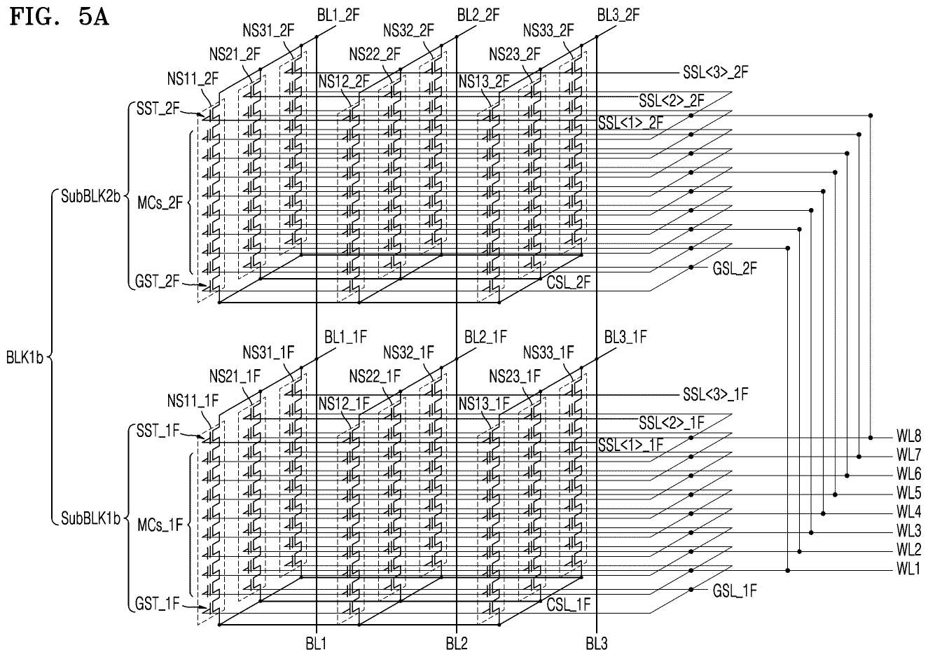

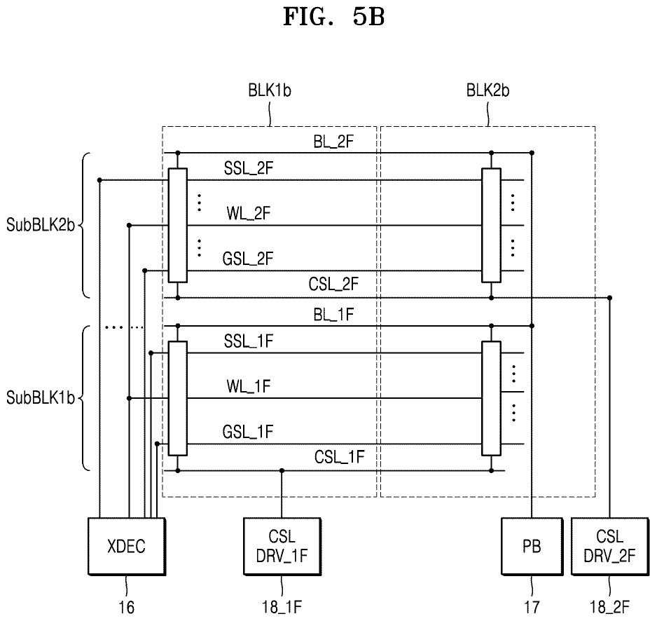

FIGS. 5A and 5B are diagrams illustrating an example of a memory block according to some implementations. Redundant descriptions of the memory block BLK1 of FIGS. 3A and 3B are omitted from the descriptions of a memory block BLK1b of FIGS. 5A and 5B.

In FIG. 5A, the memory block BLK1b may include a first sub-block SubBLK1b and a second sub-block SubBLK2b. The memory block BLK1b is different from the memory block BLK1 of FIG. 3A in that the bit lines BL1_1F, BL2_1F, and BL3_1F of the first sub-block SubBLK1b and the bit lines BL1_2F, BL2_2F, and BL3_2F of the second sub-block SubBLK2b are respectively connected to each other and respectively connected to bit lines BL1, BL2, and BL3, respectively (for example, the bit line BL1_1F and the bit line BL1_2F are connected to each other and connected to the bit line BL1, the bit line BL1_2F and the bit line BL2_2F are connected to each other and connected to the bit line BL2, and the bit line BL3_1F and the bit line BL3_2F are connected to each other and connected to the bit line BL3). Referring to FIG. 5B, the page buffer 17 may drive the bit lines BL_1F, i.e., BL1_1F, BL2_1F, and BL3_1F, of the first sub-block SubBLK1b and the bit lines BL_2F, i.e., BL1_2F, BL2_2F, and BL3_2F, of the second sub-block SubBLK2b according to the operation modes.

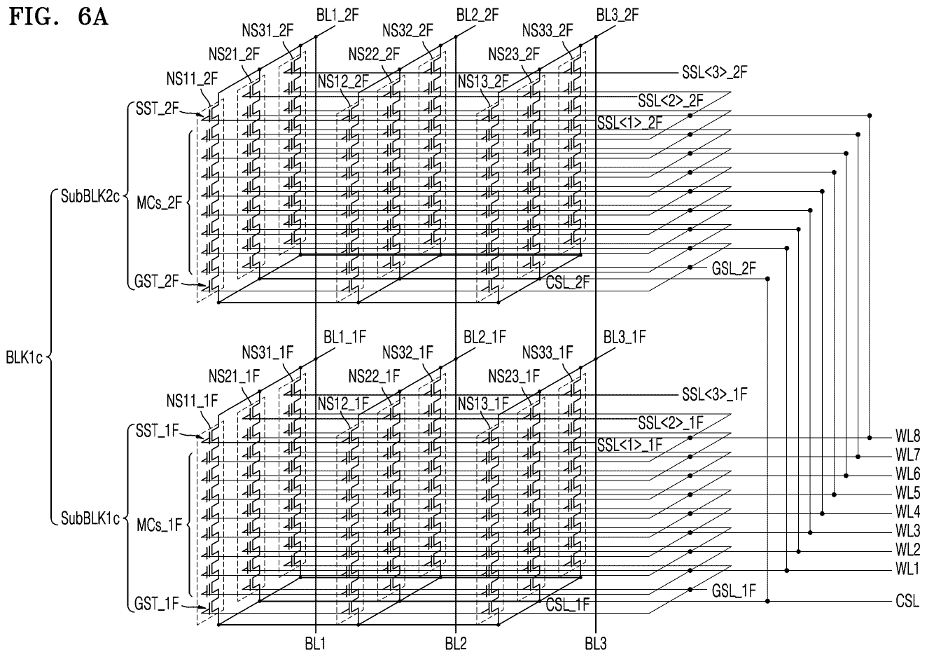

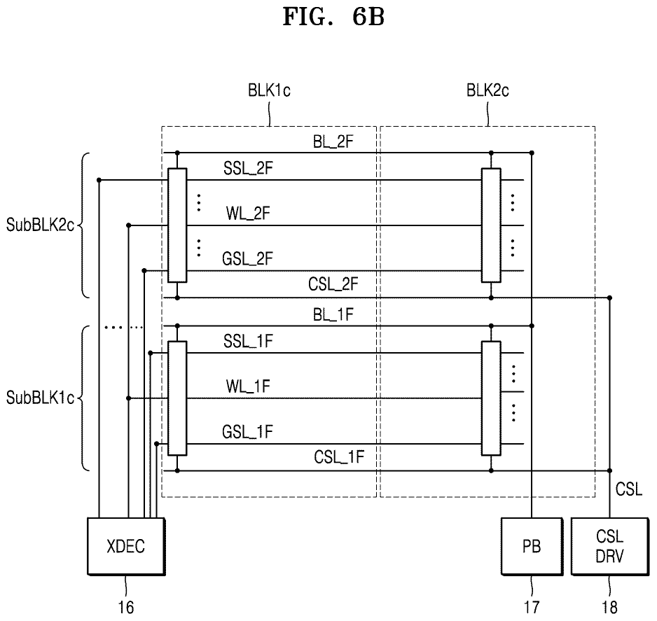

FIGS. 6A and 6B are diagrams illustrating an example of a memory block according to some implementations. Redundant descriptions of the memory block BLK1 of FIGS. 3A and 3B are omitted from the descriptions of a memory block BLK1c of FIGS. 6A and 6B.

In FIG. 6A, the memory block BLK1c may include a first sub-block SubBLK1c and a second sub-block SubBLK2c. The memory block BLK1c is different from the memory block BLK1 of FIG. 3A in that the bit lines BL1_1F, BL2_1F, and BL3_1F of the first sub-block SubBLK1c and the bit lines BL1_2F, BL2_2F, and BL3_2F of the second sub-block SubBLK2c are respectively connected to each other and respectively connected to the bit lines BL1, BL2, and BL3, and the common source line CSL_1F of the first sub-block SubBLK1c and the common source line CSL_2F of the second sub-block SubBLK2c may be connected to one common source line CSL. Referring to FIG. 6B, the page buffer 17 may drive the bit lines BL_1F, i.e., BL1_1F, BL2_1F, and BL3_1F, of the first sub-block SubBLK1c and the bit lines BL_2F, i.e., BL1_2F, BL2_2F, and BL3_2F, of the second sub-block SubBLK2c according to the operation modes, and the CSL driver 18 connected to the common source line CSL may drive the common source line CSL_1F of the first sub-block SubBLK1c and the common source line CSL_2F of the second sub-block SubBLK2c according to the operation modes.

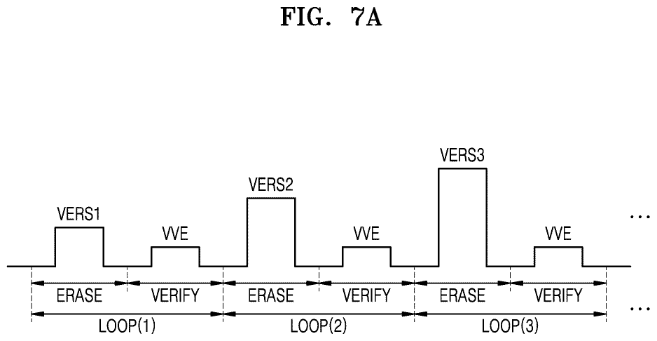

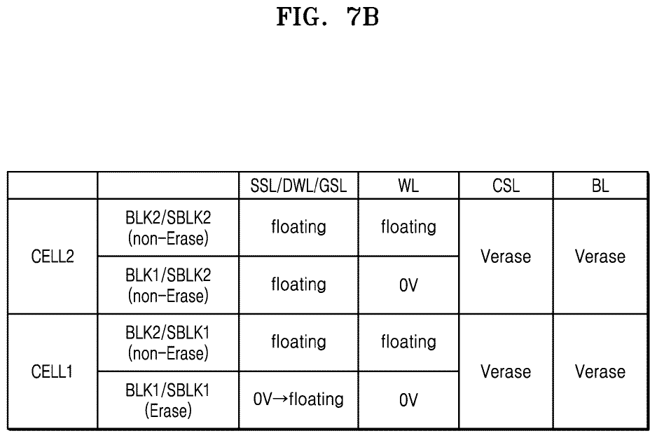

FIGS. 7A to 10 are diagrams illustrating an example of an erase operation of the memory device 10 according to some implementations.

FIG. 7A illustrates an erase operation performed on the memory block BLK1, which has been described with reference to FIGS. 4A and 4B, by using an incremental step pulse erasing (ISPE) method. In FIG. 7A, a plurality of erase loops (e.g., LOOP(1), LOOP(2), LOOP(3), . . . ) may be sequentially performed such that the erase operation is completely performed according to ISPE. When erase loops are repeated, erase voltages (e.g., VERS1, VERS2, VERS3, . . . , and sometimes, denoted by Verase) may increase stepwise. Each erase loop LOOP(i) may include an erase period ERASE and an erase verify period VERIFY, where “i” is a positive integer. To erase memory cells during the erase period ERASE, the erase voltages (VERS1, VERS2, VERS3, . . . ) may be applied to channels, and an erase enabling voltage may be applied to word lines. Thereafter, to verify whether an erase is successful during the erase verify period VERIFY, an erase verify voltage VVE may be applied to word lines. An erase operation and an erase verify operation may be repeatedly performed while the erase voltages (VERS1, VERS2, VERS3, . . . ) are being increased stepwise until an erase pass condition is satisfied. The erase pass condition may indicate the maximum allowable number of incompletely erased memory cells having a threshold voltage that is higher than the erase verify voltage VVE among selected memory cells to be erased. Erase loops may be repeated such that the number of incompletely erased memory cells is less than the maximum allowable number.

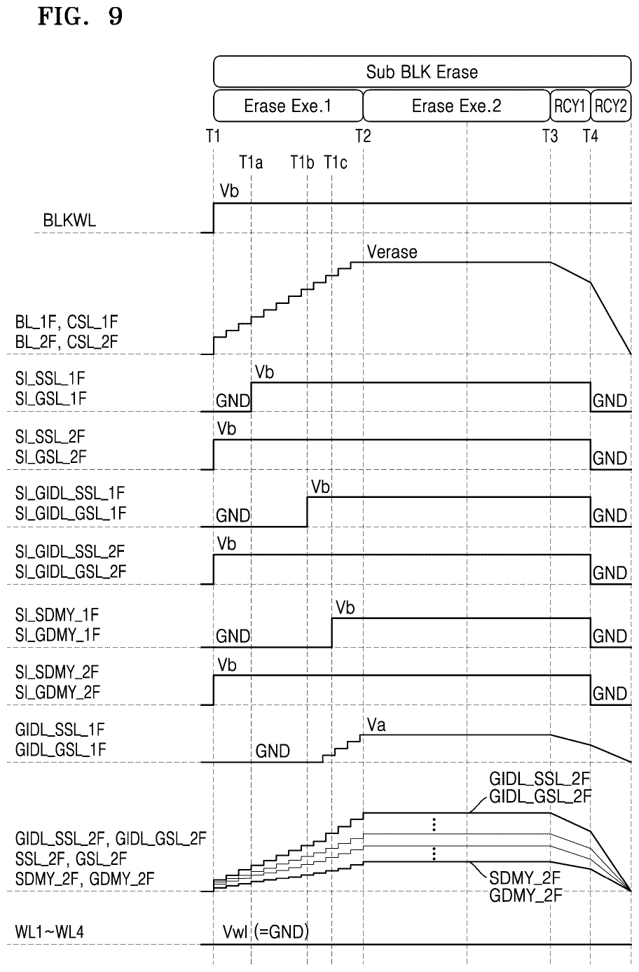

In FIG. 9, the erase period of a first erase loop LOOP(1) is described. A period between a time point T1 and a time point T2 may be referred to as a first erase period Erase Exe.1, and a period between a time point T2 and a time point T3 may be referred to as a second erase period Erase Exe.2. This is just an example only intended for help with understanding and does not limit the inventive concept. The other erase loops (LOOP(2), LOOP(3), . . . ) are the same as the first erase loop LOOP(1), except that the erase voltages (VERS1, VERS2, VERS3, . . . ) applied to channels during respective erase periods increase stepwise.

FIG. 7B is a table showing bias conditions in an erase operation of the memory block BLK1. FIGS. 8 to 10 are diagrams illustrating voltage changes and a method of controlling the memory block BLK1, according to the bias conditions of FIG. 7B. The bias conditions of FIG. 7B in the erase operation may also be applied to the memory block BLK1a of FIGS. 4A and 4B, the memory block BLK1b of FIGS. 5A and 5B, and the memory block BLK1c of FIGS. 6A and 6B.

In FIGS. 4A, 4B, and 7B, the first sub-block SubBLK1a of the first memory block BLK1a may be assumed to be erased. Accordingly, the second sub-block SubBLK2a of the first memory block BLK1a and the first sub-block SubBLK1a and the second sub-block SubBLK2a of the second memory block BLK2a may be unselected sub-blocks. Hereinafter, for convenience of description, the first sub-block SubBLK1a of the first memory block BLK1a undergoing an erase operation may be referred to as a selected sub-block SubBLK1 (or, BLK1/SBLK1), the second sub-block SubBLK2a of the first memory block BLK1a may be referred to as a sister sub-block SubBLK2 (or, BLK1/SBLK2), and the first sub-block SubBLK1a and the second sub-block SubBLK2a of the second memory block BLK2a may be referred to as unselected sub-blocks SubBLK2 (or, BLK2/SBLK1 and BLK2/SBLK2). The first memory block BLK1a may be referred to a first memory block BLK1 and the second memory block BLK2a may be referred to a second memory block BLK2.

In an erase operation, an erase voltage Verase may be applied to a common source line CSL and a bit line BL in each of the first cell region CELL1 and the second cell region CELL2 of the memory device 10. The common source line CSL in the first cell region CELL1 may refer to the common source line CSL_1F of the first sub-blocks SubBLK1 of the first memory block BLK1 and the second memory block BLK2. The bit line BL in the first cell region CELL1 may refer to the bit lines BL1_1F, BL2_1F, and BL3_1F of the first sub-blocks SubBLK1 of the first memory block BLK1 and the second memory block BLK2. The common source line CSL in the second cell region CELL2 may refer to the common source line CSL_2F of the second sub-blocks SubBLK2 of the first memory block BLK1 and the second memory block BLK2. The bit line BL in the second cell region CELL2 may refer to the bit lines BL1_2F, BL2_2F, and BL3_2F of the second sub-blocks SubBLK2 of the first memory block BLK1 and the second memory block BLK2. In other words, the first sub-blocks SubBLK1 of the first memory block BLK1 and the second memory block BLK2 may share the common source line CSL_1F and the bit line BL_1F, and the second sub-blocks SubBLK2 of the first memory block BLK1 and the second memory block BLK2 may share the common source line CSL_2F and the bit line BL_2F.

When a ground voltage GND is applied to a string select line SSL, a dummy word line DWL, and a ground select line GSL in the selected sub-block, i.e., the first sub-block SubBLK1 of the first memory block BLK1, a string select transistor (SST), dummy memory cells, and a ground select transistor (GST) of the selected sub-block may be turned off. The ground voltage GND may be applied to word lines WL. When the potentials of the bit line BL and the common source line CSL increase to the level of the erase voltage Verase in the state where the SST, the dummy memory cells, and the GST are turned off, leakage current may flow between the drain of the SST and the bit line BL and between the drain of the GST and the common source line CSL, and accordingly, gate-induced drain leakage (GIDL) current may flow in the channel direction of cell strings. Accordingly, hot holes generated in the SST and the GST may flow into the channel direction, causing channel potential to increase to the level of the erase voltage Verase. Thereafter, the string select line SSL, the dummy word line DWL, and the ground select line GSL may float. When the channel potential of the cell strings NS increases to the level of the erase voltage Verase, the difference between channel potential and the potential (i.e., the ground voltage GND) of the word lines WL may be greater than the magnitude required to erase a memory cell, thereby erasing the memory cells MCs of the selected sub-block.

GIDL is a phenomenon in which leakage occurs in the drain of a transistor due to the gate of the transistor. For example, when 0 V or a negative voltage is applied to the gate and a sufficiently high positive voltage is applied to the drain, oxide near the drain may be energized that is high at the gate and low at the drain. In this case, because there is so much band bending in silicon (Si) itself, band-to-band tunneling of electrons occurs from the valence band of a silicon surface to the conduction band of a silicon bulk. These tunneled electrons are attracted to a drain electrode, eventually increasing drain current. At this time, because a substrate is usually biased to the ground, holes are attracted to the substrate that is relatively lower than the drain. In general, that a gate voltage is at a negative voltage level means that in a situation in which a transistor is to be turned off, the transistor operates as if the transistor is turned on because drain current increases due to GIDL. In this GIDL phenomenon, GIDL current increases as the gate has a negative voltage and the drain has an increasing positive voltage. By using this GIDL, the channel of a cell string may be precharged or boosted. To generate GIDL, a string select transistor or ground select transistor of a cell string or a GIDL transistor may be used.

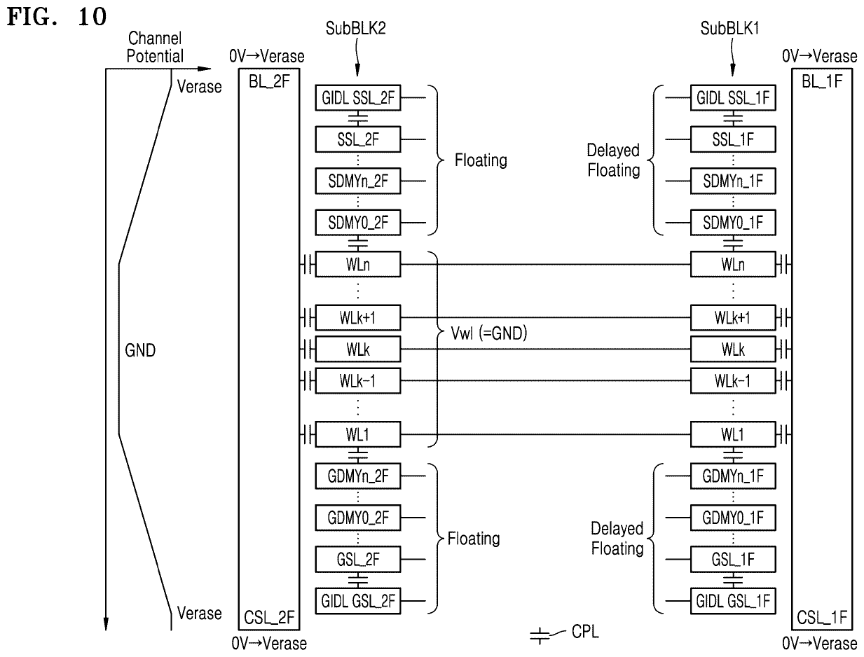

In an unselected sub-block, e.g., the first sub-block SubBLK1 of the second memory block BLK2, the string select line SSL, the dummy word line DWL, the ground select line GSL, and the word lines WL may float. Because the first sub-block SubBLK1 of the second memory block BLK2 shares the common source line CSL and the bit line BL with the first sub-block SubBLK1 of the first memory block BLK1, the erase voltage Verase may be applied to the common source line CSL and the bit line BL. When the potential of the common source line CSL and the bit line BL increases, the channel potential of the cell strings NS may increase along the potential of the common source line CSL and the bit line BL, and the potential of the word lines WL that float may also increase along the channel potential due to capacitive coupling (e.g., CPL in FIG. 10). Accordingly, the potential difference between the word line WL and a channel may be maintained to be less than the magnitude required to erase a memory cell so that the memory cells MCs of the unselected sub-block are not erased.

In a sister sub-block, e.g., the second sub-block SubBLK2 of the first memory block BLK1, the string select line SSL, the dummy word line DWL, and the ground select line GSL may float. Because the word lines WL of the first sub-block SubBLK1 of the first memory block BLK1 are respectively connected to the word lines WL of the second sub-block SubBLK2 of the first memory block BLK1, the ground voltage GND applied to the word lines WL of the first sub-block SubBLK1 of the first memory block BLK1 may also be applied to the word lines WL of the second sub-block SubBLK2 of the first memory block BLK1. When the potential of the common source line CSL and the bit line BL increases to the erase voltage Verase, the potential of the string select line SSL, the dummy word line DWL, and the ground select line GSL, which float, may also increase along the level of the erase voltage Verase due to capacitive coupling. Accordingly, the SST, the dummy memory cells, and the GST may be turned off, and the channel potential of the cell strings NS may have the level of the ground voltage GND. Because there is no substantial potential difference between the word lines WL and a channel, the memory cells MCs of the sister sub-block may not be erased.

In some implementations, the channel potential of the cell strings NS of the sister sub-block, i.e., the second sub-block SubBLK2 of the first memory block BLK1, may have a higher voltage level than the ground voltage GND. To prevent the memory cells MCs of the sister sub-block from being erased, the memory device 10 may be designed such that there is no substantial potential difference between the word lines WL and a channel. A word line voltage Vwl, which is very small and corresponds to the channel potential, may be applied to the word lines WL of the second sub-block SubBLK2 of the first memory block BLK1. In this case, because the word lines WL of the second sub-block SubBLK2 of the first memory block BLK1 are respectively connected to the word lines WL of the first sub-block SubBLK1 of the first memory block BLK1, the word line voltage Vwl may also be applied to the word lines WL of the first sub-block SubBLK1 of the first memory block BLK1. In practice, the word line voltage Vwl may be set to a level close to the ground voltage GND.

In an unselected sub-block, e.g., the second sub-block SubBLK2 of the second memory block BLK2, the string select line SSL, the dummy word line DWL, the ground select line GSL, and the word lines WL may float. Because the second sub-block SubBLK2 of the second memory block BLK2 shares the common source line CSL and the bit line BL with the second sub-block SubBLK2 of the first memory block BLK1, the erase voltage Verase may be applied to the common source line CSL and the bit line BL. When the potential of the common source line CSL and the bit line BL increases, the channel potential of the cell strings NS may increase along the potential of the common source line CSL and the bit line BL, and the potential of the word lines WL that float may also increase along the channel potential due to capacitive coupling. Accordingly, the potential difference between the word line WL and a channel may be maintained to be less than the magnitude required to erase a memory cell so that the memory cells MCs of the unselected sub-block are not erased.

In FIG. 8, the memory device 10 may include the row decoder 16 and a pass transistor circuit 40 connected between the row decoder 16 and the memory block BLK1. The memory block BLK1 may include first ground select lines GIDL_GSL_1F and GIDL_GSL_2F, second ground select lines GSL_1F and GSL_2F, first dummy word lines GDMY_1F and GDMY_2F, word lines WL1 to WL4, second dummy word lines SDMY_1F and SDMY_2F, second string select lines SSL_1F and SSL_2F, and first string select lines GIDL_SSL_1F and GIDL_SSL_2F. To simplify connection relationships in the present disclosure, one second string select line SSL_1F is illustrated in the first sub-block SubBLK1 of the memory block BLK1, and one second string select line SSL_2F is illustrated in the second sub-block SubBLK2 of the memory block BLK1. In practice, the second string select line SSL_1F may include a plurality of signal lines respectively connected to a plurality of string select lines (e.g., SSL<1>_1F, SSL<2>_1F, and SSL<3>_1F (in FIG. 3A)), and the second string select line SSL_2F may include a plurality of signal lines respectively connected to a plurality of string select lines (e.g., SSL<1>_2F, SSL<2>_2F, and SSL<3>_2F (in FIG. 3A)). According to some implementations, the first ground select lines GIDL_GSL_1F and GIDL_GSL_2F, the second ground select lines GSL_1F and GSL_2F, the first dummy word lines GDMY_1F and GDMY_2F, the second dummy word lines SDMY_1F and SDMY_2F, and the first string select lines GIDL_SSL_1F and GIDL_SSL_2F may each include a plurality of signal lines.

The row decoder 16 may include a block decoder 21 and a driving signal line decoder 22. The pass transistor circuit 40 may include a plurality of pass transistors TR01, TR11, TR21, TR31, TR41, TR51, TR61, TR71, TR81, TR91, TR02, TR12, TR22, TR72, TR82, and TR92. The pass transistor circuit 40 may be provided for each of memory blocks (e.g., BLK1 to BLKn in FIG. 2). The block decoder 21 and the driving signal line decoder 22 may be provided in common for the memory blocks (BLK1 to BLKn).

The block decoder 21 may provide a block select signal BLKWL to the pass transistor circuit 40. The block select signal BLKWL may select one (e.g., BLK1) of the memory blocks (BLK1 to BLKn). The block select signal BLKWL may be applied to the respective gates of the pass transistors TR01, TR11, TR21, TR31, TR41, TR51, TR61, TR71, TR81, TR91, TR02, TR12, TR22, TR72, TR82, and TR92 of the memory block BLK1. When the block select signal BLKWL is activated, the pass transistors TR01, TR11, TR21, TR31, TR41, TR51, TR61, TR71, TR81, TR91, TR02, TR12, TR22, TR72, TR82, and TR92 of the memory block BLK1 may be turned on.

The driving signal line decoder 22 may provide first ground select line driving signals SI_GIDL_GSL_1F and SI_GIDL_GSL_2F, second ground select line driving signals SI_GSL_1F and SI_GSL_2F, first dummy word line driving signals SI_GDMY_1F and SI_GDMY_2F, word line driving signals SI_WL1 to SI_WL4, second dummy word line driving signals SI_SDMY_1F and SI_SDMY_2F, second string select line driving signals SI_SSL_1F and SI_SSL_2F, and first string select line driving signals SI_GIDL_SSL_1F and SI_GIDL_SSL_2F to the pass transistor circuit 40. The first ground select line driving signals SI_GIDL_GSL_1F and SI_GIDL_GSL_2F, the second ground select line driving signals SI_GSL_1F and SI_GSL_2F, the first dummy word line driving signals SI_GDMY_1F and SI_GDMY_2F, the word line driving signals SI_WL1 to SI_WL4, the second dummy word line driving signals SI_SDMY_1F and SI_SDMY_2F, the second string select line driving signals SI_SSL_1F and SI_SSL_2F, and the first string select line driving signals SI_GIDL_SSL_1F and SI_GIDL_SSL_2F may be respectively applied to the respective sources of the pass transistors TR01, TR02, TR11, TR12, TR21, TR22, TR31, TR41, TR51, TR61, TR71, TR72, TR81, TR82, TR91, and TR92.

The pass transistor circuit 40 may include a first pass transistor circuit 41, which is connected to the first sub-block SubBLK1 of the memory block BLK1, and a second pass transistor circuit 42, which is connected to the second sub-block SubBLK2 of the memory block BLK1. The first pass transistor circuit 41 may transmit the first ground select line driving signal SI_GIDL_GSL_1F, the second ground select line driving signal SI_GSL_1F, the first dummy word line driving signal SI_GDMY_1F, the word line driving signals SI_WL1 to SI_WL4, the second dummy word line driving signal SI_SDMY_1F, the second string select line driving signal SI_SSL_1F, and the first string select line driving signal SI_GIDL_SSL_1F to the first ground select line GIDL_GSL_1F, the second ground select line GSL_1F, the first dummy word line GDMY_1F, the word lines WL1 to WL4, the second dummy word line SDMY_1F, the second string select line SSL_1F, and the first string select line GIDL_SSL_1F, respectively, through the pass transistors TR01, TR11, TR21, TR31, TR41, TR51, TR61, TR71, TR81, and TR91, respectively, which are turned on in response to the activation of the block select signal BLKWL.

The second pass transistor circuit 42 may transmit the first ground select line driving signal SI_GIDL_GSL_2F, the second ground select line driving signal SI_GSL_2F, the first dummy word line driving signal SI_GDMY_2F, the second dummy word line driving signal SI_SDMY_2F, the second string select line driving signal SI_SSL_2F, and the first string select line driving signal SI_GIDL_SSL_2F to the first ground select line GIDL_GSL_2F, the second ground select line GSL_2F, the first dummy word line GDMY_2F, the second dummy word line SDMY_2F, the second string select line SSL_2F, and the first string select line GIDL_SSL_2F, respectively, through the pass transistors TR02, TR12, TR22, TR72, TR82, and TR92, respectively, which are turned on in response to the activation of the block select signal BLKWL. The second pass transistor circuit 42 may be different from the first pass transistor circuit 41 in that there are no pass transistors that provide the voltage levels of the word line driving signals SI_WL1 to SI_WL4 to the word lines WL1 to WL4 of the second sub-block SubBLK2 of the memory block BLK1. The word lines WL1 to WL4 of the second sub-block SubBLK2 of the memory block BLK1 may be provided with the voltage levels of the word line driving signals SI_WL1 to SI_WL4 through the pass transistors TR31, TR41, TR51, and TR61 of the first pass transistor circuit 41.

The timing diagram of FIG. 9 shows a sub-block erase operation (Sub BLK Erase) in connection with FIG. 8, in which the block select signal BLKWL that selects the memory block BLK1 may be activated at the time point T1. The block select signal BLKWL may be provided at the level of a first voltage Vb that is higher than or equal to a power supply voltage VDD. The erase voltage Verase increasing stepwise may be applied to the common source line CSL_1F and the bit line BL_1F of the first sub-block SubBLK1 of the memory block BLK1 and the common source line CSL_2F and the bit line BL_2F of the second sub-block SubBLK2 of the memory block BLK1. The level of the erase voltage Verase may increase starting from the time point T1, at which the erase voltage Verase starts to be applied, to the time point T2, and the erase voltage Verase may become a high voltage at the time point T2.

At the time point T1, the level of the ground voltage GND may be provided to the second string select line driving signal SI_SSL_1F, the second ground select line driving signal SI_GSL_1F, the first ground select line driving signal SI_GIDL_GSL_1F, the first string select line driving signal SI_GIDL_SSL_1F, the first dummy word line driving signal SI_GDMY_1F, and the second dummy word line driving signal SI_SDMY_1F. Because the word lines WL1 to WL4 of the first sub-block SubBLK1 of the memory block BLK1 are respectively connected to the word lines WL1 to WL4 of the second sub-block SubBLK2 of the memory block BLK1, the word line voltage Vwl having the level of the ground voltage GND may be applied to the word lines WL1 to WL4 of the first sub-block SubBLK1 and the second sub-block SubBLK2 of the memory block BLK1.

In a period between the time point T1 and the time point T2, the second string select line driving signal SI_SSL_1F, the second ground select line driving signal SI_GSL_1F, the first ground select line driving signal SI_GIDL_GSL_1F, the first string select line driving signal SI_GIDL_SSL_1F, the first dummy word line driving signal SI_GDMY_1F, and the second dummy word line driving signal SI_SDMY_1F, which are at the level of the ground voltage GND, may be sequentially provided at the level of the first voltage Vb to the first sub-block SubBLK1 of the memory block BLK1. For example, at a time point T1a, the second string select line driving signal SI_SSL_1F and the second ground select line driving signal SI_GSL_1F may be applied at the level of the first voltage Vb so that the second string select line SSL_1F and the second ground select line GSL_1F may float. At a time point T1b, the first ground select line driving signal SI_GIDL_GSL_1F and the first string select line driving signal SI_GIDL_SSL_1F may be applied at the level of the first voltage Vb so that the first string select line GIDL_SSL_1F and the first ground select line GIDL_GSL_1F may float. At a time point T1c, the first dummy word line driving signal SI_GDMY_1F and the second dummy word line driving signal SI_SDMY_1F may be applied at the level of the first voltage Vb so that the first dummy word line GDMY_1F and the second dummy word line SDMY_1F may float.

In the period between the time points T1 and T2, when the potential of the common source line CSL_2F and the bit line BL_2F of the second sub-block SubBLK2 of the memory block BLK1 increases to the erase voltage Verase, the potential of the first string select line GIDL_SSL_2F, the first ground select line GIDL_GSL_2F, the second string select line SSL_2F, the second ground select line GSL_2F, the second dummy word line SDMY_2F, and the first dummy word line GDMY_2F, which are in a floating state, may increase along the erase voltage Verase due to a coupling effect.

In a period between the time point T2 and the time point T3, the erase voltage Verase at a high level may be applied to the common source line CSL_1F and the bit line BL_1F of the first sub-block SubBLK1 of the memory block BLK1 and the common source line CSL_2F and the bit line BL_2F of the second sub-block SubBLK2 of the memory block BLK1. Due to coupling to the erase voltage Verase of the common source line CSL_1F and the bit line BL_1F of the first sub-block SubBLK1, the potential of the first ground select line GIDL_GSL_1F and the first string select line GIDL_SSL_1F, which float in the first sub-block SubBLK1, may increase to a level of a second voltage Va and may be proportional to the increase in the erase voltage Verase, which is applied to the common source line CSL_1F and the bit line BL_1F after the time point T1b.

In the first sub-block SubBLK1 of the memory block BLK1, GIDL current caused by the SST and the GST may flow in the channel direction, and hot holes generated in the drains of the SST and the GST may flow in the channel direction so that the channel potential of the cell strings NS of the first sub-block SubBLK1 may increase to the level of the erase voltage Verase. When the channel potential of the cell strings NS of the first sub-block SubBLK1 increases to the level of the erase voltage Verase, the difference between the channel potential and the word line voltage Vwl of the word lines WL1 to WL4 may be greater than the magnitude required to erase a memory cell so that the memory cells MCs of the first sub-block SubBLK1 may be erased.

Due to coupling to the erase voltage Verase of the common source line CSL_2F and the bit line BL_2F of the second sub-block SubBLK2 of the memory block BLK1, the potential of the first string select line GIDL_SSL_2F, the first ground select line GIDL_GSL_2F, the second string select line SSL_2F, the second ground select line GSL_2F, the second dummy word line SDMY_2F, and the first dummy word line GDMY_2F, which float in the second sub-block SubBLK2, may increase.

In the period between the time point T2 and the time point T3, the first string select line GIDL_SSL_2F, the first ground select line GIDL_GSL_2F, the second string select line SSL_2F, the second ground select line GSL_2F, the second dummy word line SDMY_2F, and the first dummy word line GDMY_2F, which float in the second sub-block SubBLK2 of the memory block BLK1, may be coupled to different voltage levels according to the physical distances to the common source line CSL_2F and the bit line BL_2F. The first ground select line GIDL_GSL_2F close to the common source line CSL_2F and the first string select line GIDL_SSL_2F close to the bit line BL_2F may increase to a relatively high voltage level close to the level of the erase voltage Verase. The first dummy word line GDMY_2F far from the common source line CSL_2F and the second dummy word line SDMY_2F far from the bit line BL_2F may increase to a level that is higher than the level of the ground voltage GND applied to the word lines WL1 to WL4.

In the period between the time point T2 and the time point T3, because the word lines WL1 to WL4 of the first sub-block SubBLK1 of the memory block BLK1 are respectively connected to the word lines WL1 to WL4 of the second sub-block SubBLK2 of the memory block BLK1, the ground voltage GND applied to the word lines WL1 to WL4 of the first sub-block SubBLK1 of the memory block BLK1 may also be applied to the word lines WL1 to WL4 of the second sub-block SubBLK2 of the memory block BLK1. When the potential of the common source line CSL_2F and the bit line BL_2F of the second sub-block SubBLK2 of the memory block BLK1 increases to the level of the erase voltage Verase, the potential of the first ground select line GIDL_GSL_2F and the first string select line GIDL_SSL_2F, which are in a floating state, may increase to the level of the erase voltage Verase due to a coupling effect. Accordingly, the GST and the SST of the second sub-block SubBLK2 may be turned off so that the channel potential is coupled to the voltage levels of the second string select line SSL_2F, the second ground select line GSL_2F, the second dummy word line SDMY_2F, and the first dummy word line GDMY_2F, which sequentially decrease due to capacitive coupling. As a result, there may be no substantial potential difference between a channel and the word lines WL1 to WL4, so that the memory cells MCs of the second sub-block SubBLK2 may not be erased.

At the time point T3, an erase recovery operation may be performed on the memory block BLK1. At the time point T3, the level of the erase voltage Verase, which is applied to the common source line CSL_1F and the bit line BL_1F of the first sub-block SubBLK1 of the memory block BLK1 and the common source line CSL_2F and the bit line BL_2F of the second sub-block SubBLK2 of the memory block BLK1, may start to decrease. At a time point T4, the first ground select line driving signals SI_GIDL_GSL_1F and SI_GIDL_GSL_2F, the first string select line driving signals SI_GIDL_SSL_1F and SI_GIDL_SSL_2F, the second ground select line driving signals SI_GSL_1F and SI_GSL_2F, the second string select line driving signals SI_SSL_1F and SI_SSL_2F, the first dummy word line driving signals SI_GDMY_1F and SI_GDMY_2F, and the second dummy word line driving signals SI_SDMY_1F and SI_SDMY_2F of the first sub-block SubBLK1 and the second sub-block SubBLK2 may be recovered to the level of the ground voltage GND. A period between the time point T3 and the time point T4 may be referred to as a first erase recovery period RCY1, and a period after the time point T4 may be referred to as a second erase recovery period RCY2.

In some implementations, in the period between the time point T2 and the time point T4, the level of the word line voltage Vwl applied to the word lines WL1 to WL4 of the first sub-block SubBLK1 and the word lines WL1 to WL4 of the second sub-block SubBLK2 in the memory block BLK1 may be different from the level of the ground voltage GND. In a 3D cell string structure, e.g., a structure illustrated in FIG. 31, as the diameter of a pillar of a vertical channel structure CH increases, the effective area of a conductive layer forming the word lines WL1 to WL4 may decrease, thereby increasing resistance. In addition, capacity formed between membrane layers may also increase. Accordingly, as the diameter of the pillar increases, the coupling capacity and resistance of a cell transistor may increase. Consequently, there may be cell transistors on which an erase operation is rapidly performed due to the difference between the resistance and the capacity of the cell transistors. To slow down the erasing speed of the cell transistors, a voltage, e.g., the power supply voltage VDD of the memory device 10, which has a higher level than the ground voltage GND, may be applied to the word lines WL1 to WL4.

FIG. 10 shows channel potential of the first sub-block SubBLK1, which is a selected sub-block of the memory block BLK1, and the second sub-block SubBLK2, which is a sister sub-block of the first sub-block SubBLK1, during the second erase period Erase Exe.2 between the time points T2 and T3 in FIG. 9.

In FIG. 10, in the first sub-block SubBLK1 of the memory block BLK1, the erase voltage Verase may be applied to the common source line CSL_1F and the bit line BL_1F. The first string select line GIDL_SSL_1F, the second string select line SSL_1F, and second dummy word lines SDMY0_1F to SDMYn_1F may sequentially float with a delay at the level of the ground voltage GND. The word line voltage Vwl having the level of the ground voltage GND may be applied to word lines WL1 to WLn. The second ground select line GSL_1F, the first ground select line GIDL_GSL_1F, and first dummy word lines GDMY0_1F to GDMYn_1F may sequentially float with a delay at the level of the ground voltage GND. Due to coupling to the erase voltage Verase of the common source line CSL_1F and the bit line BL_1F, GIDL current caused by an SST and a GST of the first sub-block SubBLK1 may flow in a channel direction, and hot holes generated in the SST and the GST may flow in the channel direction so that the channel potential of the cell strings NS of the first sub-block SubBLK1 may increase to the level of the erase voltage Verase. The difference between the channel potential (e.g., Verase) and the potential (e.g., the ground voltage GND) of the word lines WL1 to WLn may be greater than the magnitude required to erase a memory cell so that the memory cells MCs of the first sub-block SubBLK1 may be erased.

In the second sub-block SubBLK2 of the memory block BLK1, the erase voltage Verase may be applied to the common source line CSL_2F and the bit line BL_2F. Due to coupling to the erase voltage Verase of the bit line BL_2F, the potential of the first string select line GIDL_SSL_2F, the second string select line SSL_2F, and second dummy word lines SDMY0_2F to SDMYn_2F, which float, may increase. Because the word lines WL1 to WLn of the first sub-block SubBLK1 are respectively connected to the word lines WL1 to WLn of the second sub-block SubBLK2, the word line voltage Vwl having the level of the ground voltage GND may be applied to the word lines WL1 to WLn. Due to coupling to the erase voltage Verase of the common source line CSL_2F, the potential of the first ground select line GIDL_GSL_2F, the second ground select line GSL_2F, and first dummy word lines GDMY0_2F to GDMYn_2F may increase. Due to coupling to the erase voltage Verase of the bit line BL_2F, the potential of the first string select line GIDL_SSL_2F, the second string select line SSL_2F, and the second dummy word lines SDMY0_2F to SDMYn_2F may increase. Because the first ground select line GIDL_GSL_2F close to the common source line CSL_2F and the first string select line GIDL_SSL_2F closed to the bit line BL_2F are coupled to a high voltage level, the GST and the SST of the second sub-block SubBLK2 may be turned off. The channel potential of the second sub-block SubBLK2 may be coupled to the voltage levels of the second string select line SSL_2F, the second ground select line GSL_2F, the second dummy word lines SDMY0_2F to SDMYn_2F, and the first dummy word lines GDMY0_2F to GDMYn_2F, which sequentially decrease due to capacitive coupling, and thus gradually become the level of the ground voltage GND. Accordingly, there may be no substantial potential difference between a channel and the word lines WL1 to WLn, so that the memory cells MCs of the second sub-block SubBLK2 may not be erased.

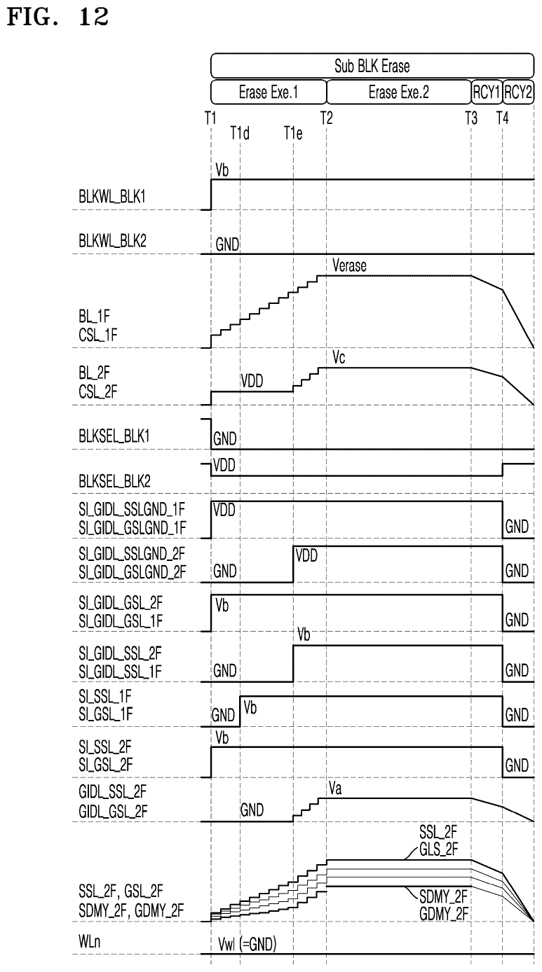

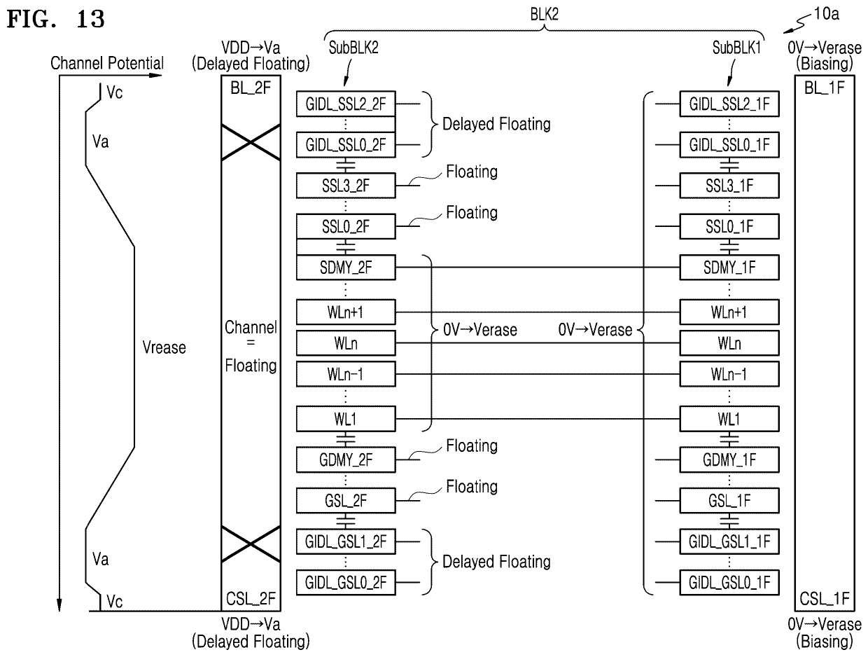

FIGS. 11 to 13 are diagrams illustrating an example of an erase operation of a memory device 10a according to implementations. FIG. 11 is a diagram illustrating an example modification of the first and second memory blocks BLK1 and BLK2 in FIGS. 3A and 3B. FIG. 12 is a timing diagram illustrating bias conditions of an erase operation of the first memory block BLK1 in FIG. 11. FIG. 13 shows channel potential of the first sub-block SubBLK1 and the second sub-block SubBLK2 of the second memory block BLK2, which is an unselected memory block, during the second erase period Erase Exe.2 between the time point T2 and the time point T3.

In FIG. 11, in each of the first and second memory blocks BLK1 and BLK2 of the memory device 10a, the bit line BL_1F of the first sub-block SubBLK1 and the bit line BL_2F of the second sub-block SubBLK2 may be separated from each other and driven to different voltage levels by the first page buffer 17_1F and the second page buffer 17_2F, respectively. In each of the first and second memory blocks BLK1 and BLK2, the common source line CSL_1F of the first sub-block SubBLK1 and the common source line CSL_2F of the second sub-block SubBLK2 may be separated from each other and driven to different voltage levels by the first CSL driver 18_1F and the second CSL driver 18_2F, respectively. For example, in each of the first and second memory blocks BLK1 and BLK2, the bit line BL_1F and the common source line CSL_1F of the first sub-block SubBLK1 may be driven to the level of the erase voltage Verase, and the bit line BL_2F and the common source line CSL_2F of the second sub-block SubBLK2 may be driven to the power supply voltage VDD and may then float.

In each of the first and second memory blocks BLK1 and BLK2, the first ground select line GIDL_GSL_1F of the first sub-block SubBLK1 may receive the first ground select line driving signal SI_GIDL_GSL_1F through a pass transistor TR01a or a third ground select line driving signal SI_GIDL_GSLGND_1F through a pass transistor TR01b. The first string select line GIDL_SSL_1F of the first sub-block SubBLK1 may receive the first string select line driving signal SI_GIDL_SSL_1F through a pass transistor TR91a or a third string select line driving signal SI_GIDL_SSLGND_1F through a pass transistor TR91b. A first block select signal BLKWL_BLK1 (or, BLKWL_BLK2) may be applied to the gates of the pass transistors TR01a and TR91a, and a second block select signal BLKSEL_BLK1 (or, BLKSEL_BLK2) may be applied to the gates of the pass transistors TR01b and TR91b.

In each of the first and second memory blocks BLK1 and BLK2, the first ground select line GIDL_GSL_2F of the second sub-block SubBLK2 may receive the first ground select line driving signal SI_GIDL_GSL_2F through a pass transistor TR02a or a third ground select line driving signal SI_GIDL_GSLGND_2F through a pass transistor TR02b. The first string select line GIDL_SSL_2F of the second sub-block SubBLK2 may receive the first string select line driving signal SI_GIDL_SSL_2F through a pass transistor TR92a or a third string select line driving signal SI_GIDL_SSLGND_2F through a pass transistor TR92b. The first block select signal BLKWL_BLK1 may be applied to the gates of the pass transistors TR02a and TR92a, and the second block select signal BLKSEL_BLK1 may be applied to the gates of the pass transistors TR02b and TR92b.

When the first memory block BLK1 is a selected memory block, the first block select signal BLKWL_BLK1 applied to the gates of the pass transistors TR01a, TR91a, TR02a, and TR92a of the first memory block BLK1 may be activated, and the second block select signal BLKSEL_BLK1 applied to the gates of the pass transistors TR01b, TR91b, TR02b, and TR92b of the first memory block BLK1 may be deactivated. A first block select signal BLKWL_BLK2 applied to the gates of the pass transistors TR01a, TR91a, TR02a, and TR92a of the second memory block BLK2 may be deactivated, and a second block select signal BLKSEL_BLK2 applied to the gates of the pass transistors TR01b, TR91b, TR02b, and TR92b of the second memory block BLK2 may be activated.

Contrarily, when the second memory block BLK2 is a selected memory block, the first block select signal BLKWL_BLK2 applied to the gates of the pass transistors TR01a, TR91a, TR02a, and TR92a of the second memory block BLK2 may be activated, and the second block select signal BLKSEL_BLK2 applied to the gates of the pass transistors TR01b, TR91b, TR02b, and TR92b of the second memory block BLK2 may be deactivated. In addition, the first block select signal BLKWL_BLK1 applied to the gates of the pass transistors TR01a, TR91a, TR02a, and TR92a of the first memory block BLK1 may be deactivated, and the second block select signal BLKSEL_BLK1 applied to the gates of the pass transistors TR01b, TR91b, TR02b, and TR92b of the first memory block BLK1 may be activated.

The timing diagram of FIG. 12 shows an erase operation (for example, the sub-block erase operation) of the first memory block BLK1 in connection with FIGS. 8 and 11, in which the first block select signal BLKWL_BLK1 that selects the first memory block BLK1 may be activated at the time point T1 and provided at the level of the first voltage Vb that is higher than the level of the power supply voltage VDD, and the first block select signal BLKWL_BLK2 that selects the second memory block BLK2 may be deactivated to the level of the ground voltage GND. In response to the activation of the first block select signal BLKWL_BLK1 applied to the first memory block BLK1, the pass transistors TR01a, TR91a, TR02a, and TR92a of the first memory block BLK1 may be turned on. In response to the deactivation of the first block select signal BLKWL_BLK2 applied to the second memory block BLK2, the pass transistors TR01a, TR91a, TR02a, and TR92a of the second memory block BLK2 may be turned off.

At the time point T1, because word lines WLn of the first sub-block SubBLK1 of the first memory block BLK1 are respectively connected to word lines WLn of the second sub-block SubBLK2 of the first memory block BLK1, the word line voltage Vwl having the level of the ground voltage GND may be applied to the word lines WLn of the first sub-block SubBLK1 and the second sub-block SubBLK2 of the first memory block BLK1. The word lines WLn of the first sub-block SubBLK1 and the second sub-block SubBLK2 of the second memory block BLK2 may float in response to the deactivation of the first block select signal BLKWL_BLK2.

At the time point T1, the erase voltage Verase increasing stepwise may be applied to the common source line CSL_1F and the bit line BL_1F of the first sub-block SubBLK1 of the first memory block BLK1. The power supply voltage VDD may be applied to the common source line CSL_2F and the bit line BL_2F of the second sub-block SubBLK2 of the first memory block BLK1.

At the time point T1, the second block select signal BLKSEL_BLK1 applied to the first memory block BLK1 may be at the level of the ground voltage GND so that the pass transistors TR01b, TR91b, TR02b, and TR92b of the first memory block BLK1 may be turned off. The second block select signal BLKSEL_BLK2 may be applied to the second memory block BLK2 at the level of the power supply voltage VDD. The second block select signal BLKSEL_BLK2 of the second memory block BLK2 may be at the level of the power supply voltage VDD for a certain period of time and may then float with a delay at a time point T1e. The pass transistor TR01b and TR91b of the first sub-block SubBLK1 of the second memory block BLK2 may be turned off, and the pass transistor TR02b and TR92b of the second sub-block SubBLK2 of the second memory block BLK2 may be turned on and then turned off.

At the time point T1, the third string select line driving signal SI_GIDL_SSLGND_1F and the third ground select line driving signal SI_GIDL_GSLGND_1F may be applied at the level of the power supply voltage VDD to the first sub-block SubBLK1 of each of the first and second memory blocks BLK1 and BLK2. The third string select line driving signal SI_GIDL_SSLGND_2F and the third ground select line driving signal SI_GIDL_GSLGND_2F may be applied at the level of the ground voltage GND to the second sub-block SubBLK2 of each of the first and second memory blocks BLK1 and BLK2.

Because the pass transistors TR01b and TR91b of the first sub-block SubBLK1 of the first memory block BLK1 are turned off, the third string select line driving signal SI_GIDL_SSLGND_1F and the third ground select line driving signal SI_GIDL_GSLGND_1F may not be transmitted to the first string select line GIDL_SSL_1F and the first ground select line GIDL_GSL_1F, respectively. Because the pass transistors TR01b and TR91b of the first sub-block SubBLK1 of the second memory block BLK2 are turned off, the third string select line driving signal SI_GIDL_SSLGND_1F and the third ground select line driving signal SI_GIDL_GSLGND_1F may not be transmitted to the first string select line GIDL_SSL_1F and the first ground select line GIDL_GSL_1F, respectively. Because the pass transistors TR02b and TR92b of the second sub-block SubBLK2 of the second memory block BLK2 are turned on, the third string select line driving signal SI_GIDL_SSLGND_2F and the third ground select line driving signal SI_GIDL_GSLGND_2F may be transmitted to the first string select line GIDL_SSL_2F and the first ground select line GIDL_GSL_2F, respectively, so that the first string select line GIDL_SSL_2F and the first ground select line GIDL_GSL_2F may come to be at the level of the ground voltage GND.

At the time point T1, the first ground select line driving signals SI_GIDL_GSL_1F and SI_GIDL_GSL_2F may be applied at the level of the first voltage Vb to the first sub-block SubBLK1 and the second sub-block SubBLK2 of the first memory block BLK1, and the first string select line driving signals SI_GIDL_SSL_1F and SI_GIDL_SSL_2F may be applied at the level of the ground voltage GND to the first sub-block SubBLK1 and the second sub-block SubBLK2 of the first memory block BLK1.

In the first sub-block SubBLK1 and the second sub-block SubBLK2 of the first memory block BLK1, the pass transistors TR01a and TR02a may be turned off respectively by the first ground select line driving signals SI_GIDL_GSL_1F and SI_GIDL_GSL_2F at the level of the first voltage Vb so that the first ground select lines GIDL_GSL_1F and GIDL_GSL_2F may float. The pass transistors TR91a and TR92a, which respectively receive the first string select line driving signals SI_GIDL_SSL_1F and SI_GIDL_SSL_2F at the level of the ground voltage GND, may be turned on so that the first string select lines GIDL_SSL_1F and GIDL_SSL_2F may come to be at the level of the ground voltage GND. The GST and the SST of the first sub-block SubBLK1 of the first memory block BLK1 may be turned off due to the first ground select line GIDL_GSL_1F that floats and the first string select line GIDL_SSL_1F at the level of the ground voltage GND so that the channel of the first sub-block SubBLK1 of the first memory block BLK1 may float. The GST and the SST of the second sub-block SubBLK2 of the first memory block BLK1 may be turned off due to the first ground select line GIDL_GSL_2F that floats and the first string select line GIDL_SSL_2F at the level of the ground voltage GND so that the channel of the second sub-block SubBLK2 of the first memory block BLK1 may float.

At the time point T1, the second string select line driving signal SI_SSL_1F and the second ground select line driving signal SI_GSL_1F may be applied at the level of the ground voltage GND to the first sub-block SubBLK1 of the first memory block BLK1. The second string select line driving signal SI_SSL_2F and the second ground select line driving signal SI_GSL_2F may be applied at the level of the first voltage Vb to the second sub-block SubBLK2 of the first memory block BLK1. In the second sub-block SubBLK2 of the first memory block BLK1, the pass transistors TR82 and TR12 may be turned off respectively by the second string select line driving signal SI_SSL_2F and the second ground select line driving signal SI_GSL_2F at the level of the first voltage Vb so that the second string select line SSL_2F and the second ground select line GSL_2F may float. Accordingly, the voltage of the channel of the second sub-block SubBLK2 of the first memory block BLK1 may sequentially decrease due to capacitive coupling, thereby suppressing hot holes generated in the SST and the GST from flowing in the channel direction.

In the period between the time point T1 and the time point T2, in the first sub-block SubBLK1 of each of the first and second memory blocks BLK1 and BLK2, the second string select line driving signal SI_SSL_1F and the second ground select line driving signal SI_GSL_1F may be at the level of the ground voltage GND for a certain period of time and then come to be at the level of the first voltage Vb. In the second sub-block SubBLK2 of each of the first and second memory blocks BLK1 and BLK2, the common source line CSL_2F and the bit line BL_2F may be at the level of the power supply voltage VDD and then come to be at the level of a third voltage Vc. In the second sub-block SubBLK2 of each of the first and second memory blocks BLK1 and BLK2, the first string select line driving signal SI_GIDL_SSL_2F and the first ground select line driving signal SI_GIDL_GSL_2F may be at the level of the ground voltage GND for a certain period of time and then come to be at the level of the first voltage Vb. In addition, in the second sub-block SubBLK2 of each of the first and second memory blocks BLK1 and BLK2, the third string select line driving signal SI_GIDL_SSLGND_2F and the third ground select line driving signal SI_GIDL_GSLGND_2F may be at the level of the ground voltage GND for a certain period of time and then come to be at the level of the power supply voltage VDD.

For example, at a time point T1d, in the first sub-block SubBLK1 of the first memory block BLK1, the second string select line driving signal SI_SSL_1F and the second ground select line driving signal SI_GSL_1F may change from the level of the ground voltage GND to the level of the first voltage Vb so that the second string select line SSL_1F and the second ground select line GSL_1F may float.

At the time point T1e, in the second sub-block SubBLK2 of the first memory block BLK1, the common source line CSL_2F and the bit line BL_2F may float at the level of the power supply voltage VDD, and the first string select line driving signal SI_GIDL_SSL_2F may change from the level of the ground voltage GND to the level of the first voltage Vb. In the second sub-block SubBLK2, the pass transistors TR92a and TR02a, which respectively receive the first string select line driving signal SI_GIDL_SSL_2F and the first ground select line driving signal SI_GIDL_GSL_2F, may be turned off by the level of the first voltage Vb of the first block select signal BLKWL_BLK1 applied to the first memory block BLK1 so that the first string select line GIDL_SSL_2F and the first ground select line GIDL_GSL_2F may float. Accordingly, the common source line CSL_2F and the bit line BL_2F, which float in the second sub-block SubBLK2, may increase from the level of the power supply voltage VDD to the level of a third voltage Vc, and the first string select line GIDL_SSL_2F and the first ground select line GIDL_GSL_2F, which float, may increase from the level of the ground voltage GND to the level of the second voltage Va. According to some implementations, the level of the second voltage Va may be higher than the level of the first voltage Vb, and the level of the third voltage Vc may be higher than the level of the second voltage Va and lower than the level of the erase voltage Verase.

In the period between the time point T2 and the time point T3, in the first sub-block SubBLK1 of the first memory block BLK1, the erase voltage Verase at a high level may be provided to the common source line CSL_1F and the bit line BL_1F. Due to coupling to the erase voltage Verase of the common source line CSL_1F and the bit line BL_1F of the first sub-block SubBLK1, the potential of the first ground select line GIDL_GSL_1F and the first string select line GIDL_SSL_1F, which float in the first sub-block SubBLK1, may increase to the level of the second voltage Va. Accordingly, GIDL current caused by the SST and the GST of the first sub-block SubBLK1 may flow in the channel direction, and hot holes generated in the SST and the GST may flow in the channel direction so that the channel potential of the cell strings NS of the first sub-block SubBLK1 may increase to the level of the erase voltage Verase. When the channel potential of the cell strings NS of the first sub-block SubBLK1 increases to the level of the erase voltage Verase, the difference between the channel potential and the word line voltage Vwl of the word lines WLn may be greater than the magnitude required to erase a memory cell so that the memory cells MCs of the first sub-block SubBLK1 may be erased.

In the period between the time point T2 and the time point T3, the common source line CSL_2F and the bit line BL_2F of the second sub-block SubBLK2 of the first memory block BLK1 may be coupled to the level of the third voltage Vc. In the second sub-block SubBLK2 of the first memory block BLK1, the first string select line GIDL_SSL_2F, the first ground select line GIDL_GSL_2F, the second string select line SSL_2F, the second ground select line GSL_2F, the second dummy word line SDMY_2F, and the first dummy word line GDMY_2F, which float, may be coupled to different voltage levels according to the physical distances to the common source line CSL_2F and the bit line BL_2F. The first dummy word line GDMY_2F, which is far from the common source line CSL_2F, and the second dummy word line SDMY_2F, which is far from the bit line BL_2F and close to the word lines WLn, may be coupled to the ground voltage GND applied to the word lines WLn and may thus increase to a relatively low voltage level. The second ground select line GSL_2F close to the common source line CSL_2F and the second string select line SSL_2F close to the bit line BL_2F may be coupled to a voltage level corresponding to the difference between the power supply voltage VDD and the third voltage Vc and may thus increase to a relatively high voltage level. Accordingly, the channel potential of the second sub-block SubBLK2 may gradually come to be at the level of the ground voltage GND due to capacitive coupling, and there may be no substantial potential difference between a channel and the word lines WLn, so that the memory cells MCs of the second sub-block SubBLK2 of the first memory block BLK1 may not be erased.

In the period between the time point T2 and the time point T3, the common source line CSL_2F and the bit line BL_2F of the second sub-block SubBLK2 of the second memory block BLK2 may be coupled to the level of the third voltage Vc. In the second sub-block SubBLK2 of the second memory block BLK2, the first string select line GIDL_SSL_2F, the first ground select line GIDL_GSL_2F, the second string select line SSL_2F, the second ground select line GSL_2F, the second dummy word line SDMY_2F, and the first dummy word line GDMY_2F, which float, may be coupled to different voltage levels according to the physical distances to the common source line CSL_2F and the bit line BL_2F. The first dummy word line GDMY_2F, which is far from the common source line CSL_2F, and the second dummy word line SDMY_2F, which is far from the bit line BL_2F and close to the word lines WLn, may be coupled to a voltage level corresponding to the voltage of the word lines WLn, which is coupled to the erase voltage Verase of the common source line CSL_1F and the bit line BL_1F and thus increases, and may thus increase to a relatively high voltage level. The first ground select line GIDL_GSL_2F close to the common source line CSL_2F and the first string select line GIDL_SSL_2F close to the bit line BL_2F may be coupled to a voltage level corresponding to the difference between the power supply voltage VDD and the third voltage Vc and may thus increase to a relatively low voltage level. Accordingly, the GST and the SST of the second sub-block SubBLK2 of the second memory block BLK2 may be turned off, and the channel potential may be coupled to the voltage of the word line WLn so that the potential difference between a channel and the word lines WLn may decrease. As a result, the memory cells MCs of the second sub-block SubBLK2 of the second memory block BLK2 may not be erased.

Because the second sub-block SubBLK2 of the first memory block BLK1 is a sister sub-block, the memory cells MCs of the second sub-block SubBLK2 may be not erased. In this case, the common source line CSL_2F and the bit line BL_2F of the second sub-block SubBLK2 of the first memory block BLK1, which are at the level of the power supply voltage VDD, may be coupled to the level of the third voltage Vc. The level of the third voltage Vc may be lower than the level of the erase voltage Verase of the common source line CSL_2F and the bit line BL_2F of the second sub-block SubBLK2 of the first memory block BLK1, which has been described with reference to FIGS. 8 to 10. This may mean that power consumption may be reduced in the erase operation of the memory device 10a.

At the time point T3, an erase recovery operation may be performed on the first memory block BLK1 and the second memory block BLK2. At the time point T3, the level of the erase voltage Verase, which is applied to the common source line CSL_1F and the bit line BL_1F of the first sub-block SubBLK1 of each of the first and second memory blocks BLK1 and BLK2 and to the common source line CSL_2F and the bit line BL_2F of the second sub-block SubBLK2 of each of the first and second memory blocks BLK1 and BLK2, may decrease. At the time point T4, the first ground select line driving signals SI_GIDL_GSL_1F and SI_GIDL_GSL_2F, the first string select line driving signals SI_GIDL_SSL_1F and SI_GIDL_SSL_2F, the second ground select line driving signals SI_GSL_1F and SI_GSL_2F, the second string select line driving signals SI_SSL_1F and SI_SSL_2F, the third ground select line driving signals SI_GIDL_GSLGND_1F and SI_GIDL_GSLGND_2F, and the third string select line driving signals SI_GIDL_SSLGND_1F and SI_GIDL_SSLGND_2F of the first sub-block SubBLK1 and the second sub-block SubBLK2 may be recovered to the level of the ground voltage GND.

FIG. 13 shows channel potential of the first sub-block SubBLK1 and the second sub-block SubBLK2 of the second memory block BLK2, which is the unselected memory block in FIG. 11, during the second erase period Erase Exe.2.

In FIG. 13, in the first sub-block SubBLK1 of the second memory block BLK2, first string select lines GIDL_SSL2_1F and GIDL_SSL0_1F, second string select lines SSL3_1F and SSL0_1F, a second dummy word line SDMY_1F, word lines WL1 to WLn+1, a first dummy word line GDMY_1F, a second ground select line GSL_1F, and first ground select lines GIDL_GSL1_1F and GIDL_GSL0_1F, which float at the level of the ground voltage GND, may be coupled to the level of the erase voltage Verase due to the erase voltage Verase applied to the common source line CSL_1F and the bit line BL_1F.

In the second sub-block SubBLK2 of the second memory block BLK2, first string select lines GIDL_SSL2_2F and GIDL_SSL0_2F and first ground select lines GIDL_GSL1_2F and GIDL_GSL0_2F may be at the level of the ground voltage GND for a certain period of time and may then float with a delay, and the common source line CSL_2F and the bit line BL_2F may be at the level of the power supply voltage VDD and may then float with a delay. Because the word lines WL1 to WLn+1 of the first sub-block SubBLK1 of the second memory block BLK2 are respectively connected to the word lines WL1 to WLn+1 of the second sub-block SubBLK2 of the second memory block BLK2, the word lines WL1 to WLn+1 may be coupled to the level of the erase voltage Verase from the level of the ground voltage GND.

In the second sub-block SubBLK2 of the second memory block BLK2, a channel below the first string select lines GIDL_SSL2_2F and GIDL_SSL0_2F and the first ground select lines GIDL_GSL1_2F and GIDL_GSL0_2F may be coupled to the level of the third voltage Vc of the common source line CSL_2F and the bit line BL_2F and then to the level of the second voltage Va of the first string select line GIDL_SSL2_2F and the first ground select line GIDL_GSL1_2F, which have floated. A channel below second string select lines SSL3_ 2F and SSL0_ 2F, a second dummy word line SDMY_2F, the word lines WL1 to WLn+1, a first dummy word line GDMY_2F, and a second ground select line GSL_2F, which float, may be coupled to the level of the erase voltage Verase from the level of the second voltage Va.

Because there is no substantial potential difference between the channel and the word lines WL1 to WLn+1 in FIG. 13, the memory cells of the second memory block BLK2 that is an unselected memory block may not be erased. Because the common source line CSL_2F and the bit line BL_2F of the second sub-block SubBLK2 of the second memory block BLK2 are coupled to the level of the third voltage Vc, which is lower than the level of the erase voltage Verase, from the level of the power supply voltage VDD, power consumption may be reduced in an erase operation of the memory device 10a.

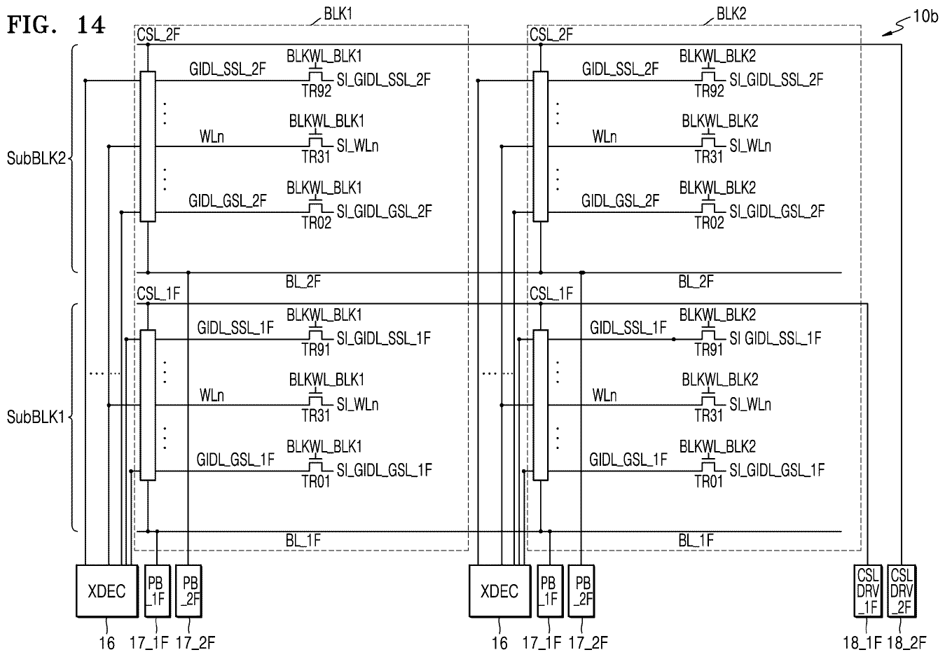

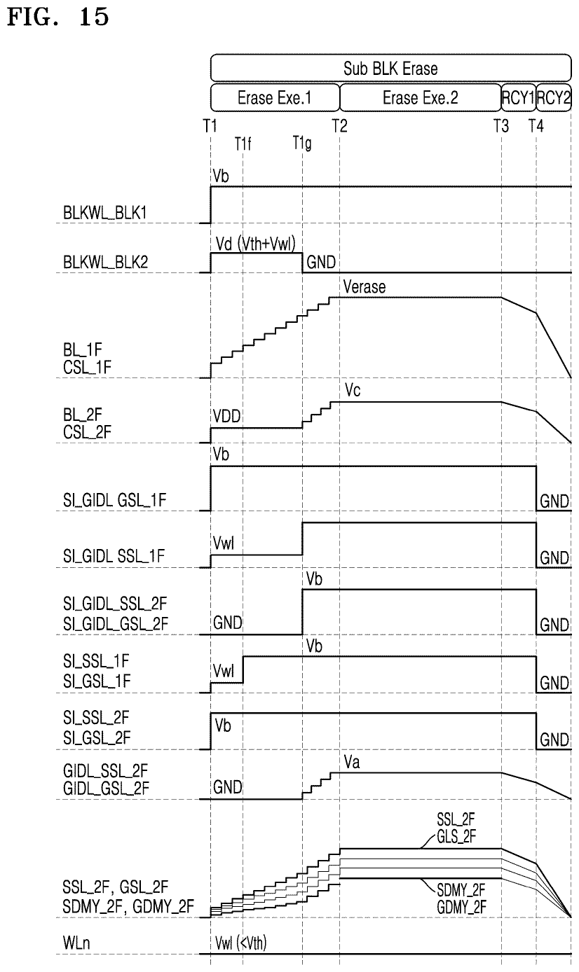

FIGS. 14 and 15 are diagrams illustrating an example of an erase operation of a memory device 10b according to some implementations. FIG. 14 is a diagram illustrating the first and second memory blocks BLK1 and BLK2 in FIGS. 3A and 3B. FIG. 15 is a timing diagram illustrating bias conditions of an erase operation of the first memory block BLK1 in FIG. 14.

In FIG. 14, in each of the first and second memory blocks BLK1 and BLK2 of the memory device 10b, the bit line BL_1F of the first sub-block SubBLK1 and the bit line BL_2F of the second sub-block SubBLK2 may be separated from each other and driven to different voltage levels by the first page buffer 17_1F and the second page buffer 17_2F, respectively. In each of the first and second memory blocks BLK1 and BLK2, the common source line CSL_1F of the first sub-block SubBLK1 and the common source line CSL_2F of the second sub-block SubBLK2 may be separated from each other and driven to different voltage levels by the first CSL driver 18_1F and the second CSL driver 18_2F, respectively. For example, in each of the first and second memory blocks BLK1 and BLK2, the bit line BL_1F and the common source line CSL_1F of the first sub-block SubBLK1 may be driven to the level of the erase voltage Verase, and the bit line BL_2F and the common source line CSL_2F of the second sub-block SubBLK2 may be driven to the power supply voltage VDD and may then float.

In the first sub-block SubBLK1 of each of the first and second memory blocks BLK1 and BLK2, the first ground select line GIDL_GSL_1F may receive the first ground select line driving signal SI_GIDL_GSL_1F through the pass transistor TR01, and the first string select line GIDL_SSL_1F may receive the first string select line driving signal SI_GIDL_SSL_1F through the pass transistor TR91. In the second sub-block SubBLK2 of each of the first and second memory blocks BLK1 and BLK2, the first ground select line GIDL_GSL_2F may receive the first ground select line driving signal SI_GIDL_GSL_2F through the pass transistor TR02, and the first string select line GIDL_SSL_2F may receive the first string select line driving signal SI_GIDL_SSL_2F through the pass transistor TR92. In the first sub-block SubBLK1 and the second sub-block SubBLK2 of each of the first and second memory blocks BLK1 and BLK2, the word lines WLn may receive a word line driving signal SI_WLn through a pass transistor (e.g., the pass transistor TR31).

The timing diagram of FIG. 15 shows an erase operation (for example, the sub-block erase operation) of the first memory block BLK1 in connection with FIGS. 8 and 14, in which the first block select signal BLKWL_BLK1 that selects the first memory block BLK1 may be activated at the time point T1 and provided at the level of the first voltage Vb that is higher than the level of the power supply voltage VDD, and the first block select signal BLKWL_BLK2 that selects the second memory block BLK2 may be provided at the level of a fourth voltage Vd. The fourth voltage Vd may be set to have a voltage level Vth+Vwl that is the sum of the level of a transistor threshold voltage Vth and the level of the word line voltage Vwl.

At the time point T1, because word lines WLn of the first sub-block SubBLK1 of each of the first memory block BLK1 and the second memory block BLK2 are respectively connected to word lines WLn of the second sub-block SubBLK2 of each of the first memory block BLK1 and the second memory block BLK2, the word line voltage Vwl may be applied to the word lines WLn of the first sub-block SubBLK1 and the second sub-block SubBLK2 in each of the first memory block BLK1 and the second memory block BLK2. The word line voltage Vwl may be set to a level that is lower than the level of the transistor threshold voltage Vth.

At the time point T1, the erase voltage Verase increasing stepwise may be applied to the common source line CSL_1F and the bit line BL_1F of the first sub-block SubBLK1 of the first memory block BLK1. The power supply voltage VDD may be applied to the common source line CSL_2F and the bit line BL_2F of the second sub-block SubBLK2 of the first memory block BLK1.

At the time point T1, in the first sub-block SubBLK1 of each of the first memory block BLK1 and the second memory block BLK2, the level of the first voltage Vb may be applied to the first ground select line driving signal SI_GIDL_GSL_1F, and the level of the word line voltage Vwl may be applied to the first string select line driving signal SI_GIDL_SSL_1F.

In the first sub-block SubBLK1 of the first memory block BLK1, the first block select signal BLKWL_BLK1 may be provided at the level of the first voltage Vb, and the pass transistor TR01 may be turned off by the first ground select line driving signal SI_GIDL_GSL_1F at the level of the first voltage Vb, so that the first ground select line GIDL_GSL_1F may float. The pass transistor TR31 receiving the word line driving signal SI_WLn at the level of the word line voltage Vwl may be turned on so that the word line WLn may come to be at the level of the word line voltage Vwl. The pass transistor TR91 receiving the first string select line driving signal SI_GIDL_SSL_1F at the level of the word line voltage Vwl may be turned on so that the first string select line GIDL_SSL_1F may come to be at the level of the word line voltage Vwl.

In the first sub-block SubBLK1 of the second memory block BLK2, the first block select signal BLKWL_BLK2 may be provided at the level of the fourth voltage Vd, and the pass transistor TR01 may be turned off by the first ground select line driving signal SI_GIDL_GSL_1F at the level of the first voltage Vb, so that the first ground select line GIDL_GSL_1F may float. The pass transistor TR31 receiving the word line driving signal SI_WLn at the level of the word line voltage Vwl may be turned off so that the word line WLn may float. The pass transistor TR91 receiving the first string select line driving signal SI_GIDL_SSL_1F at the level of the word line voltage Vwl may be turned off so that the first string select line GIDL_SSL_1F may float.

At the time point T1, in the second sub-block SubBLK2 of each of the first memory block BLK1 and the second memory block BLK2, the level of the ground voltage GND may be applied to the first ground select line driving signal SI_GIDL_GSL_2F and the first string select line driving signal SI_GIDL_SSL_2F.

In the second sub-block SubBLK2 of the first memory block BLK1, the pass transistor TR02 may be turned off by the first ground select line driving signal SI_GIDL_GSL_2F at the level of the ground voltage GND so that the first ground select line GIDL_GSL_2F may be at the level of the ground voltage GND. The pass transistor TR92 may be turned on by the first string select line driving signal SI_GIDL_SSL_2F at the level of the ground voltage GND so that the first string select line GIDL_SSL_2F may be at the level of the ground voltage GND. The channel of the second sub-block SubBLK2 of the first memory block BLK1 may float due to the first ground select line GIDL_GSL_2F and the first string select line GIDL_SSL_2F, which are at the level of the ground voltage GND.

In the second sub-block SubBLK2 of the second memory block BLK2, the first block select signal BLKWL_BLK2 may be provided at the level of the fourth voltage Vd, and the pass transistor TR02 may be turned on by the first ground select line driving signal SI_GIDL_GSL_2F at the level of the ground voltage GND, so that the first ground select line GIDL_GSL_2F may float. The pass transistor TR92 may be turned on by the first string select line driving signal SI_GIDL_SSL_2F at the level of the ground voltage GND so that the first string select line GIDL_SSL_2F may be at the level of the ground voltage GND. The channel of the second sub-block SubBLK2 of the second memory block BLK2 may float due to the first ground select line GIDL_GSL_2F and the first string select line GIDL_SSL_2F, which are at the level of the ground voltage GND.

At the time point T1, in the first sub-block SubBLK1 of each of the first memory block BLK1 and the second memory block BLK2, the level of the word line voltage Vwl may be applied to the second string select line driving signal SI_SSL_1F and the second ground select line driving signal SI_GSL_1F.

In the first sub-block SubBLK1 of the first memory block BLK1, the pass transistors TR81 and TR11 may be turned on by the second string select line driving signal SI_SSL_1F and the second ground select line driving signal SI_GSL_1F, which are at the level of the word line voltage Vwl, so that the second string select line SSL_1F and the second ground select line GSL_1F may be at the level of the word line voltage Vwl. In the first sub-block SubBLK1 of the second memory block BLK2, the pass transistors TR81 and TR11 may be turned off by the second string select line driving signal SI_SSL_1F and the second ground select line driving signal SI_GSL_1F, which are at the level of the word line voltage Vwl, so that the second string select line SSL_1F and the second ground select line GSL_1F may float.

At the time point T1, in the second sub-block SubBLK2 of each of the first memory block BLK1 and the second memory block BLK2, the level of the first voltage Vb may be applied to the second string select line driving signal SI_SSL_2F and the second ground select line driving signal SI_GSL_2F. In the second sub-block SubBLK2 of the first memory block BLK1, the pass transistors TR82 and TR12 may be turned off by the second string select line driving signal SI_SSL_2F and the second ground select line driving signal SI_GSL_2F, which are at the level of the first voltage Vb, so that the second string select line SSL_2F and the second ground select line GSL_2F may float. In the first sub-block SubBLK1 of the second memory block BLK2, the pass transistors TR82 and TR12 may be turned off by the second string select line driving signal SI_SSL_2F and the second ground select line driving signal SI_GSL_2F, which are at the level of the first voltage Vb, so that the second string select line SSL_2F and the second ground select line GSL_2F may float.

In the period between the time point T1 and the time point T2, in the first sub-block SubBLK1 of each of the first and second memory blocks BLK1 and BLK2, the second string select line SSL_1F and the second ground select line GSL_1F may be at the level of the word line voltage Vwl for a certain period of time and may then float with a delay. In the second sub-block SubBLK2 of each of the first and second memory blocks BLK1 and BLK2, the common source line CSL_2F and the bit line BL_2F may be at the level of the power supply voltage VDD and may then float with a delay. In the second sub-block SubBLK2 of each of the first and second memory blocks BLK1 and BLK2, the first string select line GIDL_SSL_2F and the first ground select line GIDL_GSL_2F may be at the level of the ground voltage GND for a certain period of time and may then float with a delay.

For example, at a time point T1f, in the first sub-block SubBLK1 of the first memory block BLK1, the second string select line driving signal SI_SSL_1F and the second ground select line driving signal SI_GSL_1F may float at the level of the word line voltage Vwl and change from the level of the word line voltage Vwl to the level of the first voltage Vb, and the first ground select line GIDL_GSL_1F and the first string select line GIDL_SSL_1F may float.

At a time point T1g, in the second sub-block SubBLK2 of the first memory block BLK1, the common source line CSL_2F and the bit line BL_2F may float at the level of the power supply voltage VDD, and the first string select line driving signal SI_GIDL_SSL_2F and the first ground select line driving signal SI_GIDL_GSL_2F may float at the level of the ground voltage GND. In the second sub-block SubBLK2, the pass transistors TR92 and TR02, which respectively receive the first string select line driving signal SI_GIDL_SSL_2F and the first ground select line driving signal SI_GIDL_GSL_2F, may be turned off by the level of the first voltage Vb of the first block select signal BLKWL_BLK1 applied to the first memory block BLK1 so that the first string select line GIDL_SSL_2F and the first ground select line GIDL_GSL_2F may float. Accordingly, the common source line CSL_2F and the bit line BL_2F, which float in the second sub-block SubBLK2, may increase from the level of the power supply voltage VDD to the level of the third voltage Vc, and the first string select line GIDL_SSL_2F and the first ground select line GIDL_GSL_2F, which float, may increase from the level of the ground voltage GND to the level of the second voltage Va.

In the period between the time point T2 and the time point T3, in the first sub-block SubBLK1 of the first memory block BLK1, the erase voltage Verase at a high level may be provided to the common source line CSL_1F and the bit line BL_1F. Due to coupling to the erase voltage Verase of the common source line CSL_1F and the bit line BL_1F of the first sub-block SubBLK1, the potential of the first ground select line GIDL_GSL_1F and the first string select line GIDL_SSL_1F, which float in the first sub-block SubBLK1, may increase to the level of the second voltage Va, which turns on the GST and the SST. Accordingly, GIDL current caused by the SST and the GST of the first sub-block SubBLK1 may flow in the channel direction, and hot holes generated in the SST and the GST may flow in the channel direction so that the channel potential of the cell strings NS of the first sub-block SubBLK1 may increase to the level of the erase voltage Verase. When the channel potential of the cell strings NS of the first sub-block SubBLK1 increases to the level of the erase voltage Verase, the difference between the channel potential and the word line voltage Vwl of the word lines WLn may be greater than the magnitude required to erase a memory cell so that the memory cells MCs of the first sub-block SubBLK1 may be erased.

In the period between the time point T2 and the time point T3, the common source line CSL_2F and the bit line BL_2F of the second sub-block SubBLK2 of the first memory block BLK1 may be coupled to the level of the third voltage Vc. In the second sub-block SubBLK2 of the first memory block BLK1, the second string select line SSL_2F, the second ground select line GSL_2F, the second dummy word line SDMY_2F, and the first dummy word line GDMY_2F, which float, may be coupled to different voltage levels according to the physical distances to the common source line CSL_2F and the bit line BL_2F. The first dummy word line GDMY_2F, which is far from the common source line CSL_2F, and the second dummy word line SDMY_2F, which is far from the bit line BL_2F and close to the word lines WLn, may be coupled to the level of the ground voltage GND applied to the word lines WLn and may thus increase to a relatively low voltage level. The second ground select line GSL_2F close to the common source line CSL_2F and the second string select line SSL_2F close to the bit line BL_2F may be coupled to a voltage level corresponding to the difference between the power supply voltage VDD and the third voltage Vc and may thus increase to a relatively high voltage level. Accordingly, the channel potential of the second sub-block SubBLK2 may gradually come to be at the level of the ground voltage GND due to capacitive coupling, and there may be no substantial potential difference between a channel and the word lines WLn, so that the memory cells MCs of the second sub-block SubBLK2 of the first memory block BLK1 may not be erased.

In the period between the time point T2 and the time point T3, the common source line CSL_2F and the bit line BL_2F of the second sub-block SubBLK2 of the second memory block BLK2 may be coupled to the level of the third voltage Vc. In the second sub-block SubBLK2 of the second memory block BLK2, the first string select line GIDL_SSL_2F, the first ground select line GIDL_GSL_2F, the second string select line SSL_2F, the second ground select line GSL_2F, the second dummy word line SDMY_2F, and the first dummy word line GDMY_2F, which float, may be coupled to different voltage levels according to the physical distances to the common source line CSL_2F and the bit line BL_2F. The first dummy word line GDMY_2F, which is far from the common source line CSL_2F, and the second dummy word line SDMY_2F, which is far from the bit line BL_2F and close to the word lines WLn, may be coupled to a voltage level corresponding to the voltage of the word lines WLn, which is coupled to the erase voltage Verase of the common source line CSL_1F and the bit line BL_1F and thus increases, and may thus increase to a relatively high voltage level. The first ground select line GIDL_GSL_2F close to the common source line CSL_2F and the first string select line GIDL_SSL_2F close to the bit line BL_2F may be coupled to a voltage level corresponding to the difference between the power supply voltage VDD and the third voltage Vc and may thus increase to a relatively low voltage level. Accordingly, the GST and the SST of the second sub-block SubBLK2 of the second memory block BLK2 may be turned off, and the channel potential may be coupled to the voltage of the word line WLn so that the potential difference between a channel and the word lines WLn may decrease. As a result, the memory cells MCs of the second sub-block SubBLK2 of the second memory block BLK2 may not be erased.

Because the common source line CSL_2F and the bit line BL_2F of the second sub-block SubBLK2 of the first memory block BLK1 are coupled to the level of the third voltage Vc, which is lower than the erase voltage Verase, at the level of the power supply voltage in FIG. 15, power consumption may be reduced in an erase operation of the memory device 10b.

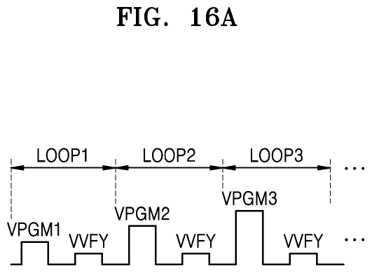

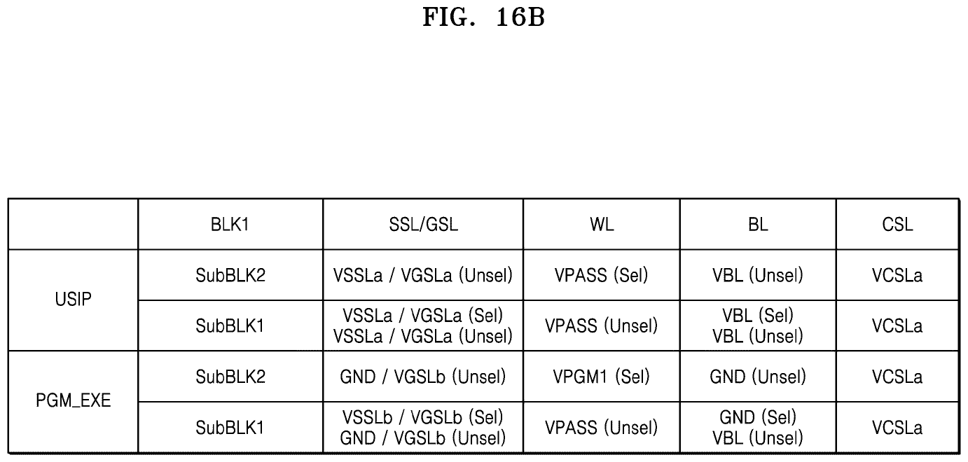

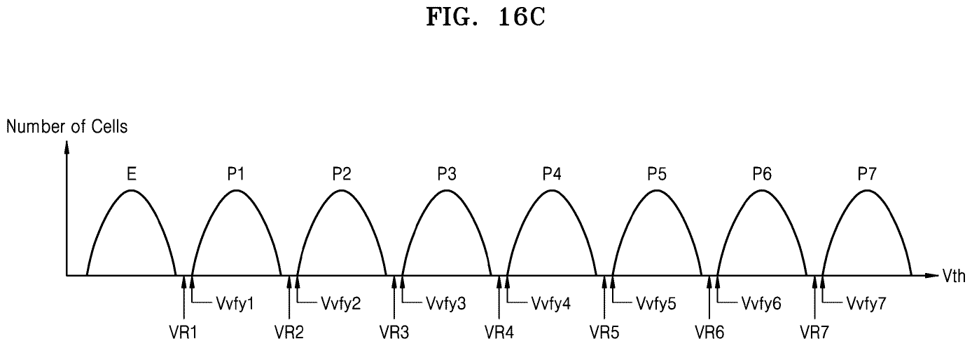

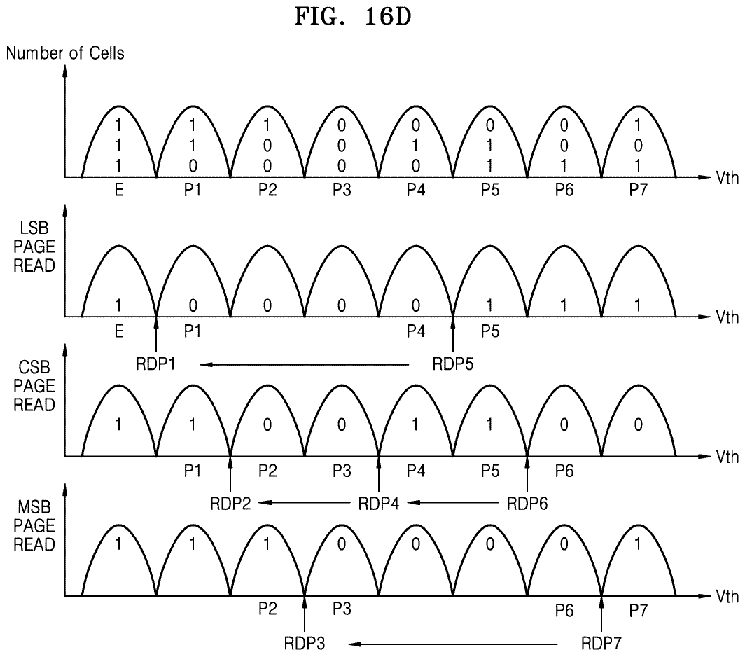

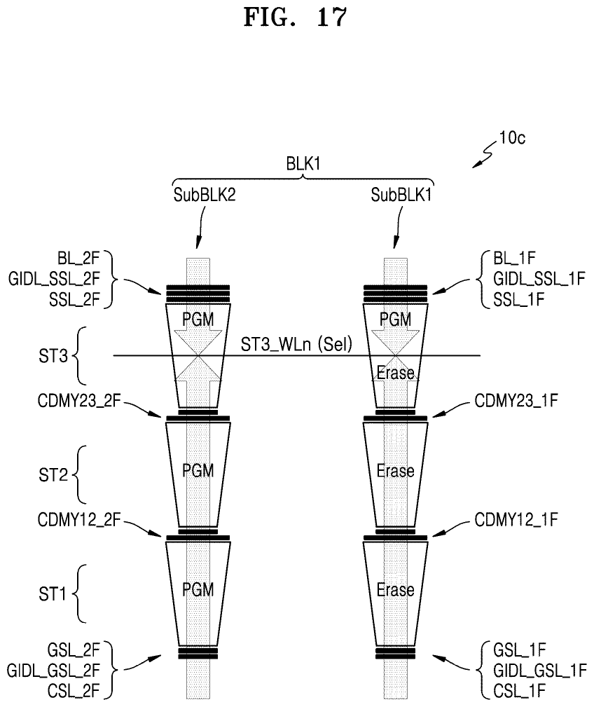

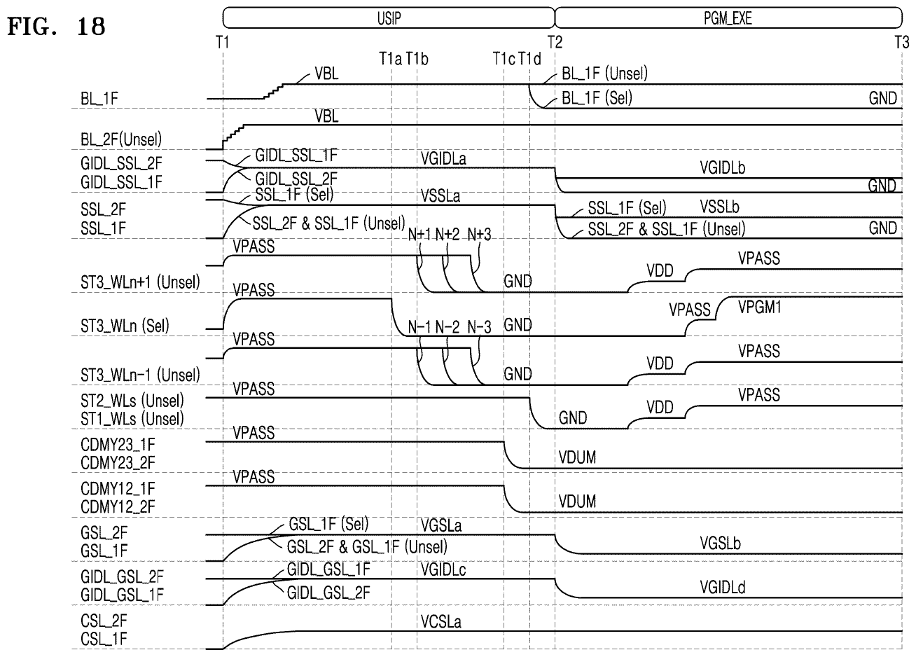

FIGS. 16A to 20 are diagrams illustrating an example of a program operation of a memory device 10c according to some implementations. FIG. 16A illustrates a program method of the memory block BLK1, which has been described with reference to FIGS. 4A and 4B and is included in the memory device 10c of FIG. 17. FIG. 16B is a table showing bias conditions of a program operation. In the memory block BLK1 described with reference to FIGS. 4A and 4B, the word lines WL1 to WL8 of the first sub-block SubBLK1 may be respectively connected to the word lines WL1 to WL8 of the second sub-block SubBLK2, and the common source line CSL_1F of the first sub-block SubBLK1 and the common source line CSL_2F of the second sub-block SubBLK2 may be connected to one common source line CSL. FIGS. 16C and 16D are diagrams illustrating examples of the states of a multi-level cell to which the program method of FIGS. 16A and 16B may be applied. FIGS. 18 to 20 are diagrams showing methods of controlling the memory block BLK1 and voltage changes, according to the bias conditions of FIG. 16B.

In FIG. 16A, it is assumed that the first sub-block SubBLK1 of the memory block BLK1 of the memory device 10c is a selected sub-block undergoing a program operation and the second sub-block SubBLK2 of the memory block BLK1 is a sister sub-block with respect to which programming is inhibited. A plurality of program loops (e.g., LOOP1, LOOP2, LOOP3, . . . ) may be sequentially performed such that a program operation of a selected memory cell connected to a selected word line WL(Sel) of the first sub-block SubBLK1 is completely performed according to incremental step pulse programming (ISPP). When program loops are repeated, program voltages (e.g., VPGM1, VPGM2, VPGM3, . . . ) may increase stepwise. Each program loop LOOPi (where “i” is a positive integer) may include a program period, in which a program voltage VPGMi is applied to the selected word line WL(Sel) to program the selected memory cell, and a verify period, in which a verify voltage VVFY is applied to the selected word line WL(Sel) to verify whether programming is successful. The program period of the program loop LOOPi may include a precharge period USIP (in FIG. 16B) and a program execution period PGM_EXE (in FIG. 16B). In some implementations, the program period of a first program loop LOOP1 is described. The precharge period USIP of the program period may refer to the period between the time point T1 and the time point T2, and the program execution period PGM_EXE may refer to the period between the time point T2 and the time point T3. This is just an example only intended for help with understanding and does not limit the inventive concept. The other program loops (LOOP2, LOOP3, . . . ) are the same as the first program loop LOOP1, except that the program voltages (VPGM1, VPGM2, VPGM3, . . . ) applied to the selected word line WL(Sel) in the program execution period PGM_EXE increase stepwise.

In FIG. 16B, because the word lines WL of the first sub-block SubBLK1 are respectively connected to the word lines WL of the second sub-block SubBLK2 in the memory block BLK1, a pass voltage VPASS may be applied to the selected word line WL(Sel) (e.g., ST3_WLn(Sel) in FIG. 18) and unselected word lines WL(Unsel) in each of the first sub-block SubBLK1 and the second sub-block SubBLK2 of the memory block BLK1 in the precharge period USIP. According to some implementations, the pass voltage VPASS may be set to a level, which turns on a memory cell transistor and is higher than the level of the power supply voltage VDD.

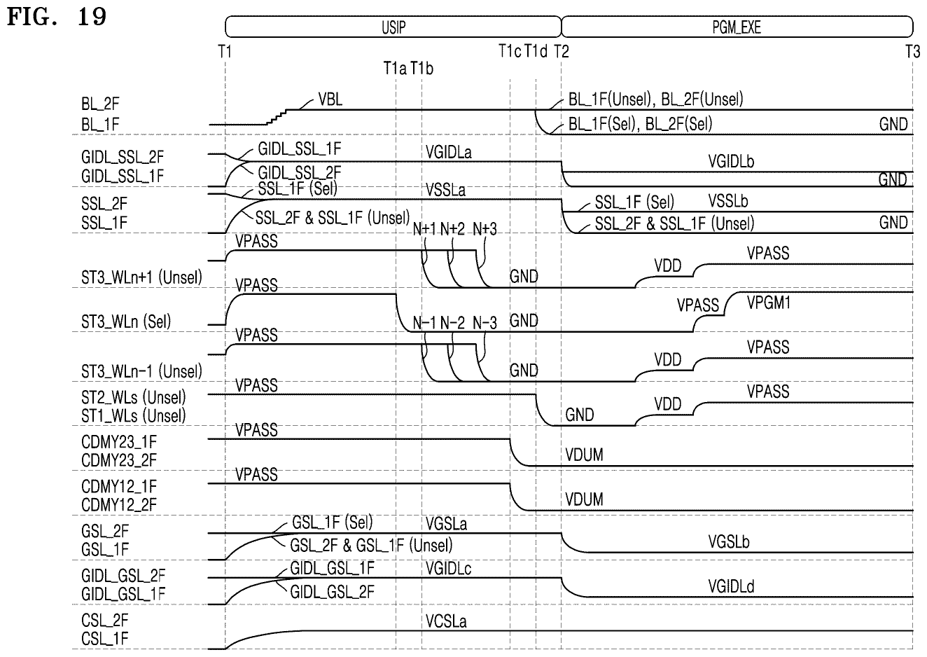

In some implementations, before the precharge period USIP ends (e.g., at a time point T1d in FIG. 19), the selected word line WL(Sel), the unselected word lines WL(Unsel), and dummy word lines of the first sub-block SubBLK1 and the second sub-block SubBLK2 may be recovered to the level of the ground voltage GND or the level of a channel cut-off voltage VDUM (in FIG. 19). Accordingly, because memory cell transistors of each of the first sub-block SubBLK1 and the second sub-block SubBLK2 are turned off, a current path is not generated between the bit line BL_1F or BL_2F and the common source line CSL_1F or CSL_2F.

In the first sub-block SubBLK1, a bit line voltage VBL at a program-inhibition voltage level may be applied to a selected bit line BL_1F(Sel) connected to the selected memory cell, and the bit line voltage VBL may also be applied to unselected bit lines BL_1F(Unsel). According to some implementations, the bit line voltage VBL may have the level of the power supply voltage VDD. A turn-on voltage VSSLa, which turns on the SST, may be applied to a selected string select line SSL_1F(Sel) and an unselected string select line SSL_1F(Unsel). A turn-on voltage VGSLa, which turns on the GST, may be applied to a selected ground select line GSL_1F(Sel) and an unselected ground select line GSL_1F(Unsel). A first common source line voltage VCSLa may be applied to the common source line CSL_1F. According to some implementations, the first common source line voltage VCSLa may have the level of the power supply voltage VDD.

In the second memory block BLK2, the bit line voltage VBL may be applied to unselected bit lines BL_2F(Unsel), the turn-on voltages VSSLa and VGSLa may be respectively applied to unselected string select lines SSL_2F(Unsel) and unselected ground select line GSL_2F(Unsel), and the first common source line voltage VCSLa may be applied to the common source line CSL_2F.

In the precharge period USIP, channels of the cell strings of the first sub-block SubBLK1 and the second sub-block SubBLK2 may be precharged through the selected SST, which is connected to the selected string select line SSL_1F(Sel) and the unselected string select lines SSL_1F(Unsel) and SSL_2F(Unsel), and the GST, which is connected to the selected ground select line GSL_1F(Sel) and the unselected ground select lines GSL_1F(Unsel) and GSL_2F(Unsel). This means a bidirectional precharge scheme. The channel potential of the first sub-block SubBLK1 and the second sub-block SubBLK2 may be stably boosted by precharging performed in two directions, i.e., the direction of the bit line BL_1F or BL_2F and the direction of the common source line CSL_1F or CSL_2F.

In the program execution period PGM_EXE, the ground voltage GND, the pass voltage VPASS, and the program voltage VPGM1 may be sequentially applied to the selected word line WL(Sel) of the first sub-block SubBLK1 of the memory block BLK1. The ground voltage GND, the power supply voltage VDD, and the pass voltage VPASS may be sequentially applied to the unselected word lines WL(Unsel).

In the first sub-block SubBLK1, the ground voltage GND may be applied to the selected bit line BL_1F(Sel), and the bit line voltage VBL may be applied to the unselected bit lines BL_1F(Unsel). A turn-on voltage VSSLb (where VSSLb<VSSLa), which turns on the SST, may be applied to the selected string select line SSL_1F(Sel), and the ground voltage GND may be applied to the unselected string select line SSL_1F(Sel). A turn-off voltage VGSLb, which turns off the GST, may be applied to the selected ground select line GSL_1F(Sel) and the unselected ground select line GSL_1F(Unsel). The first common source line voltage VCSLa may be applied to the common source line CSL_1F.

In the second sub-block SubBLK2, the bit line voltage VBL may be applied to the unselected bit lines BL_2F(Unsel), the ground voltage GND orthe turn-off voltage VGSLb may be applied to the unselected string select line SSL_2F(Unsel) and the unselected ground select line GSL_2F(Unsel), and the first common source line voltage VCSLa may be applied to the common source line CSL_2F.

In the program execution period PGM_EXE, the program voltage VPGM1 at a high level may be applied to the gate of the selected memory cell to be programmed in the first sub-block SubBLK1, and the channel of the selected memory cell may be at the level of the ground voltage GND. Because a strong electric field is formed between the gate and the channel of the selected memory cell, the selected memory cell may be programmed. The pass voltage VPASS may be applied to the gate of a first unselected memory cell adjacent to the selected memory cell of the first sub-block SubBLK1, and the channel of the first unselected memory cell may have the bit line voltage VBL at the level of the power supply voltage VDD. Because a weak electric field is formed between the gate and the channel of the first unselected memory cell, the first unselected memory cell may not be programmed. The pass voltage VPASS may be applied to the gates of second unselected memory cells adjacent to the selected memory cell, and the channels of the second unselected memory cells may be at the level of the ground voltage GND. Because the second unselected memory cells are in a floating state due to an unselected string select line SSL(Unsel), the channels of the second unselected memory cells may be increased to a boosting level by the pass voltage VPASS, and the second unselected memory cells may not be programmed.

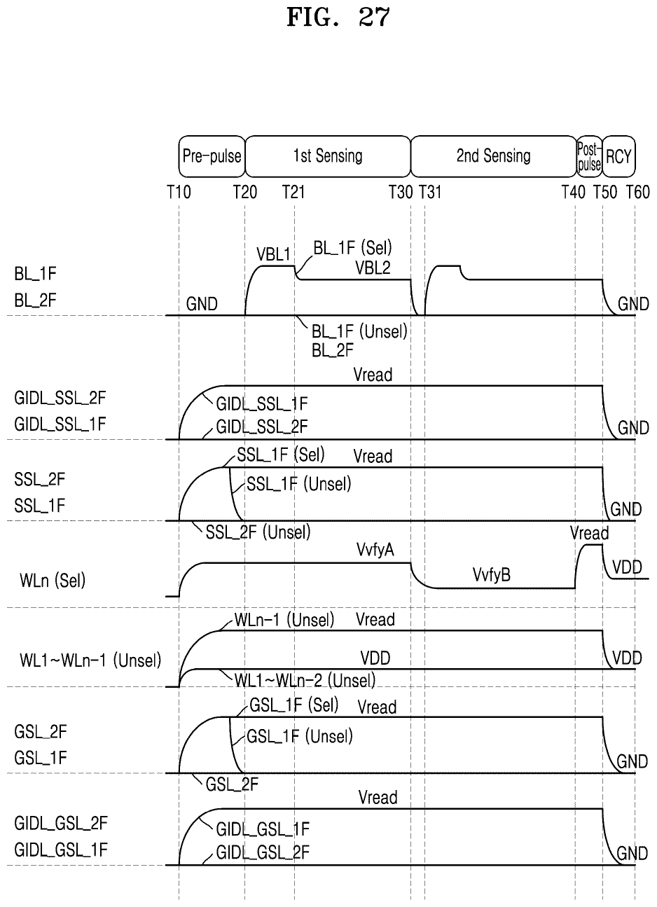

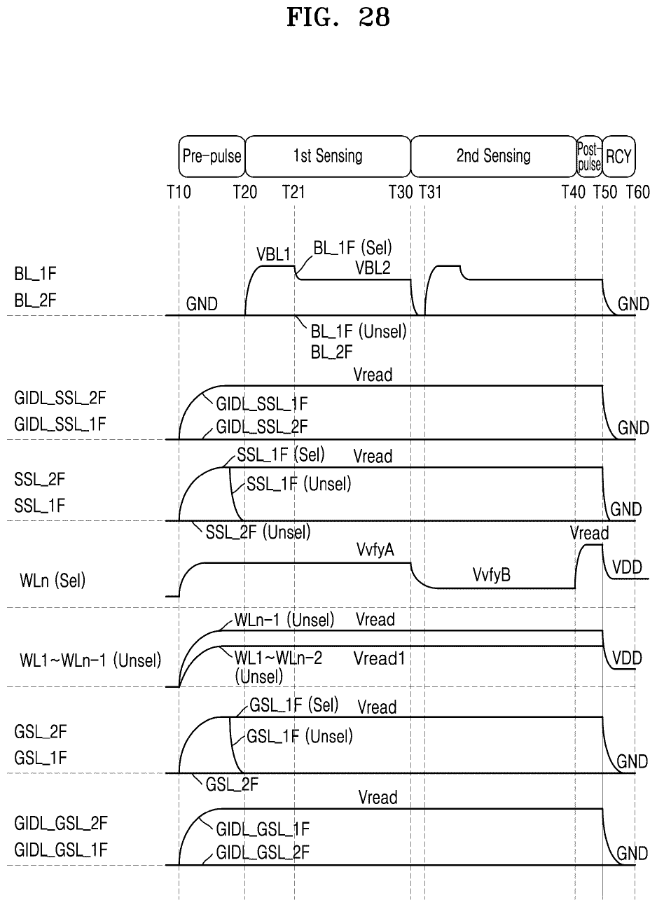

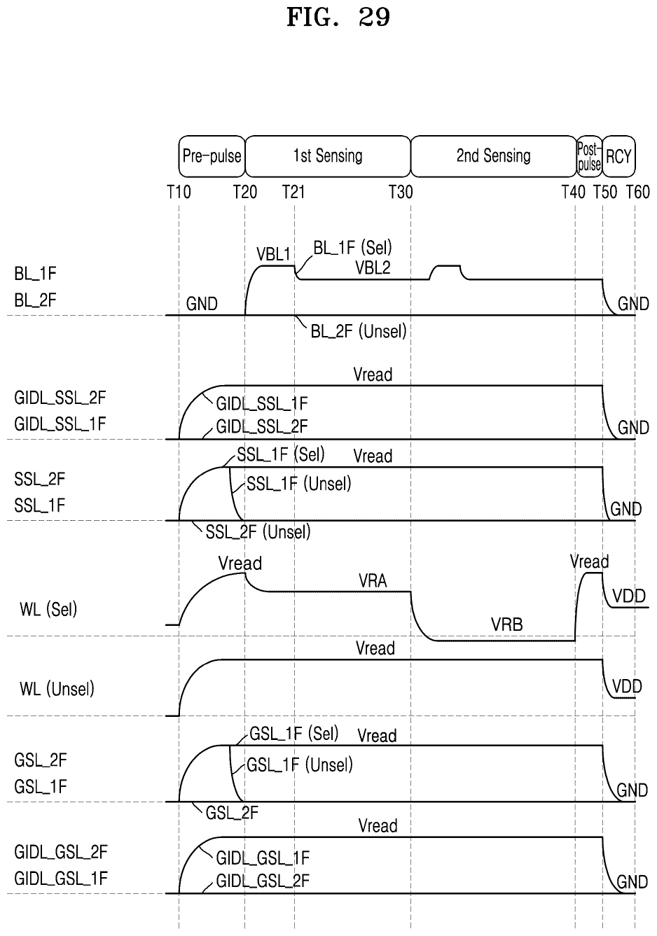

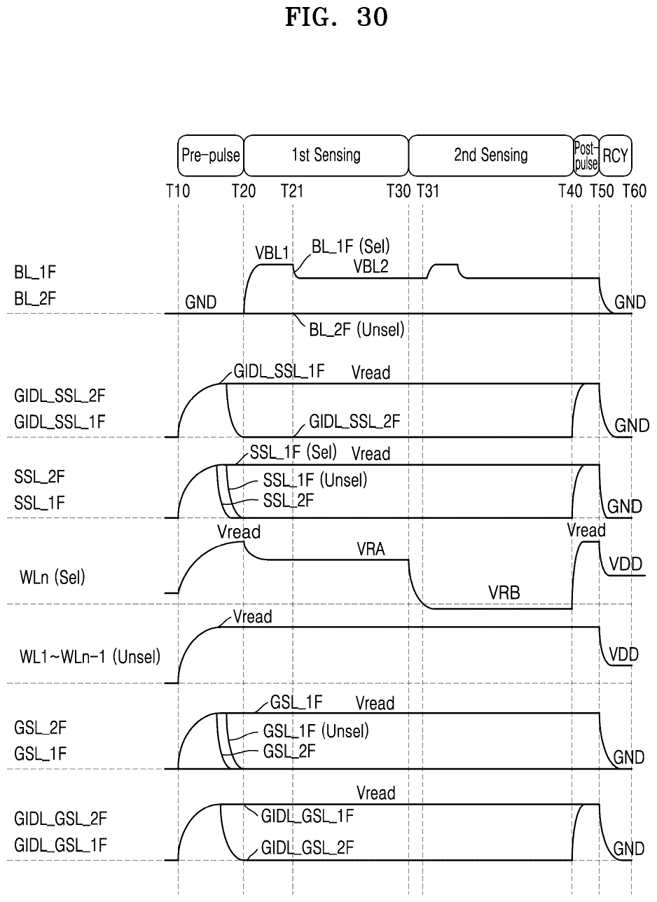

FIG. 16C shows first to eighth states E and P1 to P7 of a triple-level cell (TLC) that stores 3-bit data. In FIG. 16C, the horizontal axis indicates a threshold voltage Vth of a memory cell and the vertical axis indicates the number of cells (for example, memory cells) corresponding to the threshold voltage (for example, the transistor threshold voltage) Vth. In a program operation, programming results with respect to the first to eighth states E and P1 to P7 may be determined by applying first to seventh verify voltages Vvfy1 to Vvfy7 to a selected word line, as described below with reference to FIGS. 27 and 28. In a read operation, the first to eighth states E and P1 to P7 may be determined by applying a portion of first to seventh read voltages VR1 to VR7 to a selected word line, as described below with reference to FIGS. 29 and 30.

FIG. 16D illustrates a method of reading TLCs by pages. In FIG. 16D, each of the memory cells connected to a single word line (sometimes, referred to as a page) may be in an erased state E indicating data “111”, a first programmed state P1 indicating data “110”, a second programmed state P2 indicating data “100”, a third programmed state P3 indicating data “000”, a fourth programmed state P4 indicating data “010”, a fifth programmed state P5 indicating data “011”, a sixth programmed state P6 indicating data “001”, or a seventh programmed state P7 indicating data “101”.

A least significant bit (LSB) page read operation on the memory cells may include a fifth programmed state read operation RDP5, which distinguishes the fifth programmed state P5 from the fourth programmed state P4 adjacent to the fifth programmed state P5, and a first programmed state read operation RDP1, which distinguishes the first programmed state P1 from the erased state E adjacent to the first programmed state P1. In some implementations, the fifth programmed state read operation RDP5 may be performed prior to the first programmed state read operation RDP1.

A central significant bit (CSB) page read operation on the memory cells may include a sixth programmed state read operation RDP6, which distinguishes the sixth programmed state P6 from the fifth programmed state P5 adjacent to the sixth programmed state P6, a fourth programmed state read operation RDP4, which distinguishes the fourth programmed state P4 from the third programmed state P3 adjacent to the fourth programmed state P4, and a second programmed state read operation RDP2, which distinguishes the second programmed state P2 from the first programmed state P1 adjacent to the second programmed state P2. In some implementations, the sixth programmed state read operation RDP6, the fourth programmed state read operation RDP4, and the second programmed state read operation RDP2 may be sequentially performed.

A most significant bit (MSB) page read operation on the memory cells may include a seventh programmed state read operation RDP7, which distinguishes the seventh programmed state P7 from the sixth programmed state P6 adjacent to the seventh programmed state P7, and a third programmed state read operation RDP3, which distinguishes the third programmed state P3 from the second programmed state P2 adjacent to the third programmed state P3. In some implementations, the seventh programmed state read operation RDP7 may be performed prior to the third programmed state read operation RDP3.

Although FIG. 16D shows an example in which the memory cells are TLCs each storing 2-bit data, the memory cells of a memory device according to some implementations may include any multi-level cells. For example, the memory cells may include a quadruple-level cells (QLCs) each storing 4-bit data but are not limited thereto.

In FIG. 17, each of the cell string NS of each of the first sub-block SubBLK1 and the second sub-block SubBLK2 of the memory block BLK1 of the memory device 10c may include a plurality of stacks, e.g., first to third stacks ST1, ST2, and ST3, and third dummy word lines CDMY12_1F and CDMY23_1F or CDMY12_2F and CDMY23_2F, which are near the boundaries among the first to third stacks ST1, ST2, and ST3.

It is assumed that a selected word line ST3_WLn(Sel) corresponding to a program address is included in the third stack ST3 of the first sub-block SubBLK1. The third stack ST3 may correspond to a selected stack to be programmed, and the first stack ST1 and the second stack ST2 may correspond to unselected stacks. According to the operating scenario of the memory device 10c, a program operation, in which word lines are sequentially programmed downwards starting from the top word line, may be performed. In the first sub-block SubBLK1, the memory cells MCs of a programmed word line of the selected stack, i.e., the third stack ST3, may each be in an erased (Erase) state or a programmed (PGM) state according to data programmed thereto, and the memory cells of each of the second stack ST2 and the first stack ST1, which are below the third stack ST3, may all be in the erased state.

The timing diagram of FIG. 18 illustrates a program operation of the first memory block BLK1 in connection with FIGS. 8, 16B, and 17, in which the period from the time point T1 to the time point T2 may correspond to the precharge period USIP, and the period from the time point T2 to the time point T3 may correspond to the program execution period PGM_EXE.

During the precharge period USIP, in the first sub-block SubBLK1 and the second sub-block SubBLK2, the bit line voltage VBL may be applied to all bit lines BL_1F and BL_2F, and a turn-on voltage (e.g., VGIDLa, VSSLa, VGIDLc, or VGSLa) may be applied to the first string select lines GIDL_SSL_1F and GIDL_SSL_2F, the second string select lines SSL_1F and SSL_2F, the first ground select lines GIDL_GSL_1F and GIDL_GSL_2F, or the second ground select lines GSL_1F and GSL_2F. The first common source line voltage VCSLa may be applied to the common source lines CSL_1F and CSL_2F. In the first sub-block SubBLK1 and the second sub-block SubBLK2, the pass voltage VPASS may be applied to the selected word line ST3_WLn(Sel), to unselected word lines ST3_WLn+1(Unsel), ST3_WLn−1(Unsel), ST2_WLs(Unsel), and ST1_WLs(Unsel), and to the third dummy word lines CDMY12_1F, CDMY23_1F, CDMY12_2F, and CDMY23_2F.

The selected word line ST3_WLn(Sel), the unselected word lines ST3_WLn+1(Unsel), ST3_WLn−1(Unsel), ST2_WLs(Unsel), and ST1_WLs(Unsel), and the third dummy word lines CDMY12_1F, CDMY23_1F, CDMY12_2F, and CDMY23_2F, to which the pass voltage VPASS has been applied, may be recovered to the level of the ground voltage GND or the channel cut-off voltage VDUM before the program execution period PGM_EXE. In the period between the time point T1 and the time point T2, the selected word line ST3_WLn(Sel) may be recovered to the level of the ground voltage GND at the time point T1a, the unselected word lines ST3_WLn+1(Unsel) and ST3_WLn−1(Unsel) may be recovered to the level of the ground voltage GND at the time point T1b, the third dummy word lines CDMY12_1F, CDMY23_1F, CDMY12_2F, and CDMY23_2F may be recovered to the level of the channel cut-off voltage VDUM at the time point T1c, and the unselected word lines ST2_WLs(Unsel) and ST1_WLs(Unsel) may be recovered to the level of the ground voltage GND at the time point T1d. This may mean that after the selected word line ST3_WLn(Sel) is recovered, the unselected word lines are sequentially recovered from those (e.g., the unselected word lines ST3_WLn+1(Unsel) and ST3_WLn−1(Unsel)) close to the selected word line ST3_WLn(Sel). This may also mean that after the third dummy word lines CDMY12_1F, CDMY23_1F, CDMY12_2F, and CDMY23_2F near the boundaries among the first to third stacks ST1, ST2, and ST3 are recovered, the unselected word lines ST2_WLs(Unsel) and ST1_WLs(Unsel) of the unselected stacks, i.e., the second and first stacks ST2 and ST1, are recovered, so that charge sharing may be prevented.

During the program execution period PGM_EXE, the ground voltage GND, the power supply voltage VDD, and the pass voltage VPASS may be sequentially applied to each of the unselected word lines ST3_WLn+1(Unsel), ST3_WLn−1(Unsel), ST2_WLs(Unsel), and ST1_WLs(Unsel) of each of the first sub-block SubBLK1 and the second sub-block SubBLK2 of the memory block BLK1. The ground voltage GND, the pass voltage VPASS, and the program voltage VPGM1 may be sequentially applied to the selected word line ST3_WLn(Sel).

In the first sub-block SubBLK1, the ground voltage GND may be applied to the selected bit line BL_1F(Sel), and the bit line voltage VBL may be applied to the unselected bit line BL_1F(Unsel). A turn-on voltage VGIDLb (VGIDLb<VGIDLa), which turns on the SST, may be applied to a first selected string select line GIDL_SSL_1F(Sel), and the ground voltage GND may be applied to a first unselected string select line GIDL_SSL_1F(Unsel). The turn-on voltage VSSLb may be applied to a second selected string select line SSL_1F(Sel), and the ground voltage GND may be applied to a second unselected string select line SSL_1F(Unsel). The turn-off voltage VGSLb may be applied to a second selected ground select line GSL_1F(Sel) and a second unselected ground select line GSL_1F(Unsel). A turn-off voltage VGIDLd may be applied to a first selected ground select line GIDL_GSL_1F(Sel) and a first unselected ground select line GIDL_GSL_1F(Unsel). The first common source line voltage VCSLa may be applied to the common source line CSL_1F.

In the second sub-block SubBLK2, the bit line voltage VBL may be applied to the unselected bit line BL_2F(Unsel), the ground voltage GND or a turn-off voltage VGIDLd or VGSLb may be applied to the first string select line GIDL_SSL_2F, the second string select line SSL_2F, second ground select line GIDL_GSL_2F, andthe first ground select line GSL_2F, which are unselected, and the first common source line voltage VCSLa may be applied to the common source line CSL_2F. Accordingly, in the cell strings NS of the second sub-block SubBLK2, the electrical connection between the unselected bit line BL_2F(Unsel) and the common source line CSL_2F may be cut off so that the memory cells of the second sub-block SubBLK2 may not be programmed.

In the program execution period PGM_EXE, the program voltage VPGM1 at a high level may be applied to the gate of a selected memory cell connected to the selected word line ST3_WLn(Sel) of the first sub-block SubBLK1, and the channel of the selected memory cell may be at the level of the ground voltage GND, so that a strong electric field may be formed between the gate and the channel of the selected memory cell. As a result, the selected memory cell may be programmed. The pass voltage VPASS may be applied to the gate of a first memory cell adjacent to the selected memory cell of the first sub-block SubBLK1, and a channel voltage may be at the level of the ground voltage GND, so that a weak electric field may be formed between the gate and the channel of the first memory cell adjacent to the selected memory cell. As a result, the first memory cell may not be programmed. Because the channels of second memory cells adjacent to the selected memory cell may float due to the second unselected string select line SSL_1F(Unsel) at the level of the ground voltage GND, a channel voltage may be increased to a boosting level by the pass voltage VPASS, and the second memory cells adjacent to the selected memory cell may not be programmed.

FIG. 19 is a timing diagram illustrating an example of a program operation of the first memory block BLK1 described with reference to FIGS. 6A and 6B. In the first memory block BLK1 described with reference to FIGS. 6A and 6B, the word lines WL1 to WL8 of the first sub-block SubBLK1 may be respectively connected to the word lines WL1 to WL8 of the second sub-block SubBLK2, the bit line BL_1F of the first sub-block SubBLK1 may be connected to the bit line BL_2F of the second sub-block SubBLK2, and the common source line CSL_1F of the first sub-block SubBLK1 and the common source line CSL_2F of the second sub-block SubBLK2 are connected to one common source line CSL. Redundant descriptions given with reference to FIG. 18 are omitted from the description of the timing diagram of FIG. 19.

In the timing diagram of FIG. 19, in connection with FIGS. 8, 16B, and 17, during the precharge period USIP, the bit line voltage VBL may be applied to all bit lines BL_1F and BL_2F of the first sub-block SubBLK1 and the second sub-block SubBLK2. During the program execution period PGM_EXE, the ground voltage GND may be applied to the selected bit lines BL_1F(Sel) and BL_2F(Sel), and the bit line voltage VBL may be applied to the unselected bit lines BL_1F(Unsel) and BL_2F(Unsel).

In the program execution period PGM_EXE, because the ground voltage GND or the turn-off voltage VGSLb or VGIDLd are applied to the second string select line SSL_2F and the first string select line GIDL_SSL_2F, which are unselected, the second unselected ground select line GSL_2F(Unsel), and the first unselected ground select line GIDL_GSL_2F(Unsel) even though the bit line voltage VBL is applied to the unselected bit lines BL_2F(Unsel) of the second sub-block SubBLK2, the electrical connection between the unselected bit lines BL_2F(Unsel) and the common source line CSL_2F may be cut off so that the memory cells of the second sub-block SubBLK2 may not be programmed.

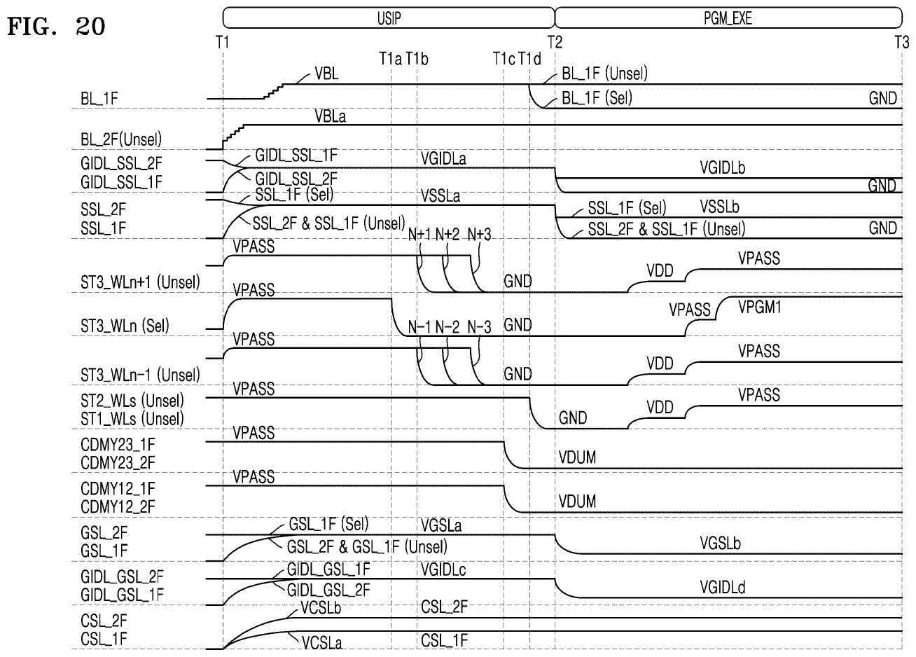

FIG. 20 is a timing diagram illustrating an example of a program operation of the first memory block BLK1 described with reference to FIGS. 3A and 3B. In the first memory block BLK1 described with reference to FIGS. 3A and 3B, the word lines WL1 to WL8 of the first sub-block SubBLK1 may be respectively connected to the word lines WL1 to WL8 of the second sub-block SubBLK2. Redundant descriptions given with reference to FIG. 19 are omitted from the description of the timing diagram of FIG. 20.

In the timing diagram of FIG. 20, in connection with FIGS. 8, 16B, and 17, during the precharge period USIP and the program execution period PGM_EXE, different voltages may be applied to the common source line CSL_1F of the first sub-block SubBLK1 and the common source line CSL_2F of the second sub-block SubBLK2. The first common source line voltage VCSLa may be applied to the common source line CSL_1F of the first sub-block SubBLK1, and a second common source line voltage VCSLb may be applied to the common source line CSL_2F of the second sub-block SubBLK2. According to some implementations, the level of the second common source line voltage VCSLb may be higher than the level of the first common source line voltage VCSLa.

In the precharge period USIP, a first bit line voltage VBL may be applied to the bit line BL_1F of the first sub-block SubBLK1, and a second bit line voltage VBLa that is higher than the first bit line voltage VBL may be applied to the bit line BL_2F of the second sub-block SubBLK2. The first common source line voltage VCSLa may be applied to the common source line CSL_1F of the first sub-block SubBLK1, and the second common source line voltage VCSLb may be applied to the common source line CSL_2F of the second sub-block SubBLK2. The level of the first bit line voltage VBL applied to the first sub-block SubBLK1 may be set to be the same as the level of the first common source line voltage VCSLa, and the level of the second bit line voltage VBLa applied to the second sub-block SubBLK2 may be set to be the same as the level of the second common source line voltage VCSLb.

In the precharge period USIP, the channels of the cell strings NS of the first sub-block SubBLK1 and the second sub-block SubBLK2 may be precharged through an SST, which is connected to a selected string select line (e.g., SSL_1F(Sel)) and unselected string select lines (e.g., SSL_1F(Unsel) and SSL_2F(Unsel)), and a GST, which is connected to a selected ground select line (e.g., GSL_1F(Sel)) and unselected ground select lines (e.g., GSL_1F(Unsel) and GSL_2F(Unsel)), and accordingly, the channel potential of the second sub-block SubBLK2 may be stably boosted.

In the program execution period PGM_EXE, when the second common source line voltage VCSLb is applied to the common source line CSL_2F of the second sub-block SubBLK2, the ground voltage GND or the turn-off voltage VGSLb or VGIDLd may be applied to each of the second string select line SSL_2F and the first string select line GIDL_SSL_2F, which are unselected, the second unselected ground select line GSL_2F(Unsel), and the first unselected ground select line GIDL_GSL_2F(Unsel). Accordingly, the electrical connection between the unselected bit lines BL_2F(Unsel) and the common source line CSL_2F may be cut off so that the memory cells of the second sub-block SubBLK2 may not be programmed.

A precharge operation (sometimes, referred to as an ISPP_USIP precharge operation) performed in the precharge period USIP of the program operation described with reference to FIGS. 18 to 20 may be performed in the same manner in the first sub-block SubBLK1 that is a selected sub-block and the second sub-block SubBLK2 that is a sister sub-block and may be performed in each of the program loops (LOOP1, LOOP2, LOOP3, . . . ) according to the ISPP of a page corresponding to the selected word line ST3_WLn(Sel) described with reference to FIG. 16A. Accordingly, the program operation of the memory device 10c may take long. When a precharge operation is performed for a certain page or each of certain pages, the programming time of the memory device 10c may be reduced.

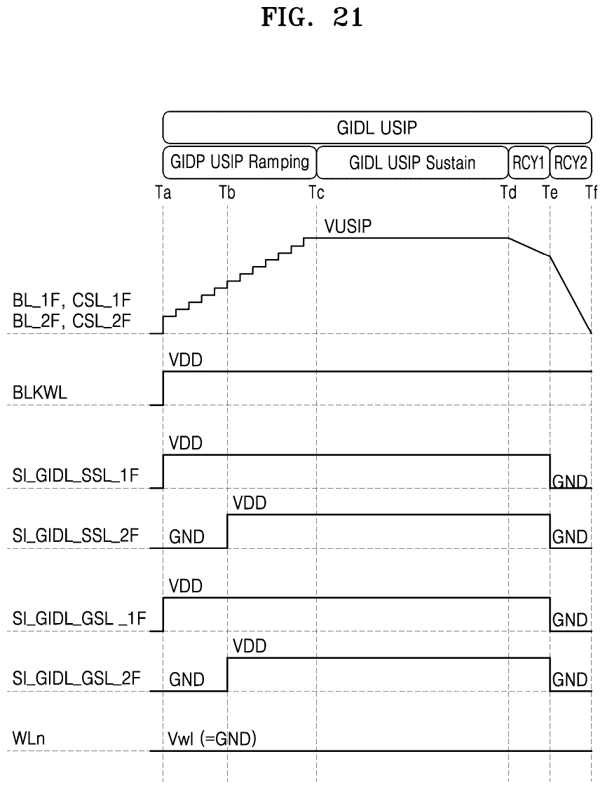

FIGS. 21 to 26 are diagrams illustrating examples of program methods according to some implementations. FIG. 21 is a timing diagram illustrating a GIDL_USIP precharge operation as an example modification of an ISPP_USIP precharge operation performed in the precharge period USIP described with reference to FIGS. 18 to 20. In the GIDL_USIP precharge operation, GIDL current (I_{GIDL}) caused by an SST and a GST may be generated using the first string select line GIDL_SSL_2F and the first ground select line GIDL_GSL_2F, which have floated with a delay, thereby increasing the channel potential of the second sub-block SubBLK2. For convenience of description, the ISPP_USIP precharge operation may be referred to as a first precharge operation, and the GIDL_USIP precharge operation may be referred to as a second precharge operation.

In FIG. 21, the block select signal BLKWL selecting the memory block BLK1 may be activated at a time point Ta. The block select signal BLKWL may be provided at the level of the power supply voltage VDD. A precharge voltage VUSIP increasing stepwise may be applied to the common source line CSL_1F and the bit line BL_1F of the first sub-block SubBLK1 and the common source line CSL_2F and the bit line BL_2F of the second sub-block SubBLK2. The level of the precharge voltage VUSIP may increase from the time point Ta to a time point Tc and may be lower than the level of the erase voltage Verase at the time point Tc. A period between the time point Ta and the time point Tc may be referred to as a precharge ramping period.

At the time point Ta, the level of the power supply voltage VDD may be provided to the first string select line driving signal SI_GIDL_SSL_1F and the first ground select line driving signal SI_GIDL_GSL_1F of the first sub-block SubBLK1. The level of the ground voltage GND may be provided to the first string select line driving signal SI_GIDL_SSL_2F and the first ground select line driving signal SI_GIDL_GSL_2F of the second sub-block SubBLK2. Because the word lines WLn of the first sub-block SubBLK1 of the memory block BLK1 are respectively connected to the word lines WLn of the second sub-block SubBLK2 of the memory block BLK1, the word line voltage Vwl at the level of the ground voltage GND may be applied to the word lines WLn of the first sub-block SubBLK1 and the second sub-block SubBLK2 of the memory block BLK1.

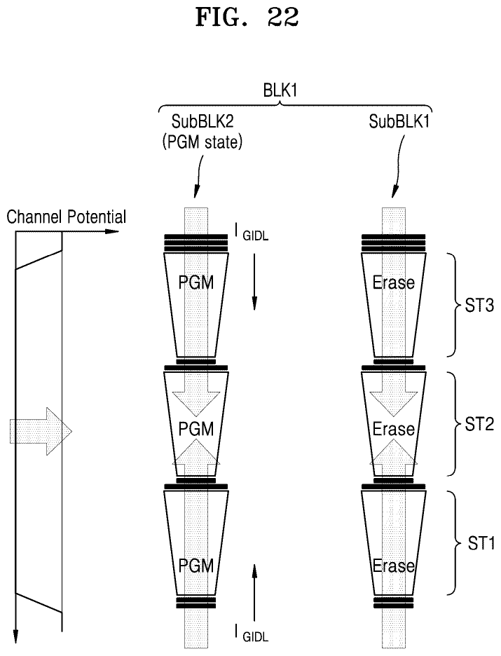

At a time point Tb, the first string select line driving signal SI_GIDL_SSL_2F and the first ground select line driving signal SI_GIDL_GSL_2F of the second sub-block SubBLK2 may float at the level of the ground voltage GND and may be coupled to the power supply voltage VDD of the block select signal BLKWL. Because the first string select line driving signal SI_GIDL_SSL_2F and the first ground select line driving signal SI_GIDL_GSL_2F reach the level of the power supply voltage VDD after a certain time delay at the level of ground voltage GND, the first string select line GIDL_SSL_2F and the first ground select line GIDL_GSL_2F may float at the level of the ground voltage GND. Due to coupling to the precharge voltage VUSIP of the bit line BL_2F and the common source line CSL_2F of the second sub-block SubBLK2, the potential of the first string select line GIDL_SSL_2F and the first ground select line GIDL_GSL_2F, which float, may increase, and the SST and the GST may be turned off. GIDL current caused by the SST and the GST may flow in a channel direction, and hot holes generated in the drains of the SST and the GST may flow in the channel direction. Accordingly, as shown in FIG. 22, the channel potential of the cell strings NS of the first sub-block SubBLK1 may increase.

From the time point Tc to a time point Td, the common source lines CSL_1F and CSL_2F and the bit lines BL_1F and BL_2F of the first sub-block SubBLK1 and the second sub-block SubBLK2 may be continuously at the level of the precharge voltage VUSIP. At the time point Td, a precharge recovery operation may be performed on the memory block BLK1. The level of the precharge voltage VUSIP, which is applied to the common source line CSL_1F and the bit line BL_1F of the first sub-block SubBLK1 and the common source line CSL_2F and the bit line BL_2F of the second sub-block SubBLK2, may decrease. At a time point Te, the first ground select line driving signals SI_GIDL_GSL_1F and SI_GIDL_GSL_2F and the first string select line driving signals SI_GIDL_SSL_1F and SI_GIDL_SSL_2F of the first sub-block SubBLK1 and the second sub-block SubBLK2 may be recovered to the level of the ground voltage GND. A period between the time point Tc and the time point Td may be referred to as a precharge sustain period, a period between the time point Td and the time point Te may be referred to as a first precharge recovery period RCY1, and a period between the time point Te and a time point Tf may be referred to as a second precharge recovery period RCY2.

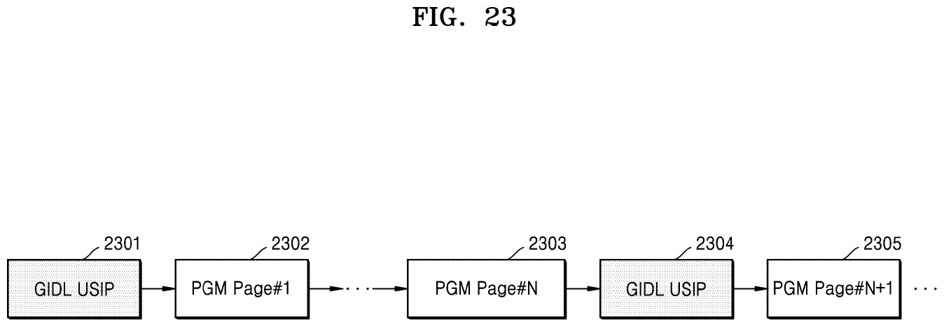

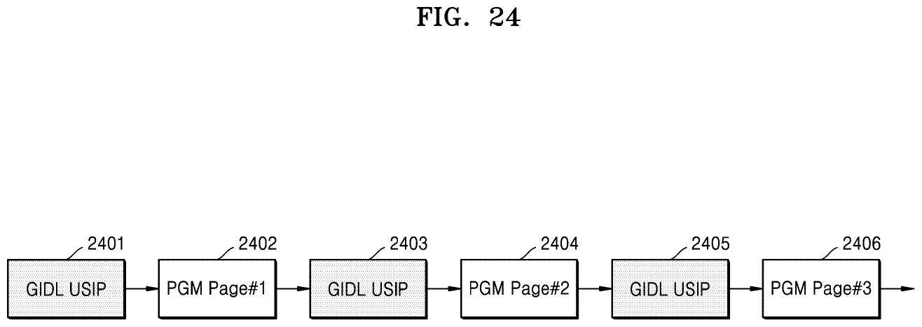

The GIDL_USIP precharge operation of FIG. 21 may be used when the number of programmed memory cells in the second sub-block SubBLK2 is greater than a certain number (e.g., N), that is, when the second sub-block SubBLK2 is in a programmed state. The GIDL_USIP precharge operation may be used in the program methods of FIGS. 23 and 24.

In FIG. 23, in the program operation of the memory block BLK1, a GIDL_USIP precharge operation (GIDL USIP) 2301 or 2304 may be performed in a program operation (e.g., 2302 or 2303) of a certain page. For example, the GIDL_USIP precharge operation 2301, a first page program operation (PGM Page#1) 2302, . . . , an N-th page program operation (PGM Page#N) 2303, the GIDL_USIP precharge operation 2304, and an (N+1)-th page program operation (PGM Page#N+1) 2305 may be sequentially performed.

In FIG. 24, in the program operation of the memory block BLK1, a GIDL_USIP precharge operation 2401, 2403, or 2405 may be performed in a program operation (e.g., 2402, 2404, or 2306) of each page. For example, the GIDL_USIP precharge operation 2401, a first page program operation 2402, the GIDL_USIP precharge operation 2403, a second page program operation (PGM Page#2) 2404, the GIDL_USIP precharge operation 2405, and a third page program operation (PGM Page#3) 2406 may be sequentially performed.

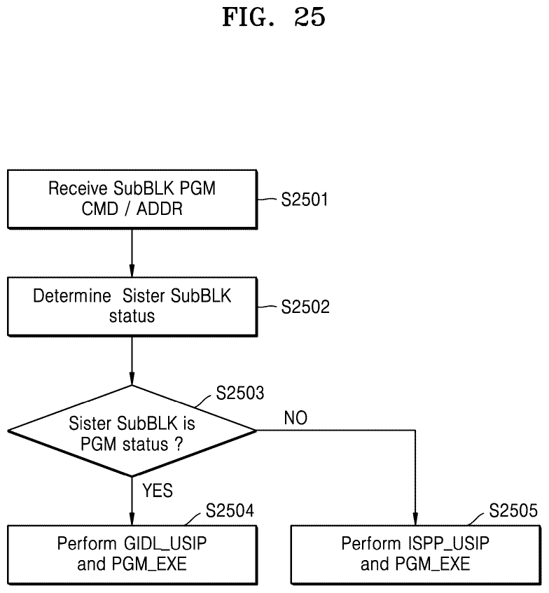

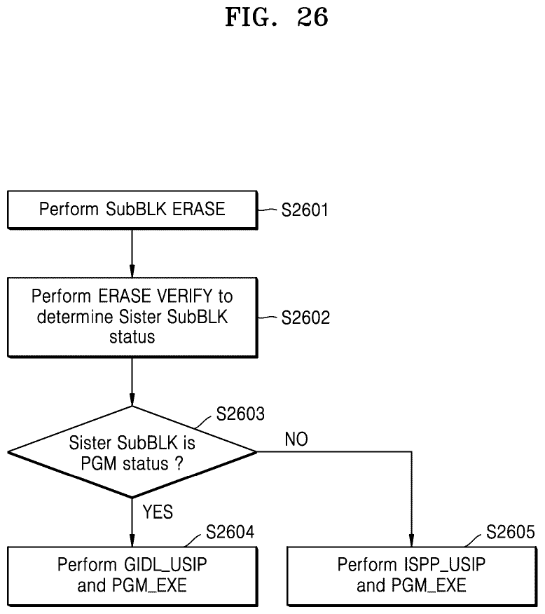

FIGS. 25 and 26 are flowcharts of examples of program operations of the memory block BLK1 according to some implementations. FIGS. 25 and 26 illustrate program operations of the first sub-block SubBLK1 of the memory block BLK1 of the memory device 10c of FIG. 17.

In FIG. 25, the memory device 10c may receive a command and an address for a program operation of the first sub-block SubBLK1, which is the selected sub-block of the memory block BLK1, in operation S2501.

The memory device 10c may determine whether the second sub-block SubBLK2 that is a sister sub-block in the memory block BLK1 is in a programmed state or an erased state in operation S2502. Operation S2502 may be performed in a program verify period (e.g., a verify period in which the verify voltage VVFY is applied to a selected word line after a program period of the first program loop LOOP1 in FIG. 16A).

When the second sub-block SubBLK2 that is the sister sub-block is determined to be in the programmed state in operation S2503 (i.e., in case of YES in operation S2503), operation S2504 may be performed. The memory device 10c may perform a GIDL_USIP precharge operation and a program execution operation for the program operation of the first sub-block SubBLK1 in operation S2504. The GIDL_USIP precharge operation may be performed in a program operation of each of certain pages of the first sub-block SubBLK1 (see FIG. 23) or may be performed in a program operation of each page of the first sub-block SubBLK1 (see FIG. 24).

When the second sub-block SubBLK2 that is the sister sub-block is determined to be in the erased state (i.e., in case of NO in operation S2502), operation S2505 may be performed. The memory device 10c may perform an ISPP_USIP precharge operation and a program execution operation for the program operation of the first sub-block SubBLK1 in operation S2505. The ISPP_USIP precharge operation may be performed in each of program loops (e.g., LOOP1, LOOP2, LOOP3, . . . ) according to the ISPP of a single page of the first sub-block SubBLK1.

Referring to FIG. 26, the memory device 10c may perform an erase operation on the first sub-block SubBLK1, which is a selected sub-block of the memory block BLK1, in operation S2601.

The memory device 10c may determine whether the second sub-block SubBLK2, i.e., a sister sub-block, is in a programmed state or an erase state in an erase verify operation (see FIG. 7A) during the erase operation on the memory block BLK1 in operation S2602.

When the second sub-block SubBLK2 that is the sister sub-block is determined to be in the programmed state in operation S2603 (i.e., in case of YES in operation S2603), operation S2604 may be performed. The memory device 10c may perform a GIDL_USIP precharge operation and a program execution operation for the program operation of the first sub-block SubBLK1 in operation S2604.

When the second sub-block SubBLK2 that is the sister sub-block is determined to be in the erased state in operation S2603 (i.e., in case of NO in operation S2603), operation S2605 may be performed. The memory device 10c may perform an ISPP_USIP precharge operation and a program execution operation for the program operation of the first sub-block SubBLK1 in operation S2605.

FIGS. 27 and 28 are timing diagrams illustrating examples of program verify methods according to some implementations. FIG. 27 illustrates a program verify method when the second sub-block SubBLK2 that is a sister sub-block is determined to be in an erased state. FIG. 28 illustrates a program verify method when the second sub-block SubBLK2 that is a sister sub-block is determined to be in a programmed state.

The timing diagram of FIG. 27 illustrates a program verify operation of the memory block BLK1 in connection with FIGS. 8, 16A, and 16C, in which a period from a time point T10 to a time point T20 may be referred to as a pre-pulse period, a period from the time point T20 to a time point T30 may be referred to as a first sensing period, a period from the time point T30 to a time point T40 may be referred to as a second sensing period, a period from the time point T40 to a time point T50 may be referred to as a post-pulse period, and a period from the time point T50 to a time point T60 may be referred to as a recovery period RCY.

At the time point T10, the ground voltage GND may be applied to all bit lines BL_1F and BL_2F of the first sub-block SubBLK1 and the second sub-block SubBLK2. A read voltage Vread may be applied to the first string select line GIDL_SSL_1F, the second selected and unselected string select lines SSL_1F(Sel) and SSL_1F(Unsel), the second selected and unselected ground select lines GSL_1F(Sel) and GSL_1F(Unsel), and the first ground select line GIDL_GSL_1F of the first sub-block SubBLK1. The read voltage Vread may be set to a level that turns on an SST and a GST and is higher than the level of the power supply voltage VDD. The ground voltage GND may be applied to the first string select line GIDL_SSL_2F, the second string select line SSL_2F, the second ground select line GSL_2F, and the first ground select line GIDL_GSL_2F of the second sub-block SubBLK2.

Because the word lines WL of the first sub-block SubBLK1 of the first memory block BLK1 are respectively connected to the word lines WL of the second sub-block SubBLK2 of the first memory block BLK1, a verify voltage VvfyA may be applied to the selected word line WLn(Sel) of each of the first sub-block SubBLK1 and the second sub-block SubBLK2 of the first memory block BLK1. The verify voltage VvfyA may be one of the first to seventh verify voltages Vvfy1 to Vvfy7. The read voltage Vread may be applied to an unselected word line WLn-1(Unsel), and the power supply voltage VDD may be applied to unselected word lines WL1˜WLn-2(Unsel), so that memory cells connected to the unselected word lines WL1˜WLn-1(Unsel) of the first sub-block SubBLK1 and the second sub-block SubBLK2 may be turned on when the memory cells are in an erased state.

In the period between the time point T10 and the time point T20, the second unselected string select line SSL_1F(Unsel) and the second unselected ground select line GSL_1F(Unsel) of the first sub-block SubBLK1 may be changed from the level of the read voltage Vread to the level of the ground voltage GND. Accordingly, hot carrier injection (HCI) may be prevented from occurring in channels of the first sub-block SubBLK1 by negative boosting. At the time point T20, a first precharge voltage VBL1 may be applied to the selected bit line BL_1F(Sel) of the first sub-block SubBLK1. At a time point T21, a second precharge voltage VBL2 that is lower than the first precharge voltage VBL1 may be applied to the selected bit line BL_1F(Sel) of the first sub-block SubBLK1.

In a period between the time point T30 and a time point T31, to perform the second sensing operation, the ground voltage GND may be applied to the selected bit line BL_1F(Sel) of the first sub-block SubBLK1, and a verify voltage VvfyB that has a different level than the verify voltage VvfyA may be applied to the selected word line WLn(Sel).

After the first precharge voltage VBL1 is applied to the selected bit line BL_1F(Sel) of the first sub-block SubBLK1 at the time point T31, the second precharge voltage VBL2 may be applied to the selected bit line BL_1F(Sel) of the first sub-block SubBLK1. According to the operating scenario of the memory device 10c, the level of the verify voltage VvfyB in the second sensing period may gradually decrease or increase from the level of the verify voltage VvfyA in the first sensing period.

In the period between the time point T40 and the time point T50, the selected word line WLn(Sel) of the first sub-block SubBLK1 and the second sub-block SubBLK2 of the first memory block BLK1 may be increased from the level of the verify voltage VvfyB to the level of the read voltage Vread. In the period between the time point T50 and the time point T60, the selected bit line BL_1F(Sel) of the first sub-block SubBLK1 may be recovered to the level of the ground voltage GND. In addition, the first ground select lines GIDL_GSL_1F and GIDL_GSL_2F, first string select lines GIDL_SSL_1F and GIDL_SSL_2F, second ground select lines GSL_1F and GSL_2F, and the second string select lines SSL_1F and SSL_2F of the first sub-block SubBLK1 and the second sub-block SubBLK2 may be recovered to the level of the ground voltage GND.

The timing diagram of FIG. 28 illustrating the program verify operation of the memory block BLK1 may be different from the timing diagram of FIG. 27 in that a read voltage Vread1 is applied to the unselected word lines WL1˜WLn-2. This may mean that the read voltage Vread1 at a higher level than the power supply voltage VDD is provided to turn on memory cells connected to the unselected word lines WL1˜WLn-2 because the second sub-block SubBLK2 corresponding to a sister sub-block is in the programmed state.

FIGS. 29 and 30 are diagrams illustrating examples of read methods of the memory device 10c according to some implementations. The read methods of the memory device 10c, which are described with reference to FIGS. 29 and 30, may be similar to the program verify method described with reference to FIG. 27. However, the read timing diagram of FIG. 29 may be different from the program verify timing diagram of FIG. 27 in that the first precharge voltage VBL1 and the second precharge voltage VBL2 may be applied to the selected word line BL_1F (Sel) of the first sub-block SubBLK1 without application of the ground voltage GND between the first sensing operation and the second sensing operation.

In the read timing diagram of FIG. 29, a first read voltage VRA may be applied to a selected word line WL(Sel) of the first sub-block SubBLK1 and the second sub-block SubBLK2 in the first sensing period, and a first read voltage VRB may be applied to the selected word line WL(Sel) in the second sensing period. The first read voltages VRA and VRB may include some read voltages (e.g., VR1 and VR5, VR2, VR4, and VR6, or VR3 and VR7) among the first to seventh read voltage VR1 to VR7 according to a method of reading a page of TLCs.

Compared to the read timing diagram of FIG. 29, referring to the read timing diagram of FIG. 30, a second read voltage Vread and the ground voltage GND may be sequentially applied to each of the first string select line GIDL_SSL_2F, the second string select line SSL_2F, the second ground select line GSL_2F, and the first ground select line GIDL_GSL_2F of the second sub-block SubBLK2 in each of the pre-pulse period and the post-pulse period. This may turn on an SST and a GST, thereby initializing the channels of the second sub-block SubBLK2.

FIG. 31 is a cross-sectional view of a memory device 500 having a bonding vertical NAND (B-VNAND) structure according to some implementations.

In FIG. 31, a memory device 500 may have a C2C structure. Here, the C2C structure may refer to a structure formed by manufacturing at least one upper chip including a cell region CELL, manufacturing a lower chip including a peripheral circuit region PERI, and then connecting the at least one upper chip to the lower chip in a bonding manner. For example, the bonding manner may include a method of electrically or physically connecting a bonding metal pattern formed on an uppermost metal layer of the upper chip to a bonding metal pattern formed on an uppermost metal layer of the lower chip. For example, when the bonding metal patterns include copper (Cu), the bonding manner may be Cu-Cu bonding. In some implementations, the bonding metal patterns may include aluminum (Al) or tungsten (W).

The memory device 500 may include at least one upper chip including a cell region. For example, as shown in FIG. 31, the memory device 500 may include two upper chips. However, this is just an example, and the number of upper chips is not limited thereto. When the memory device 500 includes two upper chips, a first upper chip including a first cell region CELL1, a second upper chip including a second cell region CELL2, and a lower chip including the peripheral circuit region PERI may be separately manufactured and then connected to one another by a bonding manner such that the memory device 500 may be manufactured. The first upper chip may be reversed and connected to the lower chip by a boning manner, and the second upper chip may also be reversed and connected to the first upper chip by a bonding manner. In the description below, the upper and lower portions of each of the first and second upper chips are defined based on before the reverse of the first and second upper chips. In other words, in FIG. 31, the upper portion of the lower chip is defined based on a +Z direction, and the upper portion of each of the first and second upper chips is defined based on a −Z direction. However, this is just an example, and only one of the first and second upper chips may be reversed and connected to the lower chip or the other upper chip by a bonding manner.

Each of the peripheral circuit region PERI and the first and second cell regions CELL1 and CELL2 of the memory device 500 may include an external pad bonding area PA, a word line bonding area WLBA, and a bit line bonding area BLBA.

The peripheral circuit region PERI may include a first substrate 210 and a plurality of circuit elements 220a, 220b, and 220c formed on the first substrate 210. An interlayer insulating layer 215 including at least one insulating layers may be on the circuit elements 220a, 220b, and 220c, and a plurality of metal wirings connecting the circuit elements 220a, 220b, and 220c to one another may be in the interlayer insulating layer 215. For example, the metal wirings may include first metal wirings 230a, 230b, and 230c respectively connected to the plurality of circuit elements 220a, 220b, and 220c, and second metal wirings 240a, 240b, and 240c formed on the first metal wirings 230a, 230b, and 230c. The metal wirings may include at least one conductive material. For example, the first metal wirings 230a, 230b, and 230c may include tungsten having relatively high electrical resistivity, and the second metal wirings 240a, 240b, and 240c may include copper having relatively low electrical resistivity.

Although the first metal wirings 230a, 230b, and 230c and the second metal wirings 240a, 240b, and 240c are shown and described in FIG. 31, the present disclosure is not limited thereto. One or more metal wirings may be further formed on the second metal wirings 240a, 240b, and 240c. In this case, the second metal wirings 240a, 240b, and 240c may include aluminum. At least a portion of the one or more metal wirings formed on the second metal wirings 240a, 240b, and 240c may include copper or the like, which has a lower electrical resistivity than aluminum included in the second metal wirings 240a, 240b, and 240c.

The interlayer insulating layer 215 may be on the first substrate 210 and include an insulating material, such as silicon oxide, silicon nitride, or the like.

Each of the first and second cell regions CELL1 and CELL2 may include at least one memory block. The first cell region CELL1 may include a second substrate 310 and a common source line 320. On the second substrate 310, a plurality of word lines 331 to 338 (i.e., 330) may be stacked in a direction (a Z-axis direction), perpendicular to the top surface of the second substrate 310. String select lines may be on the word lines 330, and a ground select line may be below the word lines 330. The word lines 330 may be between the string select lines and the ground select line. Similarly, the second cell region CELL2 may include a third substrate 410 and a common source line 420, and a plurality of word lines 431 to 438 (i.e., 430) may be stacked in the direction (the Z-axis direction), perpendicular to the top surface of the third substrate 410. The second substrate 310 and the third substrate 410 may include various materials. For example, the second substrate 310 and the third substrate 410 may include a silicon substrate, a silicon-germanium substrate, a germanium substrate, or a substrate having an epitaxial layer grown on a monocrystalline silicon substrate. A plurality of channel structures CH may be formed in each of the first and second cell regions CELL1 and CELL2.

In some implementations, as shown in A1 as an alternative embodiment of A in FIG. 31, a channel structure CH may be in the bit line bonding area BLBA and may extend in a direction, perpendicular to the top surface of the second substrate 310, and pass through the word lines 330, the string select lines, and the ground select line. The channel structure may include a data storage layer, a channel layer, a buried insulating layer, and the like. The channel layer may be electrically connected to a first metal wiring 350c and a second metal wiring 360c in the bit line bonding area BLBA. For example, the second metal wiring 360c may be a bit line 360c and connected to the first metal wiring 350c through the channel structure CH. The bit line 360c may extend in a first direction (a Y-axis direction), parallel to the top surface of the second substrate 310.

In some implementations, as shown in A2 as an alternative embodiment of A in FIG. 31, the channel structure CH may include a lower channel LCH and an upper channel UCH connected to the lower channel LCH. For example, the channel structure may be formed by a process for the lower channel LCH and a process for the upper channel UCH. The lower channel LCH may extend in a direction perpendicular to the top surface of the second substrate 310 and pass through the common source line 320 and the lower word lines 331 and 332. The lower channel LCH may include a data storage layer, a channel layer, a buried insulating layer, and the like and may be connected to the upper channel UCH. The upper channel UCH may pass through the upper word lines 333 to 338. The upper channel UCH may include a data storage layer, a channel layer, a buried insulating layer, and the like. The channel layer of the upper channel UCH may be electrically connected to the first metal wiring 350c and the second metal wiring 360c. As the length of a channel increases, it may be hard to form a channel having a uniform width for the reason of processes. According to some implementations, because the lower channel LCH and the upper channel UCH are formed by sequential processes, the memory device 500 may include a channel having increased width uniformity.

As shown in A2, when the channel structure CH includes the lower channel LCH and the upper channel UCH, a word line around the boundary between the lower channel LCH and the upper channel UCH may correspond to a dummy word line. For example, the word lines 332 and 333 around the boundary between the lower channel LCH and the upper channel UCH may correspond to dummy word lines. In this case, data may not be stored in memory cells connected to the dummy word lines. The number of pages corresponding to memory cells connected to dummy word lines may be less than the number of pages corresponding to memory cells connected to normal word lines. A voltage level applied to a dummy word line may be different from a voltage level applied to a normal word line, and accordingly, the influence of the non-uniform width of the lower and upper channels LCH and UCH on the operation of a memory device may decrease.

As shown in FIG. 31, in A2, the number of lower word lines 331 and 332 passed through by the lower channel LCH is less than the number of upper word lines 333 to 338 passed through by the upper channel UCH. However, it is just an example, and the present disclosure is not limited thereto. In some implementations, the number of lower word lines passed through by the lower channel LCH may be greater than or equal to the number of upper word lines passed through by the upper channel UCH. The structure and connection of the channel structure CH in the first cell region CELL1, which have been described above, may also be applied to channel structures CH in the second cell region CELL2.

In the bit line bonding area BLBA, a first through electrode THV1 and a second through electrode THV2 may be respectively in the first and second cell regions CELL1 and CELL2. As shown in FIG. 31, the first through electrode THV1 may pass through the common source line 320 and the word lines 330. However, this is just an example, and the first through electrode THV1 may further pass through the second substrate 310. The first through electrode THV1 may include a conductive material. In some implementations, the first through electrode THV1 may include a conductive material surrounded by an insulating material. The shape and structure of the second through electrode THV2 may be the same as those of the first through electrode THV1.

In some implementations, the first through electrode THV1 may be electrically connected to the second through electrode THV2 through a first through metal pattern 372d and a second through metal pattern 472d. The first through metal pattern 372d may be in the bottom of the first upper chip including the first cell region CELL1, and the second through metal pattern 472d may be in the top of the second upper chip including the second cell region CELL2. The first through electrode THV1 may be electrically connected to the first and second metal wirings 350c and 360c. The second through electrode THV2 may be electrically connected to a first metal wiring 450c and a second metal wiring 460 c. A lower via 371d may be between the first through electrode THV1 and the first through metal pattern 372 d, and an upper via 471d may be between the second through electrode THV2 and the second through metal pattern 472d. The first through metal pattern 372d may be connected to the second through metal pattern 472d by a bonding manner.

In the bit line bonding area BLBA, an upper metal pattern 252 may be formed in an uppermost metal layer of the peripheral circuit region PERI, and an upper metal pattern 392, which has the same shape as the upper metal pattern 252, may be formed in an uppermost metal layer of the first cell region CELL. The upper metal pattern 392 of the first cell region CELL may be electrically connected to the upper metal pattern 252 of the peripheral circuit region PERI by a bonding manner. In the bit line bonding area BLBA, the bit line 360c may be electrically connected to a page buffer included in the peripheral circuit region PERI. For example, a portion of the circuit elements 220c of the peripheral circuit region PERI may provide a page buffer, and the bit line 360c may be electrically connected to the circuit elements 220c, which provide the page buffer, through an upper bonding metal 370c of the first cell region CELL and an upper bonding metal 270c of the peripheral circuit region PERI.

In FIG. 31, in the word line bonding area WLBA, the word lines 330 of the first cell region CELL may extend in a second direction (an X-axis direction), parallel with the top surface of the second substrate 310, and may be connected to a plurality of cell contact plugs 341 to 347 (i.e., 340). A first metal wiring 350b and a second metal wiring 360b may be sequentially connected to an upper portion of each of the cell contact plugs 340 respectively connected to the word lines 330. In the word line bonding area WLBA, the cell contact plugs 340 may be connected to the peripheral circuit region PERI by an upper bonding metal 370b of the first cell region CELL1 and an upper bonding metal 270b of the peripheral circuit region PERI.

The cell contact plugs 340 may be electrically connected to a row decoder included in the peripheral circuit region PERI. For example, a portion of the circuit elements 220b of the peripheral circuit region PERI may provide the row decoder, and the cell contact plugs 340 may be electrically connected to the circuit elements 220b, which provide the row decoder, by the upper bonding metal 370b of the first cell region CELL1 and the upper bonding metal 270b of the peripheral circuit region PERI. In some implementations, operating voltages of the circuit elements 220b providing the row decoder may be different from operating voltages of the circuit elements 220c providing the page buffer. For example, operating voltages of the circuit elements 220c providing the page buffer may be greater than operating voltages of the circuit elements 220b providing the row decoder.

Similarly, in the word line bonding area WLBA, the word lines 430 of the second cell region CELL2 may extend in the second direction (the X-axis direction), parallel with the top surface of the third substrate 410, and may be connected to a plurality of cell contact plugs 441 to 447 (i.e., 440). The cell contact plugs 440 may be connected to the peripheral circuit region PERI by an upper metal pattern of the second cell region CELL2, a lower metal pattern and an upper metal pattern of the first cell region CELL1, and the cell contact plug 348.

In the word line bonding area WLBA, the upper bonding metal 370b may be formed in the first cell region CELL1, and the upper bonding metal 270b may be formed in the peripheral circuit region PERI. The upper bonding metal 370b of the first cell region CELL1 and the upper bonding metal 270b of the peripheral circuit region PERI may be electrically connected to each other by a bonding manner. The upper bonding metals 370b and 270b may include aluminum, copper, or tungsten.

In the external pad bonding area PA, a lower metal pattern 371e may be formed in a lower portion of the first cell region CELL1, and an upper metal pattern 472a may be formed in an upper portion of the second cell region CELL2. The lower metal pattern 371e of the first cell region CELL1 and the upper metal pattern 472a of the second cell region CELL2 may be connected to each other by a bonding manner in the external pad bonding area PA. Similarly, an upper metal pattern 372a may be formed in an upper portion of the first cell region CELL1, and an upper metal pattern 272a may be formed in an upper portion of the peripheral circuit region PERI. The upper metal pattern 372a of the first cell region CELL1 and the upper metal pattern 272a of the peripheral circuit region PERI may be connected to each other by a bonding manner.

Common source line contact plugs 380 and 480 may be in the external pad bonding area PA. The common source line contact plugs 380 and 480 may include a conductive material, such as metal, a metal compound, or doped polysilicon. The common source line contact plug 380 of the first cell region CELL1 may be electrically connected to the common source line 320, and the common source line contact plug 480 of the second cell region CELL2 may be electrically connected to the common source line 420. A first metal wiring 350a and a second metal wiring 360a may be sequentially stacked above the common source line contact plug 380 of the first cell region CELL1, and a first metal wiring 450a and a second metal wiring 460a may be sequentially stacked above the common source line contact plug 480 of the second cell region CELL2.

First to third I/O pads 205, 405, and 406 may be in the external pad bonding area PA. In FIG. 31, a lower insulating film 201 may cover the bottom surface of the first substrate 210, and the first I/O pad 205 may be formed on the lower insulating film 201. The first I/O pad 205 may be connected to at least one of the circuit elements 220a of the peripheral circuit region PERI by a first I/O contact plug 203 and may be separated from the first substrate 210 by the lower insulating film 201. A side insulating film may be between the first I/O contact plug 203 and the first substrate 210 and thus electrically separate the first I/O contact plug 203 and the first substrate 210.

An upper insulating film 401 may be on the third substrate 410 to cover the top surface of the third substrate 410. The second I/O pad 405 and/or the third I/O pad 406 may be on the upper insulating film 401. The second I/O pad 405 may be connected to at least one of the circuit elements 220a of the peripheral circuit region PERI by second I/O contact plugs 403 and 303, and the third I/O pad 406 may be connected to at least one of the circuit elements 220a of the peripheral circuit region PERI by third I/O contact plugs 404 and 304.

In some implementations, the third substrate 410 may not be formed in a region, in which an I/O contact plug is arranged. For example, as shown in B, the third I/O contact plug 404 may be separated from the third substrate 410 in a direction parallel with the top surface of the third substrate 410 and may pass through an interlayer insulating layer 415 of the second cell region CELL2 to be connected to the third I/O pad 406. In this case, the third I/O contact plug 404 may be formed by various processes.

For example, as shown in B1 as an alternative embodiment of B of FIG. 31, the third I/O contact plug 404 may extend in a third direction (the Z-axis direction) and have a diameter increasing toward the upper insulating film 401. In other words, while the diameter of the channel structure CH described with reference to A1 decreases toward the upper insulating film 401, the diameter of the third I/O contact plug 404 may increase toward the upper insulating film 401. For example, the third I/O contact plug 404 may be formed after the second cell region CELL2 is connected to the first cell region CELL1 by a bonding manner.

For example, in B2 as an alternative embodiment of B, the third I/O contact plug 404 may extend in the third direction (the Z-axis direction) and have a diameter decreasing toward the upper insulating film 401. In other words, the diameter of the third I/O contact plug 404 may decrease toward the upper insulating film 401 like the diameter of the channel structure CH. For example, the third I/O contact plug 404 may be formed together with the cell contact plugs 440 before the second cell region CELL2 is connected to the first cell region CELL1 by a bonding manner.

In some implementations, an I/O contact plug may overlap the third substrate 410. For example, as shown in C, the second I/O contact plug 403 may pass through the interlayer insulating layer 415 of the second cell region CELL2 in the third direction (the Z-axis direction) and may be electrically connected to the second I/O pad 405 through the third substrate 410. In this case, a connection structure of the second I/O contact plug 403 and the second I/O pad 405 may be implemented in various manners.

For example, in C1 as an alternative embodiment of C, an opening 408 may be formed through the third substrate 410, and the second I/O contact plug 403 may be directly connected to the second I/O pad 405 through the opening 408 formed in the third substrate 410. In this case, as shown in C1, the diameter of the second I/O contact plug 403 may increase toward the second I/O pad 405. However, this is just an example, and the diameter of the second I/O contact plug 403 may decrease toward the second I/O pad 405.

For example, in C2 as an alternative embodiment of C, the opening 408 may be formed through the third substrate 410, and a contact 407 may be formed in the opening 408. An end of the contact 407 may be connected to the second I/O pad 405, and an opposite end of the contact 407 may be connected to the second I/O contact plug 403. Accordingly, the second I/O contact plug 403 may be electrically connected to the second I/O pad 405 by the contact 407 in the opening 408. In this case, in C2, the diameter of the contact 407 may increase toward the second I/O pad 405, and the diameter of the second I/O contact plug 403 may decrease toward the second I/O pad 405. For example, the second I/O contact plug 403 may be formed together with the cell contact plugs 440 before the second cell region CELL2 is connected to the first cell region CELL1 by a bonding manner, and the contact 407 may be formed after the second cell region CELL2 is connected to the first cell region CELL1 by the bonding manner.

For example, in C3 as an alternative embodiment of C, a stopper 409 may be further formed on the top surface of the opening 408 of the third substrate 410 compared to C2 of FIG. 31. The stopper 409 may include a metal wiring formed in the same layer as the common source line 420. However, this is just an example, and the stopper 409 may include a metal wiring formed in the same layer as at least one of the word lines 430. The second I/O contact plug 403 may be electrically connected to the second I/O pad 405 by the contact 407 and the stopper 409.

Similar to the second and third I/O contact plugs 403 and 404 of the second cell region CELL2, each of the second and third I/O contact plugs 303 and 304 of the first cell region CELL1 may have a diameter increasing or decreasing toward the lower metal pattern 371e.

According to some implementations, a slit 411 may be formed in the third substrate 410. For example, the slit 411 may be formed in a random position in the external pad bonding area PA. As shown in D, the slit 411 may be between the second I/O pad 405 and the cell contact plugs 440 in a plan view. However, this is just an example, and the second I/O pad 405 may be between the slit 411 and the cell contact plugs 440 in a plan view.

In D1 as an alternative embodiment of D, the slit 411 may pass through the third substrate 410. For example, the slit 411 may be used to prevent the third substrate 410 from finely cracking when the opening 408 is formed. However, this is just an example, and the slit 411 may be formed to have a depth of about 60 % to about 70 % of the thickness of the third substrate 410.

In D2 as an alternative embodiment of D, a conductive material 412 may be formed in the slit 411. For example, the conductive material 412 may be used to discharge leakage current, which is generated while circuit elements of the external pad bonding area PA are operating. In this case, the conductive material 412 may be connected to an external ground line.

In D3 as an alternative embodiment of D, an insulating material 413 may be formed in the slit 411. For example, the insulating material 413 may be formed to electrically separate the second I/O pad 405 and the second I/O contact plug 403 in the external pad bonding area PA from the word line bonding area WLBA. When the insulating material 413 is formed in the slit 411, a voltage provided through the second I/O pad 405 may be prevented from influencing a metal layer on the third substrate 410 in the word line bonding area WLBA.

According to some implementations, the first to third I/O pads 205, 405, and 406 may be selectively formed. For example, the memory device 500 may include only the first I/O pad 205 above the first substrate 210, only the second I/O pad 405 above the third substrate 410, or only the third I/O pad 406 on the upper insulating film 401.

According to some implementations, at least one selected from the group consisting of the second substrate 310 of the first cell region CELL1 and the third substrate 410 of the second cell region CELL2 may be used as a sacrificial substrate and entirely or partially removed before or after a bonding process. An additional film may be stacked on a resultant structure after the sacrificial substrate is removed. For example, the second substrate 310 of the first cell region CELL1 may be removed before or after the bonding between the peripheral circuit region PERI and the first cell region CELL1, and an insulating film covering the top surface of the common source line 320 or a conductive film for connection to the common source line 320 may be formed. Similarly, the third substrate 410 of the second cell region CELL2 may be removed before or after the bonding between the first cell region CELL1 and the second cell region CELL2, and the upper insulating film 401 covering the top surface of the common source line 420 or a conductive film for connection to the common source line 420 may be formed.

According to some implementations, upper bonding metals 270c in the peripheral circuit region PERI may be above a page buffer circuit region and arranged in a matrix in the first direction (the Y-axis direction) and the second direction (the X-axis direction). The page buffer circuit region may correspond to the bit line bonding area BLBA. For example, the upper bonding metals 270c may be divided into a plurality of bonding pad groups, and each bonding pad group may include upper bonding metals 270c arranged in a line in the first direction (the Y-axis direction). According to some implementations, the peripheral circuit region PERI may include a plurality of through wirings extending in the first direction (the Y-axis direction). For example, each through wiring may be between adjacent bonding pad groups.

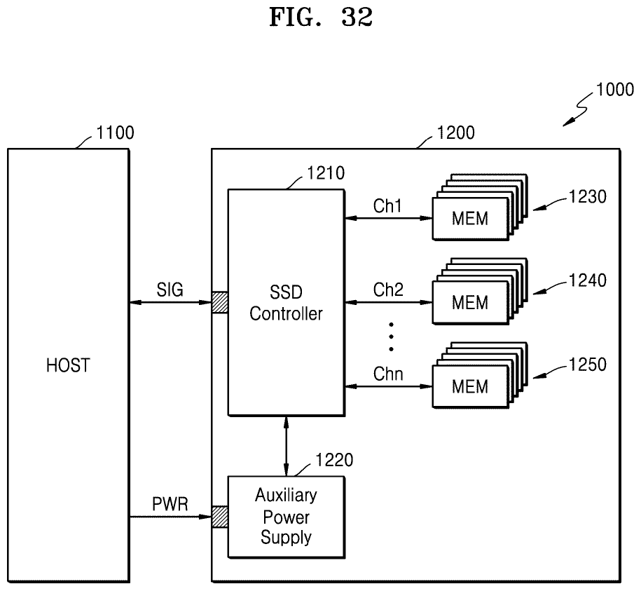

FIG. 32 is a block diagram illustrating an example of applying a memory device to a solid-state drive (SSD) system 1000 according to some implementations.

In FIG. 32, the SSD system 1000 may include a host 1100 and an SSD 1200. The SSD 1200 may exchange signals SIG with the host 1100 through a signal connector and may receive power PWR through a power connector. The SSD 1200 may include an SSD controller 1210, an auxiliary power supply 1220, and memory devices (MEMs) 1230, 1240, and 1250. The memory devices 1230, 1240, and 1250 may include vertical stack NAND flash memory devices. In some implementations, the memory devices 1230, 1240, and 1250 may be connected to the SSD controller 1210 through channels Ch1, Ch2, and Chn, respectively. In this case, the SSD 1200 may be implemented using the implementations described above with reference to FIGS. 1 to 31.

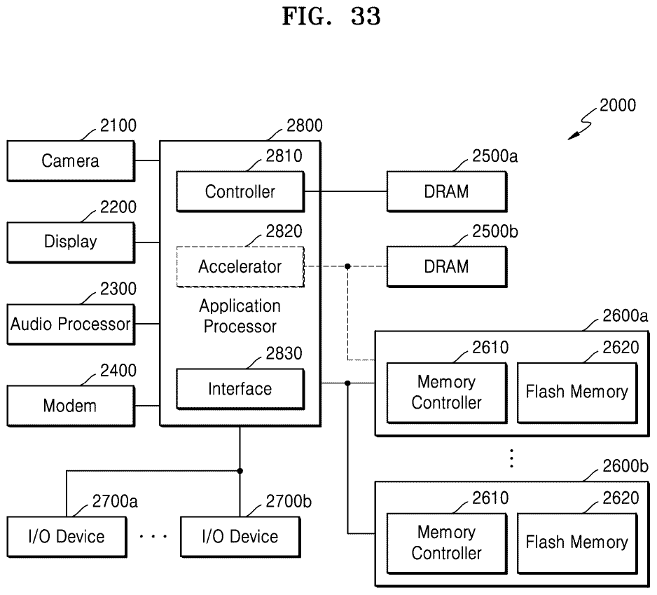

FIG. 33 is a block diagram of a system 2000 illustrating an electronic apparatus including a memory device according to some implementations.

Referring to FIG. 33, the system 2000 may include a camera 2100, a display 2200, an audio processor 2300, a modem 2400, dynamic random access memories (DRAMs) 2500a and 2500b, flash memory devices 2600a and 2600b, input/output (I/O) devices 2700a and 2700b, and an application processor (AP) 2800. The system 2000 may include a laptop computer, a mobile phone, a smartphone, a tablet personal computer (PC), a wearable device, a healthcare device, or an Internet of things (IoT) device. The system 2000 may include a server or a PC.

The camera 2100 may shoot a still image or a video under a user's control and store image/video data or transmit the image/video data to the display 2200. The audio processor 2300 may process audio data included in the contents of the flash memory devices 2600a and 2600b or a network. For wired/wireless data communication, the modem 2400 modulates a signal, transmits a modulated signal, and demodulates a received signal to restore an original signal. The I/O devices 2700a and 2700b may include devices, such as universal serial bus (USB) storage, a digital camera, a secure digital (SD) card, a digital versatile disc (DVD), a network adapter, and a touch screen, which provide digital input and/or output functions.

The AP 2800 generally controls operations of the system 2000. The AP 2800 may include a controller 2810, an accelerator (for example, an accelerator block or accelerator chip) 2820, and an interface 2830. The AP 2800 may control the display 2200 to display a portion of the contents stored in the flash memory devices 2600a and 2600b. When the AP 2800 receives user input through the I/O devices 2700a and 2700b, the AP 2800 may perform a control operation corresponding to the user input. The AP 2800 may include an accelerator block, which is a dedicated circuit for artificial intelligence (AI) data operations, or the accelerator chip 2820 may be provided separately from the AP 2800. The DRAM 2500b may be additionally mounted on the accelerator block or the accelerator chip 2820. An accelerator is a functional block that specially performs a certain function of the AP 2800 and may include a GPU that is a functional block specially performing graphics data processing, a neural processing unit (NPU) that is a functional block specially performing AI calculation and inference, and a data processing unit (DPU) that is a functional block specially performing data transmission.

The system 2000 may include a plurality of DRAMs 2500a and 2500b. The AP 2800 may control the DRAMs 2500a and 2500b through commands and mode register setting (MRS), which comply with Joint Electron Device Engineering Council (JEDEC) standards, or may set a DRAM interface protocol and communicate with the DRAMs 2500a and 2500b to use company's unique functions, such as low voltage, high speed, reliability, and a cyclic redundancy check (CRC) function, and/or an error correction code (ECC) function. For example, the AP 2800 may communicate with the DRAM 2500 a through an interface, such as low power double data rate 4 (LPDDR4) or LPDDR5, complying with the JEDEC standards, and the accelerator block or the accelerator chip 2820 may set a new DRAM interface protocol and communicate with the DRAM 2500b to control the DRAM 2500b, which has a higher bandwidth than the DRAM 2500a for an accelerator.

Although only the DRAMs 2500a and 2500b are illustrated in FIG. 33, the present disclosure is not limited thereto. Any type of memory, such as phase-change RAM (PRAM), static RAM (SRAM), magnetic RAM (MRAM), resistance RAM (RRAM), ferroelectric RAM (FRAM), or hybrid RAM, which satisfies the requirements of a bandwidth, a response speed, and/or a voltage for the AP 2800 or the accelerator chip 2820, may be used. The DRAMs 2500a and 2500b have relatively less latency and bandwidth than the I/O devices 2700a and 2700b or the flash memory devices 2600a and 2600b. The DRAMs 2500a and 2500b may be initialized when the system 2000 is powered on and may be loaded with an operating system (OS) and application data to be used as a temporary storage of the OS and the application data or may be used as a space for execution of various kinds of software code.

The four fundamental arithmetic operations, i.e., addition, subtraction, multiplication, and division, vector operations, address operation, or fast Fourier transform (FFT) operations may be performed in the DRAMs 2500a and 2500b. Functions for executions used for inference may also be performed in the DRAMs 2500a and 2500b. Here, the inference may be performed during a deep learning algorithm using an artificial neural network. The deep learning algorithm may include a training phase, in which a model is trained using various data, and an inference phase, in which data is recognized using the trained model. In some implementations, an image captured by a user by using the camera 2100 may under signal processing and may then be stored in the DRAM 2500b, and the accelerator block or the accelerator chip 2820 may perform an Artificial Intelligence (AI) data operation to recognize data by using the data stored in the DRAM 2500b and functions used for inference.

The system 2000 may include a plurality of storages or flash memory devices 2600a and 2600b, which have a larger capacity than the DRAMs 2500a and 2500b. The accelerator block or the accelerator chip 2820 may perform a training phase and an AI data operation using the flash memory devices 2600a and 2600b. In some implementations, each of the flash memory devices 2600a and 2600b may include a memory controller 2610 and a flash memory 2620 and may allow the AP 2800 and/or the accelerator chip 2820 to efficiently perform a training phase and an inference AI data operation using an arithmetic unit included in the memory controller 2610. The flash memory devices 2600a and 2600b may store images shot through the camera 2100 or data received from a data network. For example, the flash memory devices 2600a and 2600b may store augmented and/or virtual reality contents, high definition (HD) contents, or ultra-high definition (UHD) contents.

In the system 2000, the flash memory devices 2600a and 2600b may include a memory device described with reference to FIGS. 1 to 32. In memory devices, word lines of each of a plurality of sub-blocks of a memory block may be respectively connected to word lines of another sub-block of the memory block, or word lines and bit lines of each of a plurality of sub-blocks of a memory block may be respectively connected to word lines and bit lines of another sub-block of the memory block. When an erase operation, a program operation, a program verify operation, and/or a read operation are performed on a plurality of sub-blocks of these memory devices, the performance of the memory devices may be increased and the power consumption and chip size of the memory devices may be reduced.

While this disclosure contains many specific implementation details, these should not be construed as limitations on the scope of what may be claimed, equivalents thereof, as well as attached claims. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A memory device comprising
a chip stack,
wherein the chip stack includes:
a peripheral circuit including a plurality of first bonding metal pads; and
a cell array on the peripheral circuit and overlapping the peripheral circuit in a vertical direction, the cell array including a plurality of memory blocks, a plurality of second bonding metal pads, and a plurality of third bonding metal pads,
wherein the cell array includes a first cell chip and a second cell chip on the first cell chip,
wherein the first cell chip includes:
the plurality of second bonding metal pads; and
a first memory cell array region including a plurality of first sub-blocks,
wherein each first sub-block of the plurality of first sub-blocks includes a plurality of first word lines, a plurality of first string select lines, a plurality of first ground select lines, a plurality of first bit lines, and a first common source line, and a portion of the plurality of second bonding metal pads in a lower portion of the first cell chip is in contact with the plurality of first bonding metal pads,
wherein the second cell chip includes:
the plurality of third bonding metal pads; and
a second memory cell array region including a plurality of second sub-blocks,
wherein each second sub-block of the plurality of second sub-blocks includes a plurality of second word lines, a plurality of second string select lines, a plurality of second ground select lines, a plurality of second bit lines, and a second common source line, and the plurality of third bonding metal pads are in contact with another portion of the plurality of second bonding metal pads in an upper portion of the first cell chip,
wherein each memory block of the plurality of memory blocks includes a respective first sub-block from among the plurality of first sub-blocks and a respective second sub-block from among the plurality of second sub-blocks, the plurality of first word lines being respectively connected to the plurality of second word lines, and
wherein, the peripheral circuit is configured to, in an erase operation of a selected first sub-block of a selected memory block among the plurality of memory blocks, sequentially float the plurality of first string select lines after a first time delay at a level of a ground voltage starting from a first string select line away from the plurality of first bit lines.

2. The memory device of claim 1, wherein, in the erase operation of the selected first sub-block, the plurality of first ground select lines are configured to sequentially float after a second time delay at the level of the ground voltage starting from a first ground select line away from the first common source line.

3. The memory device of claim 2, wherein the peripheral circuit is configured to float the plurality of first string select lines simultaneously with the floating of the plurality of first ground select lines.

4. The memory device of claim 2,
wherein each first sub-block of the plurality of first sub-blocks includes a respective plurality of first dummy word lines between the plurality of first string select lines and the plurality of first word lines,
wherein each second sub-block of the plurality of second sub-blocks includes a respective plurality of second dummy word lines between the plurality of second string select lines and the plurality of second word lines,
wherein the plurality of first dummy word lines are respectively connected to the plurality of second dummy word lines, and
wherein, the peripheral circuit is configured to, in the erase operation of the selected first sub-block, the plurality of first dummy word lines are configured to float after a third time delay at the level of the ground voltage.

5. The memory device of claim 4, wherein the peripheral circuit is configured to float of the plurality of first dummy word lines after the floating of the plurality of first string select lines and the floating of the plurality of first ground select lines.

6. The memory device of claim 1,
wherein, in the erase operation of the selected first sub-block, the peripheral circuit is configured to:
apply the ground voltage to the plurality of first word lines and the plurality of second word lines,
apply an erase voltage to the plurality of first bit lines and the plurality of second bit lines,
apply the erase voltage to the first common source line and the second common source line, and
float the plurality of second string select lines and the plurality of second ground select lines.

7. The memory device of claim 6, wherein, in each memory block of the plurality of memory blocks, the plurality of first bit lines are respectively connected to the plurality of second bit lines.

8. The memory device of claim 6, wherein, in each memory block of the plurality of memory blocks, the first common source line is connected to the second common source line.

9. The memory device of claim 6, wherein, in each memory block of the plurality of memory blocks, the plurality of first bit lines are respectively connected to the plurality of second bit lines, and the first common source line is connected to the second common source line.

10. The memory device of claim 1,
wherein the peripheral circuit is configured to apply a first voltage, which is higher than a power supply voltage, as a block select signal of the selected memory block among the plurality of memory blocks, and
wherein the peripheral circuit is configured to apply the ground voltage as a block select signal of an unselected memory block among the plurality of memory blocks.

11. The memory device of claim 1,
wherein the peripheral circuit is configured to drive a first string select line, among the plurality of first string select lines, that is adjacent to the plurality of first bit lines by a first string select line driving signal through a first pass transistor or by a second string select line driving signal through a second pass transistor, and
wherein the peripheral circuit is configured to drive a second string select line, among the plurality of second string select lines, that is adjacent to the plurality of second bit lines by a third string select line driving signal through a third pass transistor or by a fourth string select line driving signal through a fourth pass transistor.

12. The memory device of claim 11,
wherein, in the erase operation of the selected first sub-block, the peripheral circuit is configured to turn off the first pass transistor, the second pass transistor, the third pass transistor, and the fourth pass transistor of the selected memory block, and float the first string select line adjacent to the plurality of first bit lines and the second string select line adjacent to the plurality of second bit lines of the selected memory block, and
wherein, in an unselected memory block among the plurality of memory blocks, the peripheral circuit is configured to turn off the first pass transistor and the second pass transistor of the unselected memory block, float a first string select line adjacent to the plurality of first bit line of the unselected memory block, turn off the third pass transistor of the unselected memory block, turn on the fourth pass transistor of the unselected memory block and turn off the fourth pass transistor of the unselected memory block after a certain time from being turned on, and float a second string select line adjacent to the plurality of second bit lines of the unselected memory block after the first time delay at the level of the ground voltage.

13. The memory device of claim 11,
wherein the peripheral circuit is configured to drive a first ground select line that is adjacent to the first common source line among the plurality of first ground select lines by a first ground select line driving signal through a fifth pass transistor or by a second ground select line driving signal through a sixth pass transistor, and
wherein the peripheral circuit is configured to drive a second ground select line that is adjacent to the second common source line among the plurality of second ground select lines by a third ground select line driving signal through a seventh pass transistor or by a fourth ground select line driving signal through an eighth pass transistor.

14. The memory device of claim 13,
wherein, in the erase operation of the selected first sub-block, the peripheral circuit is configured to turn off the first pass transistor, the second pass transistor, the third pass transistor, and the fourth pass transistor of the selected memory block, and float the first string select line adjacent to the plurality of first bit lines and the second string select line adjacent to the plurality of second bit lines of the selected first sub-block, and
wherein, in an unselected memory block among the plurality of memory blocks, the peripheral circuit is configured to turn off the first pass transistor and the second pass transistor of the unselected memory block, float a first string select line adjacent to the plurality of first bit line of the unselected memory block, turn off the third pass transistor of the unselected memory block, turn on the fourth pass transistor of the unselected memory block and turn off the fourth pass transistor of the unselected memory block after a certain time from being turned on, and float a second string select line adjacent to the plurality of second bit lines of the unselected memory block after the first time delay at the level of the ground voltage.

15. The memory device of claim 11, wherein, in the erase operation of the selected first sub-block, the peripheral circuit is configured to:
apply the ground voltage to the plurality of first word lines and the plurality of second word lines,
apply an erase voltage to the plurality of first bit lines, apply a power supply voltage to the plurality of second bit lines, and float the plurality of second bit linesafter a certain time, and
apply the erase voltage to the first common source line, apply the power supply voltage to the second common source line, and float the second common source line after a certain time.

16. The memory device of claim 1, wherein the peripheral circuit is configured to:
apply a first voltage higher than a power supply voltage as a block select signal of the selected memory block among the plurality of memory blocks,
apply a second voltage as a block select signal of an unselected memory block among the plurality of memory blocks, the second voltage being lower than the first voltage and having a voltage level corresponding to a sum of a level of a transistor threshold voltage and a level of a word line voltage, and
apply, in each of the selected memory block and the unselected memory block, an erase voltage to the plurality of first bit lines, and apply the power supply voltage to the plurality of second bit lines.

17. The memory device of claim 16, wherein, in each of the selected memory block and the unselected memory block, the peripheral circuit is configured to:
drive the plurality of first word lines and the plurality of second word lines by a word line driving signal at the level of the word line voltage,
apply the erase voltage to the plurality of first bit lines and the first common source line,
float the plurality of second bit lines and the second common source line at a time after the power supply voltage is applied to the plurality of second bit lines and the second common source line,
drive a first string select line that is adjacent to the plurality of first bit lines among the plurality of first string select lines by a first string select line driving signal through a first pass transistor,
drive a second string select line that is away from the plurality of first bit lines among the plurality of first string select lines by a second string select line driving signal through a second pass transistor,
drive a third string select line that is adjacent to the plurality of second bit lines among the plurality of second string select lines by a third string select line driving signal through a third pass transistor, and
drive a fourth string select line that is away from the plurality of second bit lines among the plurality of second string select lines by a fourth string select line driving signal through a fourth pass transistor.

18. The memory device of claim 17, wherein, in each of the selected memory block and the unselected memory block, the peripheral circuit is configured to:
apply the first voltage as the fourth string select line driving signal, and float the fourth string select line,
apply the word line voltage as the second string select line driving signal, and float the second string select line after the first time delay,
apply the word line voltage as the first string select line driving signal, and float the first string select line after a second time delay,
apply the ground voltage as the third string select line driving signal, and float the third string select line after the second time delay, and
apply the second voltage as the block select signal of the unselected memory block, and apply, after the second time delay, the ground voltage as the block select signal of the unselected memory block.

19. The memory device of claim 17, wherein, in each of the selected memory block and the unselected memory block, the peripheral circuit is configured to:
drive a first ground select line that is adjacent to the first common source line among the plurality of first ground select lines by a first ground select line driving signal through a fifth pass transistor,
drive a second ground select line that is away from the first common source line among the plurality of first ground select lines by a second ground select line driving signal through a sixth pass transistor,
drive a third ground select line that is adjacent to the second common source line among the plurality of second ground select lines by a third ground select line driving signal through a seventh pass transistor, and
drive a fourth ground select line that is away from the second common source line among the plurality of second ground select lines by a fourth ground select line driving signal through an eighth pass transistor.

20. The memory device of claim 19, wherein, in each of the selected memory block and the unselected memory block, the peripheral circuit is configured to:
apply the first voltage as the fourth ground select line driving signal, and float the fourth ground select line,
apply the word line voltage as the second ground select line driving signal, and float the second ground select line after the first time delay,
apply the word line voltage as the first ground select line driving signal and the third ground select line driving signal, and float the first ground select line and the third ground select line after a second time delay, and
apply the second voltage as the block select signal of the unselected memory block, and apply, after the second time delay, the ground voltage as the block select signal of the unselected memory block.
